(19) United States
(12) Patent Application Publication
(10) Pub. No.: US 2020/0006567 A1
(43) Pub. Date: Jan. 2, 2020

(54) SEMICONDUCTOR DEVICE

(71) Applicant: SEMICONDUCTOR ENERGY LABORATORY CO., LTD., ATSUGI-SHI, KANAGAWA-KEN (JP)

(72) Inventors: Yuta ENDO, Atsugi, Kanagawa (JP); Hiromi SAWAI, Atsugi, Kanagawa (JP); Hajime KIMURA, Atsugi, Kanagawa (JP); Shunpei YAMAZAKI, Setagaya, Tokyo (JP)

(73) Assignee: SEMICONDUCTOR ENERGY LABORATORY CO., LTD., ATSUGI-SHI, KANAGAWA-KEN (JP)

(21) Appl. No.: 16/484,148

(22) PCT Filed: Feb. 7, 2018
(86) PCT No.: PCT/IB2018/050747

§ 371 Date: Aug. 7, 2019

(30) Foreign Application Priority Data
Feb. 15, 2017 (JP) 2017-025705

(51) Int. Cl. H01L 29/786; H01L 29/66; H01L 21/02

(52) U.S. Cl. CPC H01L 29/7869; H01L 21/02631; H01L 21/02565; H01L 29/66969

(57) ABSTRACT

A high-performance and highly reliable semiconductor device can be provided.

The semiconductor device includes a first oxide; a second oxide over the first oxide; a source electrode and a drain electrode over the second oxide; a third oxide over the second oxide, the source electrode, and the drain electrode; a fourth oxide over the third oxide; a gate insulating film over the fourth oxide; and a gate electrode over the gate insulating film. The band gap of the first oxide is substantially the same as the band gap of the fourth oxide, the band gap of the second oxide is substantially the same as the band gap of the third oxide, the band gap of the first oxide is larger than the band gap of the second oxide, and the fourth oxide is less likely to transmit oxygen than the third oxide.

### TECHNICAL FIELD

One embodiment of the present invention relates to a semiconductor device and a driving method of the semiconductor device. Alternatively, one embodiment of the present invention relates to a semiconductor wafer, a module, and an electronic device.

Note that in this specification and the like, a semiconductor device generally means a device that can function by utilizing semiconductor characteristics. In some cases, it can be said that a display device (e.g., a liquid crystal display device and a light-emitting display device), a projection device, a lighting device, an electro-optical device, a power storage device, a memory device, a semiconductor circuit, an imaging device, an electronic device, and the like each include a semiconductor device.

Note that one embodiment of the present invention is not limited to the above technical field. One embodiment of the invention disclosed in this specification and the like relates to an object, a method, or a manufacturing method. Alternatively, one embodiment of the present invention relates to a process, a machine, manufacture, or a composition of matter.

### BACKGROUND ART

A technique by which a transistor is formed using a semiconductor thin film has been attracting attention. The transistor is widely applied to electronic devices such as an integrated circuit (IC) and an image display device (also simply referred to as a display device). A silicon-based semiconductor material is widely known as a material for semiconductor thin film that can be used for a transistor, and as another material, an oxide semiconductor has been attracting attention.

For example, techniques have been disclosed by each of which a display device is fabricated using a transistor that uses an oxide semiconductor such as zinc oxide or an In—Ga—Zn-based oxide for an active layer (see Patent Document 1 and Patent Document 2).

Moreover, in recent years, a technique has been disclosed by which an integrated circuit of a memory device is fabricated using a transistor including an oxide semiconductor (see Patent Document 3). Furthermore, not only memory devices but also arithmetic devices and the like are fabricated using transistors including oxide semiconductors.

### PRIOR ART DOCUMENTS

### Patent Documents

[Patent Document 1] Japanese Published Patent Application No. 2007-123861

[Patent Document 2] Japanese Published Patent Application No. 2007-096055

[Patent Document 3] Japanese Published Patent Application No. 2011-119674

### SUMMARY OF THE INVENTION

### Problems to be Solved by the Invention

An object of one embodiment of the present invention is to provide a semiconductor device having favorable electrical characteristics. Alternatively, an object of one embodiment of the present invention is to provide a highly reliable semiconductor device. Alternatively, an object of one embodiment of the present invention is to provide a semiconductor device that can be miniaturized or highly integrated. Alternatively, an object of one embodiment of the present invention is to provide a semiconductor device with high productivity.

Alternatively, an object of one embodiment of the present invention is to provide a semiconductor device capable of retaining data for a long time. Alternatively, an object of one embodiment of the present invention is to provide a semiconductor device capable of high-speed data writing. Alternatively, an object of one embodiment of the present invention is to provide a semiconductor device with high design flexibility. Alternatively, an object of one embodiment of the present invention is to provide a semiconductor device in which power consumption can be reduced. Alternatively, an object of one embodiment of the present invention is to provide a novel semiconductor device.

Note that the descriptions of these objects do not disturb the existence of other objects. In one embodiment of the present invention, there is no need to achieve all the objects. Objects other than these will be apparent from the descriptions of the specification, the drawings, the claims, and the like, and can be derived from the descriptions of the specification, the drawings, the claims, and the like.

### Means for Solving the Problems

A transistor included in a semiconductor device is required to have favorable electrical characteristics and high reliability. For example, states of a region in which a channel of a transistor is formed (referred to as a channel formation region) and its vicinity greatly influence electrical characteristics and reliability of the transistor. Therefore, in the channel formation region and its vicinity, it is important to reduce factors that cause deterioration in electrical characteristics and a decrease in reliability, such as defects and contamination, as much as possible.

According to one embodiment of the present invention, defects, contamination, and the like in the channel formation region and its vicinity are reduced, so that a semiconductor device including a transistor having favorable electrical characteristics and high reliability can be obtained.

One embodiment of the present invention is a semiconductor device including a first oxide; a second oxide over the first oxide; a source electrode and a drain electrode over the second oxide; a third oxide over the second oxide, the source electrode, and the drain electrode; a fourth oxide over the third oxide; a gate insulating film over the fourth oxide; and a gate electrode over the gate insulating film. A band gap of the first oxide is substantially the same as a band gap of the fourth oxide; a band gap of the second oxide is substantially the same as a band gap of the third oxide; the band gap of the first oxide is larger than the band gap of the second oxide; and the fourth oxide is less likely to transmit oxygen than the third oxide.

One embodiment of the present invention is the semiconductor device in which the second oxide and the third oxide each comprise a channel formation region; the channel formation region is positioned between the source electrode and the drain electrode; and a height from a bottom surface of the first oxide to each of the channel formation region, the source electrode, and the drain electrode is substantially the same.

One embodiment of the present invention is the semiconductor device in which a difference between the band gap of the first oxide and the band gap of the fourth oxide is less than or equal to 0.15 eV; a difference between the band gap of the second oxide and the band gap of the third oxide is less than or equal to 0.15 eV; and a difference between the band gap of the first oxide and the band gap of the second oxide is greater than or equal to 0.3 eV and less than or equal to 0.7 eV.

One embodiment of the present invention is the semiconductor device in which the first to fourth oxides each contain In, an element M, and Zn; the element M is Al, Ga, Y, or Sn; the first oxide and the fourth oxide each include a region in which a proportion of the element M is higher than a proportion of In; the second oxide and the third oxide each include a region in which a proportion of the element M is lower than a proportion of In; the first oxide and the fourth oxide have the same composition or similar compositions; and the second oxide and the third oxide have the same composition or similar compositions.

It is preferable that the fourth oxide be less likely to transmit oxygen than the gate insulating film.

One embodiment of the present invention may be a module including the above-described semiconductor device and a printed circuit board.

One embodiment of the present invention is an electronic device including the above-described semiconductor device, the above-described module, and a speaker or an operation key.

One embodiment of the present invention is a semiconductor wafer including a plurality of the above-described semiconductor devices and a region for dicing.

One embodiment of the present invention is a fabricating method of a semiconductor device including the steps of: forming a first oxide by a sputtering method using a first target; forming a second oxide over the first oxide by the sputtering method using a second target; forming a first conductor and a second conductor over the second oxide; forming a third oxide over the second oxide, the first conductor, and the second conductor by the sputtering method using a third target; forming a fourth oxide over the third oxide by the sputtering method using a fourth target; forming an insulator over the fourth oxide; and forming a third conductor over the insulator. The first to fourth targets each contain at least two or more kinds of metal elements; an atomic ratio of the metal elements in the first target and an atomic ratio of the metal elements in the fourth target are the same or similar to each other; and an atomic ratio of the metal elements in the second target and an atomic ratio of the metal elements in the third target are the same or similar to each other.

One embodiment of the present invention is the fabricating method of a semiconductor device in which the first target and the fourth target each contain In, an element M, and Zn, the element M is Al, Ga, Y, or Sn, and In atoms are less than the element M atoms; the second target and the third target each contain In, the element M, and Zn, the element M is Al, Ga, Y, or Sn, and In atoms are greater than the element M atoms.

In the above, the fabricating method of the semiconductor device is characterized in that the first oxide and the second oxide are formed under a reduced pressure in an order of the first oxide and the second oxide, and the third oxide and the fourth oxide are formed under the reduced pressure in an order of the third oxide and the fourth oxide.

One embodiment of the present invention is a fabricating method of a module, the module includes a semiconductor device fabricated using the above-described fabricating method of a semiconductor device and a printed circuit board.

One embodiment of the present invention is a fabricating method of an electronic device, the electronic device includes a semiconductor device fabricated using the above-described fabricating method of a semiconductor device; a module fabricated using the above-described fabricating method of a module; and a speaker or an operation key.

### Effect of the Invention

A semiconductor device having favorable electrical characteristics can be provided. Alternatively, one embodiment of the present invention can provide a highly reliable semiconductor device. Alternatively, a semiconductor device that can be miniaturized or highly integrated can be provided. Alternatively, a semiconductor device with high productivity can be provided.

Alternatively, a semiconductor device capable of retaining data for a long time can be provided. Alternatively, a semiconductor device capable of high-speed data writing can be provided. Alternatively, a semiconductor device with high design flexibility can be provided. Alternatively, a semiconductor device in which power consumption can be reduced can be provided. Alternatively, a novel semiconductor device can be provided.

Note that the descriptions of these effects do not disturb the existence of other effects. In one embodiment of the present invention, there is no need to have all the effects. Effects other than these will be apparent from the descriptions of the specification, the drawings, the claims, and the like, and can be derived from the descriptions of the specification, the drawings, the claims, and the like.

### BRIEF DESCRIPTION OF DRAWINGS

FIG. 1 A top view of a transistor of one embodiment of the present invention and diagrams illustrating the cross-sectional structure;

FIG. 2 A top view of a transistor of one embodiment of the present invention and diagrams illustrating the cross-sectional structure;

FIG. 3 A top view of a transistor of one embodiment of the present invention and diagrams illustrating the cross-sectional structure;

FIG. 4 A top view of a transistor of one embodiment of the present invention and diagrams illustrating the cross-sectional structure;

FIG. 5 A top view of a transistor of one embodiment of the present invention and diagrams illustrating the cross-sectional structure;

FIG. 6 A top view of a transistor of one embodiment of the present invention and diagrams illustrating the cross-sectional structure;

FIG. 7 A top view of a transistor of one embodiment of the present invention and diagrams illustrating the cross-sectional structure;

FIG. 8 Diagrams illustrating a fabricating method of a transistor of one embodiment of the present invention;

FIG. 9 Diagrams illustrating a fabricating method of a transistor of one embodiment of the present invention;

FIG. 10 Diagrams illustrating a fabricating method of a transistor of one embodiment of the present invention;

FIG. 11 Diagrams illustrating a fabricating method of a transistor of one embodiment of the present invention;

FIG. 12 Diagrams illustrating a fabricating method of a transistor of one embodiment of the present invention;

FIG. 13 Diagrams illustrating a fabricating method of a transistor of one embodiment of the present invention;

FIG. 14 Diagrams illustrating a fabricating method of a transistor of one embodiment of the present invention;

FIG. 15 Diagrams illustrating a fabricating method of a transistor of one embodiment of the present invention;

FIG. 16 Diagrams illustrating a fabricating method of a transistor of one embodiment of the present invention;

FIG. 17 A diagram showing an energy band structure of an oxide;

FIG. 18 A cross-sectional view illustrating a structure of a memory device of one embodiment of the present invention;

FIG. 19 A cross-sectional view illustrating a structure of a memory device of one embodiment of the present invention;

FIG. 20 A cross-sectional view illustrating a structure of a memory device of one embodiment of the present invention;

FIG. 21 A cross-sectional view illustrating a structure of a memory device of one embodiment of the present invention;

FIG. 22 A cross-sectional view illustrating a structure of a memory device of one embodiment of the present invention;

FIG. 23 A cross-sectional view illustrating a structure of a memory device of one embodiment of the present invention;

FIG. 24 A block diagram illustrating a structure example of a memory device of one embodiment of the present invention;

FIG. 25 Circuit diagrams illustrating structure examples of a memory device of one embodiment of the present invention;

FIG. 26 A block diagram illustrating a structure example of a memory device of one embodiment of the present invention;

FIG. 27 A block diagram and a circuit diagram illustrating a structure example of a memory device of one embodiment of the present invention;

FIG. 28 Block diagrams illustrating a structure example of a semiconductor device of one embodiment of the present invention;

FIG. 29 A block diagram and a circuit diagram illustrating a structure example of a semiconductor device of one embodiment of the present invention and a timing chart showing an operation example of the semiconductor device;

FIG. 30 A block diagram illustrating a structure example of a semiconductor device of one embodiment of the present invention;

FIG. 31 A circuit diagram illustrating a structure example of a semiconductor device of one embodiment of the present invention and a timing chart showing an operation example of the semiconductor device;

FIG. 32 A block diagram illustrating a configuration example of an AI system of one embodiment of the present invention;

FIG. 33 Block diagrams illustrating application examples of an AI system of one embodiment of the present invention;

FIG. 34 A schematic perspective view illustrating a configuration example of an IC incorporating an AI system of one embodiment of the present invention;

FIG. 35 Top views of a semiconductor wafer of one embodiment of the present invention;

FIG. 36 A flow chart and a schematic perspective view showing an example of a fabricating process of an electronic component;

FIG. 37 Diagrams each illustrating an electronic device of one embodiment of the present invention;

FIG. 38 Graphs showing I_{d}-V_{g} characteristics in Example;

FIG. 39 Diagrams illustrating layouts of transistors in Example;

FIG. 40 Graphs showing +GBT stress time dependence of ΔI_{ds} in Example;

FIG. 41 Graphs showing +GBT stress time dependence of ΔI_{ds} in Example;

FIG. 42 Graphs showing +GBT stress time dependence of ΔVₛₕ in Example;

FIG. 43 Graphs showing +GBT stress time dependence of ΔVₛₕ in Example;

FIG. 44 Graphs showing correlation between ΔVₛₕ and Initial Vₛₕ in Example;

FIG. 45 Graphs showing correlation between ΔVₛₕ and Initial Vₛₕ in Example;

FIG. 46 Graphs showing a cumulative relative frequency of ΔVₛₕ in Example.

### MODE FOR CARRYING OUT THE INVENTION

Hereinafter, embodiments will be described with reference to drawings. Note that the embodiments can be implemented with many different modes, and it will be readily appreciated by those skilled in the art that modes and details can be changed in various ways without departing from the spirit and scope thereof. Thus, the present invention should not be interpreted as being limited to the following description of the embodiments.

In the drawings, the size, the layer thickness, or the region is exaggerated for clarity in some cases. Therefore, they are not limited to the illustrated scale. Note that the drawings are schematic views showing ideal examples, and embodiments of the present invention are not limited to shapes or values shown in the drawings. Furthermore, in the drawings, the same portions or portions having similar functions are denoted by the same reference numerals in different drawings, and repeated description thereof is omitted. Furthermore, the same hatch pattern is used for the portions having similar functions, and the portions are not especially denoted by reference numerals in some cases.

In this specification and the like, the ordinal numbers such as first and second are used for convenience and do not denote the order of steps or the stacking order of layers. Therefore, for example, description can be made even when “first” is replaced with “second”, “third”, or the like, as appropriate. In addition, the ordinal numbers in this specification and the like do not correspond to the ordinal numbers which are used to specify one embodiment of the present invention in some cases.

In this specification, terms for describing arrangement, such as “over” and “under”, are used for convenience in describing a positional relation between components with reference to drawings. Furthermore, the positional relation between components is changed as appropriate in accordance with a direction in which each component is described. Thus, there is no limitation on terms used in this specification, and description can be made appropriately depending on the situation.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. An imaging device, a display device, a liquid crystal display device, a light-emitting device, an electro-optical device, a power generation device (including a thin film solar cell, an organic thin film solar cell, and the like), and an electronic device may each include a semiconductor device.

In this specification and the like, a transistor is an element having at least three terminals of a gate, a drain, and a source. In addition, the transistor includes a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when transistors having different polarities are employed or a direction of current is changed in circuit operation, for example. Therefore, the terms “source” and “drain” are used interchangeably in some cases in this specification and the like.

Note that in this specification and the like, a silicon oxynitride is a film in which oxygen content is higher than the nitrogen content in its composition. A silicon oxynitride film is preferably a film that contains, for example, oxygen, nitrogen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively. A silicon nitride oxide film is a film in which nitrogen content is higher than oxygen content in its composition. A silicon nitride oxide film preferably contains nitrogen, oxygen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively.

In this specification and the like, the term “film” and the term “layer” can be interchanged with each other. For example, the term “conductive layer” can be changed into the term “conductive film” in some cases. For another example, the term “insulating film” can be changed into the term “insulating layer” in some cases.

In addition, unless otherwise specified, transistors described in this specification and the like are field-effect transistors. Furthermore, unless otherwise specified, transistors described in this specification and the like are n-channel transistors. Thus, unless otherwise specified, the threshold voltage (also referred to as “Vₜₕ”) is higher than 0 V.

In this specification and the like, “parallel” indicates a state where two straight lines are placed at an angle of greater than or equal to −10° and less than or equal to 10°. Thus, the case where the angle is greater than or equal to −5° and less than or equal to 5° is also included. In addition, the term “substantially parallel” indicates a state where two straight lines are placed at an angle of greater than or equal to −30° and less than or equal to 30°. Moreover, “perpendicular” indicates a state where two straight lines are placed at an angle of greater than or equal to 80° and less than or equal to 100°. Thus, the case where the angle is greater than or equal to 85° and less than or equal to 95° is also included. Furthermore, “substantially perpendicular” indicates a state where two straight lines are placed at an angle of greater than or equal to 60° and less than or equal to 120°.

In this specification, in the case where a crystal is a trigonal crystal or a rhombohedral crystal, the crystal is regarded as a hexagonal crystal system.

In the case where there is an explicit description, X and Y are connected, in this specification and the like, for example, the case where X and Y are electrically connected, X and Y are functionally connected, and X and Y are directly connected are disclosed in this specification and the like. Accordingly, without being limited to a predetermined connection relation, for example, a connection relation shown in drawings or texts, a connection relation other than one shown in drawings or texts is included in the drawings or the texts.

Here, X and Y each denote an object (for example, a device, an element, a circuit, a wiring, an electrode, a terminal, a conductive film, a layer, or the like).

An example of the case where X and Y are directly connected is the case where an element that allows an electrical connection between X and Y (for example, a switch, a transistor, a capacitor, an inductor, a resistor, a diode, a display element, a light-emitting element, a load, or the like) is not connected between X and Y, and is the case where X and Y are connected without the element that allows the electrical connection between X and Y (for example, a switch, a transistor, a capacitor, an inductor, a resistor, a diode, a display element, a light-emitting element, a load, or the like) provided therebetween.

An example of the case where X and Y are electrically connected is the case where one or more elements that allows an electrical connection between X and Y (for example, a switch, a transistor, a capacitor, an inductor, a resistor, a diode, a display element, a light-emitting element, a load, or the like) can be connected between X and Y. Note that a switch has a function of being controlled to be turned on or off. That is, a switch has a function of being in a conduction state (on state) or non-conduction state (off state) to control whether or not current flows. Alternatively, the switch has a function of selecting and changing a current path. Note that the case where X and Y are electrically connected includes the case where X and Y are directly connected.

An example of the case where X and Y are functionally connected is the case where one or more circuits that allow functional connection between X and Y (for example, a logic circuit (an inverter, a NAND circuit, a NOR circuit, or the like), a signal converter circuit (a DA converter circuit, an AD converter circuit, a gamma correction circuit, or the like), a potential level converter circuit (a power supply circuit (for example, a step-up circuit, a step-down circuit, or the like), a level shifter circuit for changing the potential level of a signal, or the like), a voltage source, a current source, a switching circuit, an amplifier circuit (a circuit capable of increasing signal amplitude, the amount of current, or the like, an operational amplifier, a differential amplifier circuit, a source follower circuit, a buffer circuit, or the like), a signal generator circuit, a memory circuit, a control circuit, or the like) can be connected between X and Y. Note that even if another circuit is sandwiched between X and Y, for example, X and Y are regarded as being functionally connected in the case where a signal output from Xis transmitted to Y. Note that the case where X and Y are functionally connected includes the case where X and Y are directly connected and the case where X and Y are electrically connected.

Note that in the case where there is an explicit description X and Y are electrically connected, the case where X and Y are electrically connected (that is, the case where X and Y are connected with another element or another circuit sandwiched therebetween), the case where X and Y are functionally connected (that is, the case where X and Y are functionally connected with another circuit sandwiched therebetween), and the case where X and Y are directly connected (that is, the case where X and Y are connected without another element or another circuit sandwiched therebetween) are disclosed in this specification and the like. That is, in the case where there is an explicit description “being electrically connected”, the same contents as the case where there is only an explicit description “being connected”, are disclosed in this specification and the like.

Note that, in the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1, another part of Z1 is directly connected to X, a drain (or a second terminal or the like) of the transistor is directly connected to one part of Z2, and another part of Z2 is directly connected to Y, for example, any of the following expressions can be used.

For example, the expression “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order” can be used. Alternatively, the expression “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order” can be used. Alternatively, the expression “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order” can be used. When the connection order in a circuit configuration is defined by using an expression similar to these examples, a source (or a first terminal or the like) and a drain (or a second terminal or the like) of a transistor can be distinguished from each other to specify the technical scope.

Alternatively, as another expression, the expression “a source (or a first terminal or the like) of a transistor is electrically connected to X through at least a first connection path, the first connection path does not include a second connection path, the second connection path is a path through the transistor, between the source (or the first terminal or the like) of the transistor and a drain (or a second terminal or the like) of the transistor, the first connection path is a path through Z1, the drain (or the second terminal or the like) of the transistor is electrically connected to Y through at least a third connection path, the third connection path does not include the second connection path, and the third connection path is path through Z2” can be used. Alternatively, the expression “a source (or a first terminal or the like) of a transistor is electrically connected to X by at least a first connection path through Z1, the first connection path does not include a second connection path, the second connection path includes a connection path through the transistor, a drain (or a second terminal or the like) of the transistor is electrically connected to Y by at least a third connection path through Z2, and the third connection path does not include the second connection path” can also be used. Alternatively, the expression “a source (or a first terminal or the like) of a transistor is electrically connected to X by at least a first electrical path through Z1, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y by at least a third electrical path through Z2, the third electrical path does not include a fourth electrical path, and the fourth electrical path is an electrical path from the drain (or the second terminal or the like) of the transistor to the source (or the first terminal or the like) of the transistor” can be used. When the connection path in a circuit configuration is defined by an expression similar to the above examples, a source (or a first terminal or the like) and a drain (or a second terminal or the like) of a transistor can be distinguished from each other to specify the technical scope.

Note that these expressions are examples and there is no limitation on these expressions. Here, X, Y, Z1, and Z2 are each an object (for example, a device, an element, a circuit, a wiring, an electrode, a terminal, a conductive film, a layer, or the like).

Note that even if a circuit diagram shows that independent components are electrically connected to each other, one component might have functions of a plurality of components. For example, when part of a wiring also functions as an electrode, one conductive film has functions of both of the components, the function of a wiring and the function of an electrode. Thus, electrical connection in this specification also includes such a case where one conductive film has functions of a plurality of components, in its category.

Note that in this specification, a barrier film refers to a film having a function of inhibiting the passage of oxygen and impurities such as hydrogen, and in the case where the barrier film has conductivity, it is referred to as a conductive barrier film in some cases.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, in the case where an OS FET is stated, it can also be referred to as a transistor including an oxide or an oxide semiconductor.

### Embodiment 1

<Structure Example 1 of Semiconductor Device>

An example of a semiconductor device including a transistor 1000 of one embodiment of the present invention is described below.

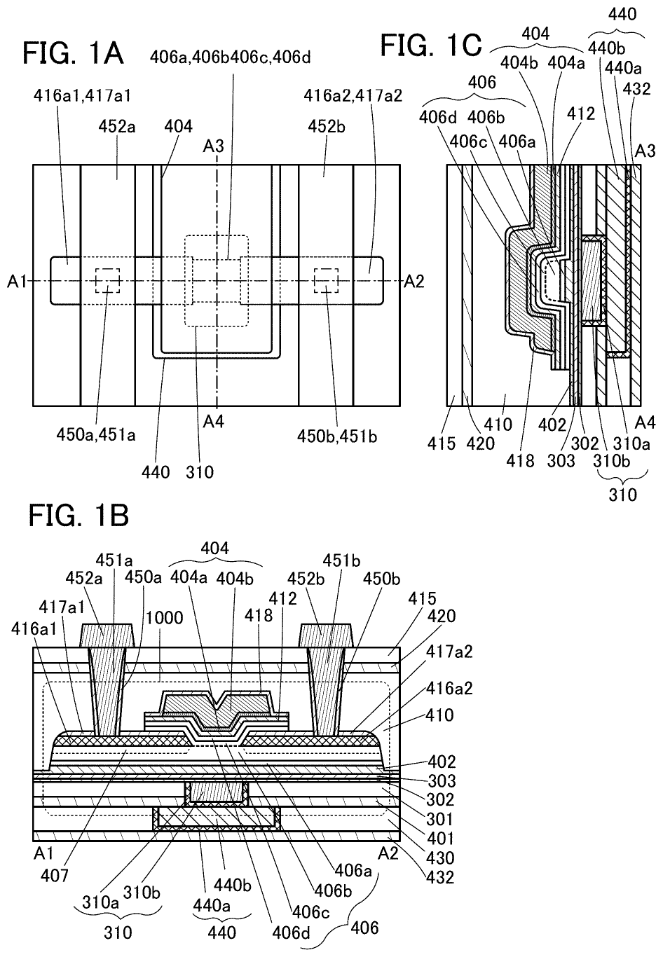

FIG. 1(A) is a top view of a semiconductor device including the transistor 1000. FIG. 1(B) is a cross-sectional view of a portion indicated by a dashed-dotted line A1-A2 in FIG. 1(A), and is a cross-sectional view in the channel length direction of the transistor 1000. FIG. 1(C) is a cross-sectional view of a portion indicated by a dashed-dotted line A3-A4 in FIG. 1(A), and is a cross-sectional view in the channel width direction of the transistor 1000. For clarity of the drawing, some components are not illustrated in the top view of FIG. 1(A).

As illustrated in FIGS. 1(A) to 1(C), the transistor 1000 includes an insulator 402 positioned over a substrate (not illustrated); an oxide 406a positioned over an oxide over the insulator 402; an oxide 406b over the oxide 406a; a conductor 416a1 and a conductor 416a2 that include a region in contact with a top surface of the oxide 406b; regions 407 in the vicinity of an interface where the top surface of the oxide 406b and the conductor 416a1 are in contact with each other and in the vicinity of an interface where the top surface of the oxide 406b and the conductor 416a2 are in contact with each other; a barrier film 417a1 over the conductor 416a1; a barrier film 417a2 over the conductor 416a2; an oxide 406c including regions in contact with a side surface of the conductor 416a1, a side surface of the conductor 416a2, a side surface of the barrier film 417a1, a side surface of the barrier film 417a2, and the top surface of the oxide 406b; an oxide 406d over the oxide 406c; an insulator 412 over the oxide 406d; a conductor 404a including a region that overlaps with the top surface of the oxide 406b with the oxide 406c, the oxide 406d, and the insulator 412 therebetween; a conductor 404b over the conductor 404a; and an insulator 418 over the conductor 404b.

Hereinafter the oxide 406a, the oxide 406b, the oxide 406c, and the oxide 406d are collectively referred to as an oxide 406 in some cases. Furthermore, the conductor 404a and the conductor 404b are collectively referred to as a conductor 404 in some cases. Note that although the transistor 1000 has a structure in which the conductor 404a and the conductor 404b are stacked, the present invention is not limited thereto. For example, a structure in which only the conductor 404b is provided may be employed.

Furthermore, the semiconductor device includes an insulator 410 positioned to cover the transistor 1000; an insulator 420 over the insulator 410; and an insulator 415 over the insulator 420. In addition, a first opening reaching the conductor 416a1 through the insulator 415, the insulator 420, the insulator 410, and the barrier film 417a1, and a second opening reaching the conductor 416a2 through the insulator 415, the insulator 420, the insulator 410, and the barrier film 417a2 are included. In addition, the first opening includes an insulator 450a that is formed in contact with an inner wall of the first opening, and a conductor 451a formed on the inner side of the insulator 450a, and the second opening includes an insulator 450b that is formed in contact with an inner wall of the second opening, and a conductor 451b formed on the inner side of the insulator 450b. In addition, a conductor 452a that is over the insulator 415 and includes a region in contact with the conductor 451a, and a conductor 452b that is over the insulator 415 and includes a region in contact with the conductor 451b are included.

As for the insulator 420, for example, when the insulator 420 is deposited by a sputtering method using plasma containing oxygen, oxygen can be added to the insulator 410 serving as a base layer of the insulator 420. The added oxygen becomes excess oxygen.

The insulator 450a and the insulator 450b preferably have a function of inhibiting the passage of oxygen and impurities such as hydrogen and water. With such a function, excess oxygen contained in the insulator 410 can be prevented from being absorbed by the conductor 451a and the conductor 451b, whereby the excess oxygen can be efficiently supplied to the oxide 406 to repair defects in the oxide 406. Furthermore, impurities such as hydrogen and water contained in the conductor 451a and the conductor 451b can be prevented from diffusing outward, whereby an increase in defects in the oxide 406 due to diffusion of the impurities into the oxide 406 can be prevented.

Silicon nitride, silicon nitride oxide, silicon oxynitride, aluminum nitride, aluminum nitride oxide, or the like is preferably used for the insulator 450a and the insulator 450b.

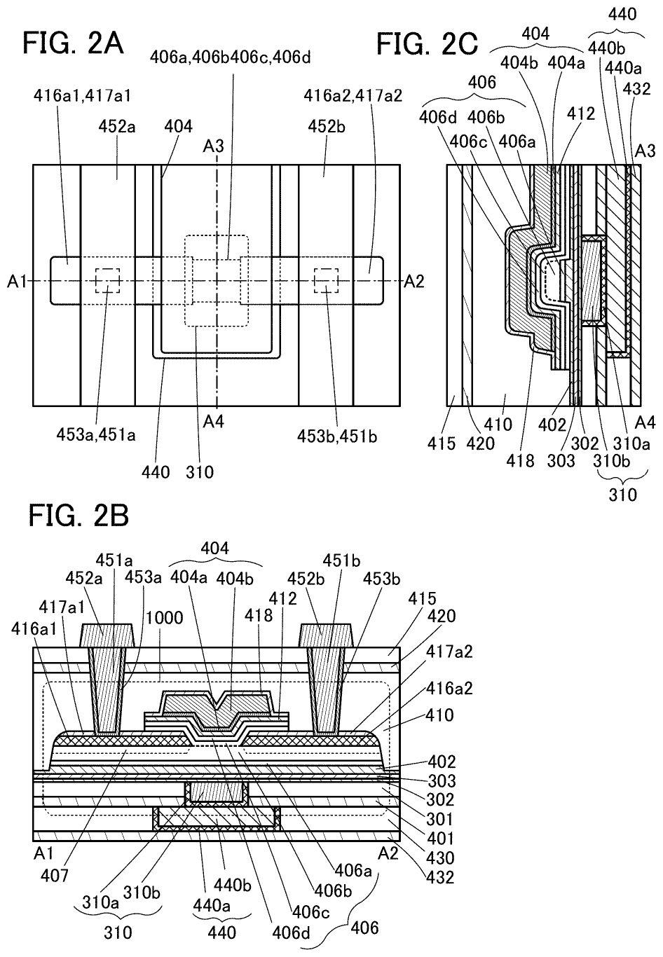

Alternatively, the insulator 450a and the insulator 450b may be replaced with a conductor 453a and a conductor 453b that have a function of inhibiting the passage of oxygen and impurities such as hydrogen and water. With the use of a conductor having such a function, the conductor 453a and the conductor 453b have an effect similar to those of the insulator 450a and the insulator 450b described above. Tantalum, tantalum nitride, titanium, titanium nitride, ruthenium, or ruthenium oxide can be used for the conductor 453a and the conductor 453b, for example. FIG. 2 illustrates an example in which the insulator 450a and the insulator 450b are replaced with the conductor 453a and the conductor 453b, respectively (see FIGS. 2(A) to 2(C)).

The transistor 1000 may have a structure in which an insulator 432 is positioned over the substrate. A structure may also be employed in which an insulator 430 positioned over the insulator 432 and a conductor 440 positioned to be embedded in the insulator 430 are included. A structure may also be employed in which an insulator 401 is positioned over the insulator 430 and an insulator 301 is positioned over the insulator 401. The transistor 1000 may have a structure in which a conductor 310 positioned to be embedded in the insulator 401 and the insulator 301 is included. Here, the conductor 310 is preferably provided over and in contact with the conductor 440 and positioned to overlap with the oxide 406 and the conductor 404. A structure may also be employed in which an insulator 302 positioned over the insulator 301 and the conductor 310, and an insulator 303 positioned over the insulator 302 are included, in which case the insulator 402 is positioned over the insulator 303.

In the conductor 440, a conductor 440a is formed in contact with an inner wall of an opening in the insulator 430, and a conductor 440b is formed on the inner side. Here, the level of the top surfaces of the conductor 440a and the conductor 440b and the level of the top surface of the insulator 430 can be substantially the same. Note that although the transistor 1000 has a structure in which the conductor 440a and the conductor 440b are stacked, the present invention is not limited thereto. For example, a structure in which only the conductor 440b is provided may be employed.

In the conductor 310, a conductor 310a is formed in contact with an inner wall of an opening in the insulator 401 and the insulator 301, and a conductor 310b is formed on the inner side. Thus, a structure in which the conductor 310a is in contact with the conductor 440b is preferable. Here, the level of the top surfaces of the conductor 310a and the conductor 310b and the level of the top surface of the insulator 301 can be substantially the same. Note that although the transistor 1000 has a structure in which the conductor 310a and the conductor 310b are stacked, the present invention is not limited thereto. For example, a structure in which only the conductor 310b is provided may be employed.

The conductor 404 is positioned to extend in the channel width direction. In addition, the conductor 404 can function as a top gate and the conductor 310 can function as a back gate. The potential of the back gate may be the same as the potential of the top gate, or may be a ground potential or a given potential. By changing the potential of the back gate independently of that of the top gate, the threshold voltage of the transistor can be changed.

The conductor 440 extends in the channel width direction in a manner similar to that of the conductor 404, and functions as a wiring through which a potential is applied to the conductor 310, i.e., the back gate. Here, when the conductor 310 that is embedded in the insulator 401 and the insulator 301 is provided to be stacked over the conductor 440 functioning as the wiring for the back gate, the insulator 401, the insulator 301, and the like are provided between the conductor 440 and the conductor 404, whereby the parasitic capacitance between the conductor 440 and the conductor 404 can be reduced and the withstand voltage can be increased. The reduction in the parasitic capacitance between the conductor 440 and the conductor 404 can improve the switching speed of the transistor, so that the transistor can have high frequency characteristics. Furthermore, the increase in the withstand voltage between the conductor 440 and the conductor 404 can improve the reliability of the transistor 1000. Thus, the thicknesses of the insulator 401 and the insulator 301 are preferably large. Note that the extending direction of the conductor 440 is not limited thereto; for example, the conductor 440 may extend in the channel length direction of the transistor 1000.

In FIGS. 1(B) and 1(C), end portions of the insulator 418, end portions of the insulator 412, and end portions of the oxide 406d and the oxide 406c are aligned and positioned over the barrier film 417a1 and the barrier film 417a2 in the channel length direction, whereas they are positioned over the insulator 402 on one side of the channel width direction.

In the transistor 1000, the conductor 404 has a function of a first gate electrode. The conductor 404 can have a stacked-layer structure of the conductor 404a and the conductor 404b. For example, when the conductor 404a having a function of inhibiting the passage of oxygen is deposited in a layer under the conductor 404b, oxidation of the conductor 404b can be prevented. Alternatively, the conductor 404 preferably includes a metal having resistance to oxidation. Alternatively, an oxide conductor or the like may be used. The insulator 412 has a function of a first gate insulator.

The conductor 416a1 and the conductor 416a2 have a function of a source electrode and a drain electrode. The conductor 416a1 and the conductor 416a2 can each have a stacked-layer structure including a conductor having a function of inhibiting the passage of oxygen. For example, when a conductor having a function of inhibiting the passage of oxygen is deposited in an upper layer, oxidation of the conductor 416a1 and the conductor 416a2 can be prevented. Alternatively, the conductor 416a1 and the conductor 416a2 preferably include a metal having resistance to oxidation. Alternatively, an oxide conductor or the like may be used.

The barrier film 417a1 and the barrier film 417a2 each have a function of inhibiting the passage of oxygen and impurities such as hydrogen and water. The barrier film 417a1 is located over the conductor 416a1 and prevents diffusion of oxygen into the conductor 416a1. The barrier film 417a2 is located over the conductor 416a2 and prevents diffusion of oxygen into the conductor 416a2.

In the transistor 1000, the oxide 406b and the oxide 406c include a channel formation region. That is, in the transistor, the resistance of the channel formation region included in the oxide 406b and the oxide 406c can be controlled by a potential applied to the conductor 404. That is, conduction or non-conduction between the conductor 416a1 and the conductor 416a2 can be controlled by the potential applied to the conductor 404.

In addition, the oxide 406b includes the regions 407 in the vicinity of interfaces where the top surface of the oxide 406b and each of the conductor 416a1 and the conductor 416a2 are in contact with each other. The vicinity of the top surface of the oxide 406b is damaged when a conductor to be the conductor 416a1 and the conductor 416a2 is deposited, whereby the region 407 is formed. The regions 407 are low-resistance regions, which is preferable because the contact resistance between the oxide 406b and each of the conductor 416a1 and the conductor 416a2 can be small. The regions 407 can be referred to as n+ regions.

As illustrated in FIG. 1(C), the conductor 404 having a function of the first gate electrode is provided to cover the whole oxide 406b, part of the oxide 406c, and part of the oxide 406d with the insulator 412 having a function of the first gate insulator therebetween. Thus, the whole oxide 406b, part of the oxide 406c, and part of the oxide 406d can be electrically surrounded by an electric field of the conductor 404 having a function of the first gate electrode. Such a transistor structure in which a channel formation region is electrically surrounded by an electric field of a first gate electrode is referred to as a surrounded channel (s-channel) structure.

Furthermore, as illustrated in FIG. 1(B), the conductor 416a1 and the conductor 416a2 which have a function of the source electrode and the drain electrode are sandwiched between the oxide 406b and the oxide 406c, and such a structure can increase the area in which the oxides are in contact with the source electrode and the drain electrode. Therefore, the contact area between the oxides 406b and 406c and each of the conductor 416a1 and the conductor 416a2 is large, which is preferable because the contact resistance can be low.

The channel formation region of the transistor 1000 is positioned between the source electrode and the drain electrode, and the height from a bottom surface of the oxide 406a to each of the channel formation region and the conductor 416a1 and the conductor 416a2, which have a function of the source electrode and the drain electrode, is substantially the same. Such a structure is preferable because a step that inhibits the current from flowing through the channel formation region between the source electrode and the drain electrode when the transistor 1000 is in an on state can be eliminated or reduced, whereby a high on-state current can be obtained.

A metal oxide functioning as an oxide semiconductor (hereinafter, also referred to as an oxide semiconductor) is preferably used as the oxide 406. However, silicon (including strained silicon), germanium, silicon germanium, silicon carbide, gallium arsenide, aluminum gallium arsenide, indium phosphide, gallium nitride, an organic semiconductor, or the like may be used instead of the oxide.

A transistor using an oxide semiconductor has an extremely low leakage current in a non-conduction state; thus, a semiconductor device with low power consumption can be provided. In addition, an oxide semiconductor can be deposited by a sputtering method or the like, and thus can be used for a transistor included in a highly integrated semiconductor device.

However, the transistor using an oxide semiconductor is likely to have its electrical characteristics changed by impurities and oxygen vacancies in the oxide semiconductor, and accordingly the reliability deteriorates, in some cases. Furthermore, hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Accordingly, a transistor using an oxide semiconductor including oxygen vacancies is likely to have normally-on characteristics. Thus, it is preferable that oxygen vacancies in the oxide semiconductor be reduced as much as possible.

An oxide semiconductor preferably contains at least indium or zinc. In particular, indium and zinc are preferably contained. Moreover, aluminum, gallium, yttrium, tin, or the like is preferably contained in addition to them. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the oxide semiconductor is an In-M-Zn oxide that contains indium, an element M, and zinc is considered. Note that the element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, magnesium, and the like. Note that a plurality of the above-described elements may be combined as the element M.

Note that in this specification and the like, a metal oxide containing nitrogen is also collectively referred to as a metal oxide in some cases. Alternatively, a metal oxide containing nitrogen may be referred to as a metal oxynitride.

Here, each of the In-M-Zn oxides used for the oxide 406b and the oxide 406c preferably contains more In atoms than element M atoms, for example. In that case, each of the oxide 406b and the oxide 406c includes a region in which the proportion of the element M is lower than that of In. With such an oxide, the mobility of the transistor 1000 increases and the carrier density also increases.

Here, for example, oxide semiconductors with the same composition or similar compositions are preferably used for the oxide 406b and the oxide 406c. Alternatively, for example, the oxide 406b and the oxide 406c are preferably deposited using the same sputtering target material. Alternatively, for example, the oxide 406b and the oxide 406c are preferably deposited using sputtering target materials with substantially the same compositions. Alternatively, for example, the oxide 406b and the oxide 406c are preferably deposited under substantially the same process condition (e.g., deposition temperature and the proportion of an oxygen gas).

Alternatively, for example, the oxide 406b and the oxide 406c may be deposited using sputtering target materials with different compositions. For example, when the process conditions (e.g., deposition temperature and the proportion of an oxygen gas) for the oxide 406b and the oxide 406c are adjusted as appropriate, oxide semiconductors with the same composition or similar compositions can be deposited for the oxide 406b and the oxide 406c, in some cases. In some cases, it is preferable to use, for the oxide 406b and the oxide 406c, oxide semiconductors whose compositions are as similar to each other as much as possible; however, desired thicknesses and functions of the oxides are different and thus the optimum deposition conditions are also different in some cases. For this reason, the oxide 406b and the oxide 406c are preferably deposited using sputtering target materials with different compositions in some cases, because the compositions of the oxide 406b and the oxide 406c can be similar to each other compared with the case where sputtering target materials with the same composition or similar compositions are used.

When the oxide 406b and the oxide 406c have the same composition or similar compositions, the band gap and the electron affinity of the oxide 406b and the band gap and the electron affinity of the oxide 406c are the same, or the difference therebetween is small. In particular, when not only the compositions but also the process conditions are substantially the same, the band gap and the electron affinity of the oxide 406b and the band gap and the electron affinity of the oxide 406c are the same, or the difference therebetween is small. Accordingly, the interface state density between the oxide 406b and the oxide 406c can be reduced. The reduced interface state density can prevent a decrease in on-state current of the transistor 1000. Note that the electron affinity can be also called energy value E_{c} of the conduction band minimum. A difference between E_{c} of the oxide 406b and E_{c} of the oxide 406c is preferably small, and preferably greater than or equal to 0 eV and less than or equal to 0.15 eV, further preferably greater than or equal to 0 V and 0.07 eV. In addition, a difference between the band gap of the oxide 406b and the band gap of the oxide 406c is preferably small, preferably less than or equal to 0.15 eV.

In addition, for example, oxide semiconductors with different band gaps and E_{c}s are preferably used for the oxide 406c and the oxide 406d. Specifically, for example, it is preferable that E_{c} of the oxide 406d be smaller than E_{c} of the oxide 406c, and the difference between E_{c} of the oxide 406d and E_{c} of the oxide 406c be greater than or equal to 0.2 eV and less than or equal to 0.4 eV. Furthermore, it is preferable that the band gap of the oxide 406d be larger than the band gap of the oxide 406c, and the difference between the band gap of the oxide 406d and the band gap of the oxide 406c be greater than or equal to 0.4 eV and less than or equal to 0.7 eV. With such a structure, a buried channel can be achieved. That is, a path through which larger amount of current flows is formed in the vicinity of the interface between the oxide 406c and the oxide 406d, not in the vicinity of the interface between the oxide 406d and the insulator 412. Accordingly, in the current path, the number of trap states in the vicinity of the interface can be reduced. As a result, the on-state current can be increased and the reliability can be improved.

Each of the In-M-Zn oxides used for the oxide 406a and the oxide 406d preferably contains more element M atoms than In atoms, for example. In that case, the oxide 406b and the oxide 406c each include a region in which the proportion of the element M is higher than that of In. When the oxide 406a and the oxide 406d have such a composition, the band gap and E_{c} of the oxide 406a and the band gap and E_{c} of the oxide 406b can be different. The band gap and E_{c} of the oxide 406c and the band gap and E_{c} of the oxide 406d can also be different.

Alternatively, for example, the oxide 406c and the oxide 406d may be deposited using sputtering target materials with substantially the same compositions under different process conditions. Alternatively, the oxide 406c and the oxide 406d may be deposited using the same sputtering target material under different process conditions. Thus, the band gap and E_{c} of the oxide 406c and the band gap and E_{c} of the oxide 406d can be different in some cases.

Alternatively, for example, the oxide 406b, the oxide 406c, and the oxide 406d may be deposited using sputtering target materials with substantially the same compositions under different process conditions. For example, the oxide 406b and the oxide 406c may be deposited under substantially the same process conditions, and the oxide 406c and the oxide 406d may be deposited under different process conditions.

Alternatively, for example, oxide semiconductors with substantially the same compositions may be used for the oxide 406a and the oxide 406d. Alternatively, for example, the oxide 406a and the oxide 406d may be deposited using the same sputtering target material.

Alternatively, for example, the oxide 406a and the oxide 406d may be deposited using sputtering target materials with substantially the same compositions. Alternatively, for example, the oxide 406a and the oxide 406d may be deposited under substantially the same process conditions (e.g., deposition temperature and the proportion of an oxygen gas). Alternatively, for example, the oxide 406a and the oxide 406d may be deposited using sputtering target materials with different compositions. For example, when the process conditions (e.g., deposition temperature and the proportion of an oxygen gas) for the oxide 406a and the oxide 406d are adjusted as appropriate, oxide semiconductors with the same composition or similar compositions can be deposited for the oxide 406a and the oxide 406d, in some cases.

When the oxide 406a and the oxide 406d have the same composition or similar compositions, the band gap and E_{c} of the oxide 406a and the band gap and E_{c} of the oxide 406d are the same, or the difference therebetween is small. In particular, when not only the compositions but also the process conditions are substantially the same, the band gap and E_{c} of the oxide 406a and the band gap and E_{c} of the oxide 406d are the same, or the difference therebetween is small. A difference between E_{c} of the oxide 406a and E_{c} of the oxide 406d is preferably small, and preferably greater than or equal to 0 eV and less than or equal to 0.15 eV, further preferably greater than or equal to 0 V and 0.07 eV. In addition, a difference between the band gap of the oxide 406a and the band gap of the oxide 406d is preferably small, preferably less than or equal to 0.15 eV.

The transistor 1000 has a structure in which the oxide 406a and the oxide 406d, which have wider band gaps than the oxide 406b and the oxide 406c, sandwich the oxide 406b and the oxide 406c, whereby a buried channel can be achieved. That is, in such a structure, a path through which larger amount of current flows is formed in the vicinity of the interface between the oxide 406a and the oxide 406c and in the vicinity of the interface between the oxide 406c and the oxide 406d. Accordingly, in the current path, trap states in the vicinity of each of the interfaces can be reduced. As a result, the on-state current can be increased and the reliability can be improved. Note that in these cases, for the oxide 406d and the oxide 406b, oxide semiconductors with different compositions may be used or oxide semiconductors with substantially the same compositions may be used.

Alternatively, for example, the oxide 406a, the oxide 406b, the oxide 406c, and the oxide 406d may be deposited using sputtering target materials with substantially the same compositions under different process conditions. For example, the oxide 406b and the oxide 406c may be deposited under substantially the same process conditions, and the oxide 406a and the oxide 406d may be deposited under substantially the same compositions, and the oxide 406a and the oxide 406b may be deposited under different process conditions.

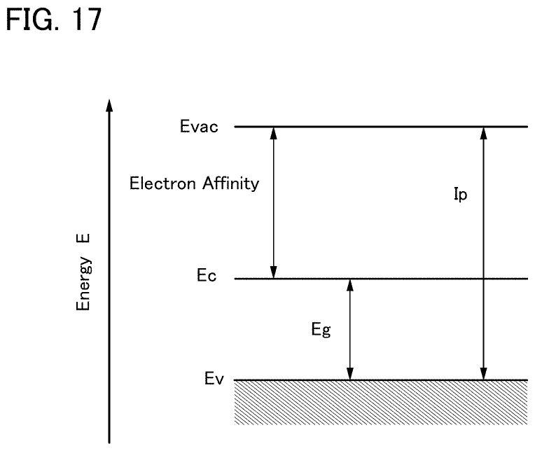

As shown in FIG. 17, the electron affinity or E_{c} can be obtained from a band gap E_{g} and an ionization potential Iₚ, which is a difference between a vacuum level E_{vac} and an energy Eᵥ of the valence band maximum. The ionization potential Iₚ can be measured using, for example, an ultraviolet photoelectron spectroscopy (UPS) apparatus. The band gap E_{g} can be measured using, for example, a spectroscopic ellipsometer.

In the structure of the transistor 1000, process damage might be caused on a top surface or a side surface of the oxide 406b when the source electrode and the drain electrode are formed. That is, a defect due to the process damage might be caused in the vicinity of the interface between the oxide 406b and the oxide 406c. When oxide semiconductors with the same composition or similar compositions are used for the oxide 406b and the oxide 406c, the difference between E_{c} of the oxide 406b and E_{c} of the oxide 406c is the same or small; thus, a channel formation region is formed not only in the vicinity of the interface between the oxide 406b and the oxide 406c but also in the vicinity of the interface between the oxide 406c and the oxide 406d whose E_{c} is smaller than that of the oxide 406c.

Therefore, influence of the vicinity of the interface between the oxide 406b subjected to the process damage and the oxide 406c can be small. Furthermore, an oxide to be the oxide 406c, an oxide to be the oxide 406d, and an insulator to be the insulator 412 having a function of the first gate insulator are deposited to be stacked, and then the oxide to be the oxide 406c, the oxide to be the oxide 406d, and the insulator to be the insulator 412 are processed to form the oxide 406c, the oxide 406d, and the insulator 412, in which case the vicinity of the interface between the oxide 406c and the oxide 406d and the vicinity of the interface between the oxide 406d and the insulator 412 are not influenced by the process damage, which is favorable.

Accordingly, the reliability of the transistor 1000 can be improved. In addition, since the whole oxide 406b, part of the oxide 406c, and part of the oxide 406d are surrounded by the electric field of the conductor 404, current in a non-conduction state (off-state current) can be reduced.

In the transistor 1000, the conductor 404 having a function of the first gate electrode includes regions overlapping with each of the conductor 416a1 and the conductor 416a2 having a function of the source electrode and the drain electrode, whereby parasitic capacitance formed between the conductor 404 and the conductor 416a1 and parasitic capacitance formed between the conductor 404 and the conductor 416a2 are included.

The structure of the transistor 1000 including the barrier film 417a1 as well as the insulator 412, the oxide 406c, and the oxide 406d between the conductor 404 and the conductor 416a1 allows a reduction in the parasitic capacitance. Similarly, the structure of the transistor 1000 including the barrier film 417a2 as well as the insulator 412, the oxide 406c, and the oxide 406d between the conductor 404 and the conductor 416a2 allows a reduction in the parasitic capacitance. Thus, the transistor 1000 is a transistor with excellent frequency characteristics.

Furthermore, the above structure of the transistor 1000 allows a reduction or prevention of a leakage current between the conductor 404 and each of the conductor 416a1 and the conductor 416a2 when the transistor 1000 operates, for example, when a potential difference between the conductor 404 and each of the conductor 416a1 and the conductor 416a2 occurs.

As described above, the transistor 1000 has a structure including the oxide 406d. With such a structure, transistors have similar characteristics and high reliability even when included in a circuit with a high arrangement density of transistor per unit area (transistor density) or included in a circuit with a low transistor density. That is, a transistor whose transistor characteristics and transistor reliability have small dependence on the transistor density can be obtained.

For example, when the channel formation region has a high defect density, the reliability of the transistor decreases. In the transistor of one embodiment of the present invention, the oxide 406b and/or the oxide 406c include(s) the channel formation region; thus, it is effective not to form defects in the region in order to improve the reliability.

The small dependence on the transistor density is caused by the use of a composition having a function of further inhibiting the passage of oxygen compared with the oxide 406b and the oxide 406c, which include the channel formation region, for the oxide 406d. For example, when the oxide 406d has a function of inhibiting the passage of oxygen, the oxide 406b and the oxide 406c can be inhibited from being deprived of oxygen by the insulator 412 that has a function of the gate insulating film. Thus, an increase in oxygen vacancies in the oxide 406b and the oxide 406c can be prevented, so that the transistor can have high reliability.

Oxygen is effective to reduce the oxygen vacancies and the carrier density in the oxide 406b and the oxide 406c; however, the oxygen might become a defect and a factor of decrease in reliability depending on its existing form. For example, it is considered that a circuit with a low transistor density might have a larger amount of excess oxygen (a higher concentration of excess oxygen) in the insulator 412 than a circuit with a high transistor density, and thus is in a state where a decrease in reliability due to excess oxygen is likely to occur.

As for the ratio of the element M to In, the oxide 406d has a higher proportion of the element M, specifically a higher proportion of Ga, than the oxide 406b and the oxide 406c, and thus has stronger bonding force to oxygen than the oxide 406b and the oxide 406c. Thus, when the oxide 406d has a function of further inhibiting the passage of oxygen, excess oxygen can be prevented from entering the oxide 406b, the oxide 406c and/or the oxide 406d too much through the insulator 412, so that the above-described decrease in reliability due to the excess oxygen can be prevented. The oxide 406d is less likely to transmit excess oxygen than the insulator 412.

Thus, the transistor 1000 preferably has the above-described structure because it allows the semiconductor device including the transistor 1000 to have a wider range of circuit design flexibility owing to the small dependence of the transistor characteristics and the transistor reliability on the transistor density. Furthermore, a high-performance and highly reliable semiconductor device can be obtained.

<Structure Example 2 of Semiconductor Device>

An example of a semiconductor device including a transistor 1000a of one embodiment of the present invention is described below.

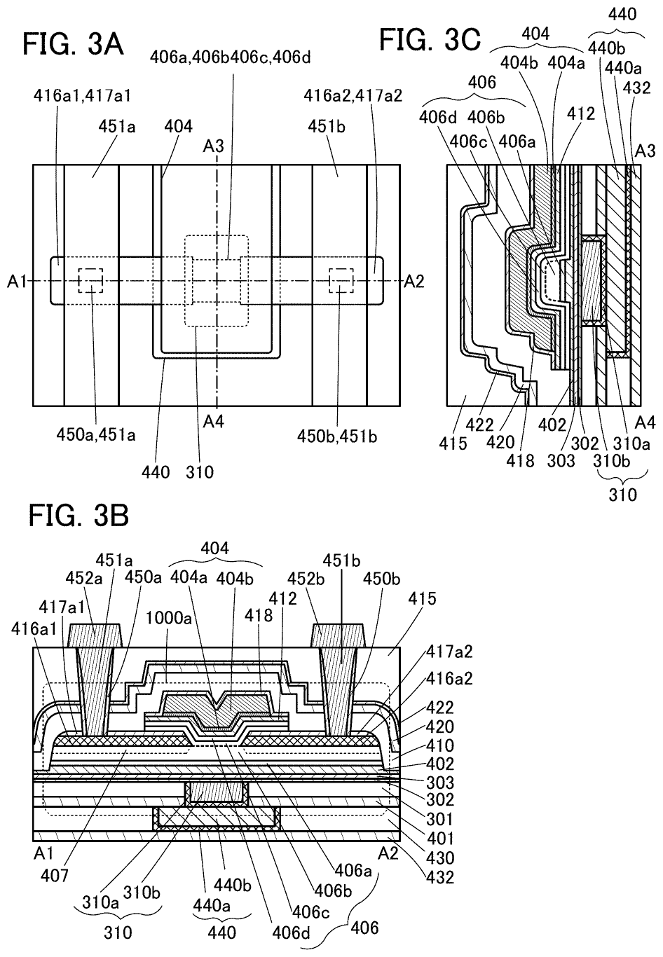

FIG. 3(A) is a top view of a semiconductor device including the transistor 1000a. FIG. 3(B) is a cross-sectional view of a portion indicated by a dashed-dotted line A1-A2 in FIG. 3(A), and is a cross-sectional view in the channel length direction of the transistor 1000a. FIG. 3(C) is a cross-sectional view of a portion indicated by a dashed-dotted line A3-A4 in FIG. 3(A), and is a cross-sectional view in the channel width direction of the transistor 1000a. For clarity of the drawing, some components are not illustrated in the top view of FIG. 3(A).

The semiconductor device is different from the semiconductor device including the transistor 1000 in that a top surface of the insulator 410 covering the transistor 1000a is not planarized and an insulator 422 is provided over the insulator 420.

Since the top surface of the insulator 410 is not planarized in the semiconductor device, coverage with the insulator 420 that is on the top surface of the insulator 410 becomes poor in some cases. Thus, the insulator 422 over the insulator 420 is preferably deposited by an ALD method that enables excellent coverage. Such a film is preferably used because a defect such as a pinhole or a void caused in the insulator 420 can be covered with the insulator 422, in some cases.

With the structure of the transistor 1000a, the surface area in which the insulator 410 containing excess oxygen is in contact with each of the insulator 450a and the insulator 450b can be small. When the surface area is small, the diffusion amount of excess oxygen contained in the insulator 410 into the conductor 451a and the conductor 451b through the insulator 450 and the insulator 450b can be minimized.

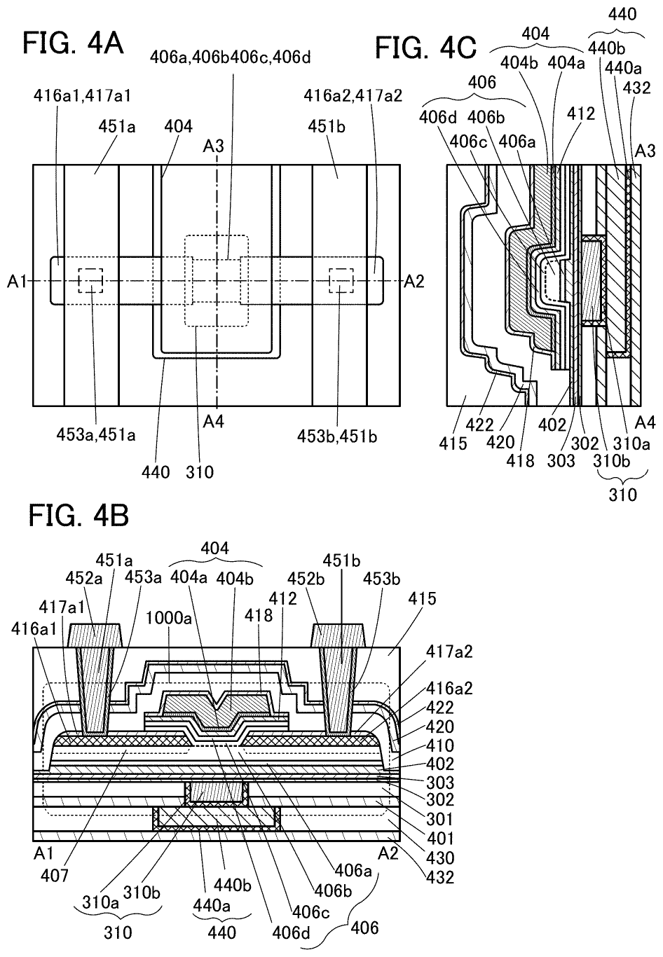

Alternatively, the insulator 450a and the insulator 450b may be replaced with a conductor 453a and a conductor 453b that have a function of inhibiting the passage of oxygen and impurities such as hydrogen and water. With the use of the conductor having such a function, the conductor 453a and the conductor 453b have an effect similar to that of the above-described insulator 450a and the insulator 450b. Tantalum, tantalum nitride, titanium, titanium nitride, ruthenium, or ruthenium oxide can be used for the conductor 453a and the conductor 453b, for example. FIG. 4 illustrates an example in which the insulator 450a and the insulator 450b are replaced with the conductor 453a and the conductor 453b, respectively (see FIGS. 4(A) to 4(C)).

For the other components and effects, refer to the transistor 1000.

<Structure Example 3 of Semiconductor Device>

An example of a semiconductor device including a transistor 1000b of one embodiment of the present invention is described below.

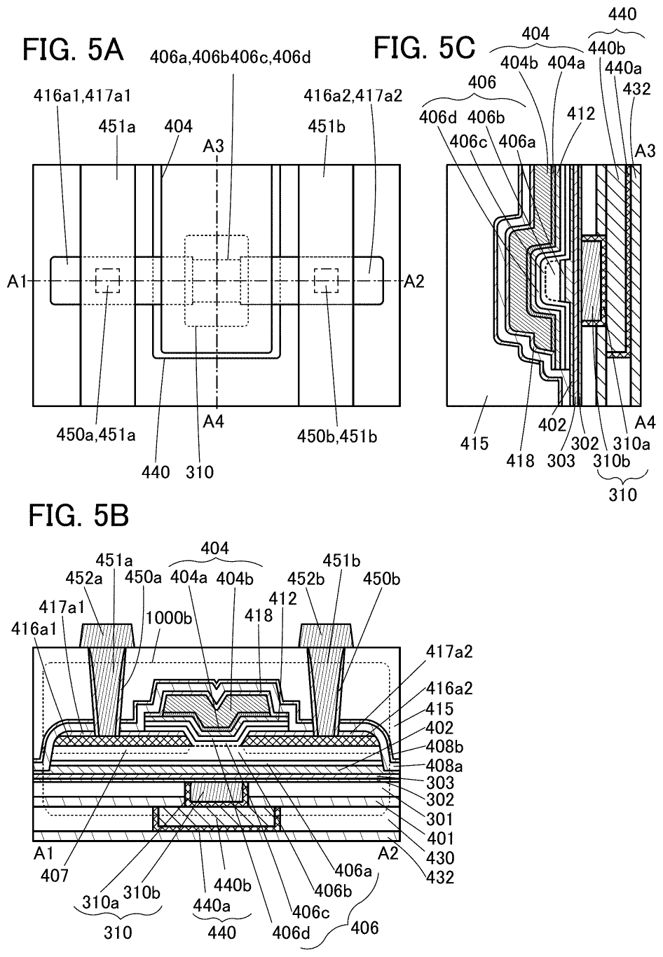

FIG. 5(A) is a top view of a semiconductor device including the transistor 1000b. FIG. 5(B) is a cross-sectional view of a portion indicated by a dashed-dotted line A1-A2 in FIG. 5(A), and is a cross-sectional view in the channel length direction of the transistor 1000b. FIG. 5(C) is a cross-sectional view of a portion indicated by a dashed-dotted line A3-A4 in FIG. 5(A), and is a cross-sectional view in a channel width direction of the transistor 1000b. For clarity of the drawing, some components are not illustrated in the top view of FIG. 5(A).

The semiconductor device is different from the semiconductor device including the transistor 1000 in that an insulator 408a is positioned to cover the transistor 1000b and an insulator 408b is positioned over the insulator 408a, whereas the insulator 410 and the insulator 420 are not provided.

For example, when the insulator 408a is deposited by a sputtering method using plasma containing oxygen, oxygen can be added to the insulator 412 and the insulator 402 serving as base layers of the oxide. The added oxygen becomes excess oxygen. The insulator 408b is preferably deposited by an ALD method that enables excellent coverage. A film deposited by an ALD method is preferably used because a defect such as a pinhole or a void caused in the insulator 408a can be covered with the insulator 408b, in some cases. For the other components and effects, refer to the transistor 1000.

<Structure Example 4 of Semiconductor Device>

An example of a semiconductor device including a transistor 1000c of one embodiment of the present invention is described below.

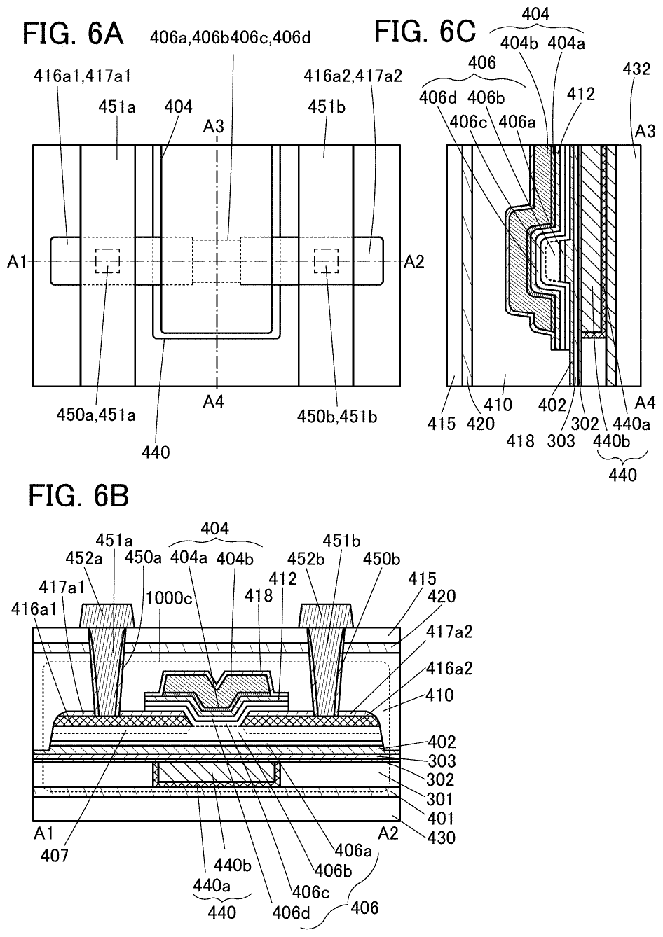

FIG. 6(A) is a top view of a semiconductor device including the transistor 1000c. FIG. 6(B) is a cross-sectional view of a portion indicated by a dashed-dotted line A1-A2 in FIG. 6(A), and is a cross-sectional view in the channel length direction of the transistor 1000c. FIG. 6(C) is a cross-sectional view of a portion indicated by a dashed-dotted line A3-A4 in FIG. 6(A), and is a cross-sectional view in the channel width direction of the transistor 1000c. For clarity of the drawing, some components are not illustrated in the top view of FIG. 6(A).

The transistor 1000c is different from the transistor 1000 in that the conductor 310 is not included. That is, the transistor 1000c has a structure in which the conductor 440 positioned to be embedded in the insulator 301 is included. For the other components and effects, refer to the transistor 1000.

<Structure Example 5 of Semiconductor Device>

An example of a semiconductor device including a transistor 2000 of one embodiment of the present invention is described below. The transistor 2000 includes the oxide 406d and can be fabricated over the same substrate as the semiconductor device including the transistor 1000.

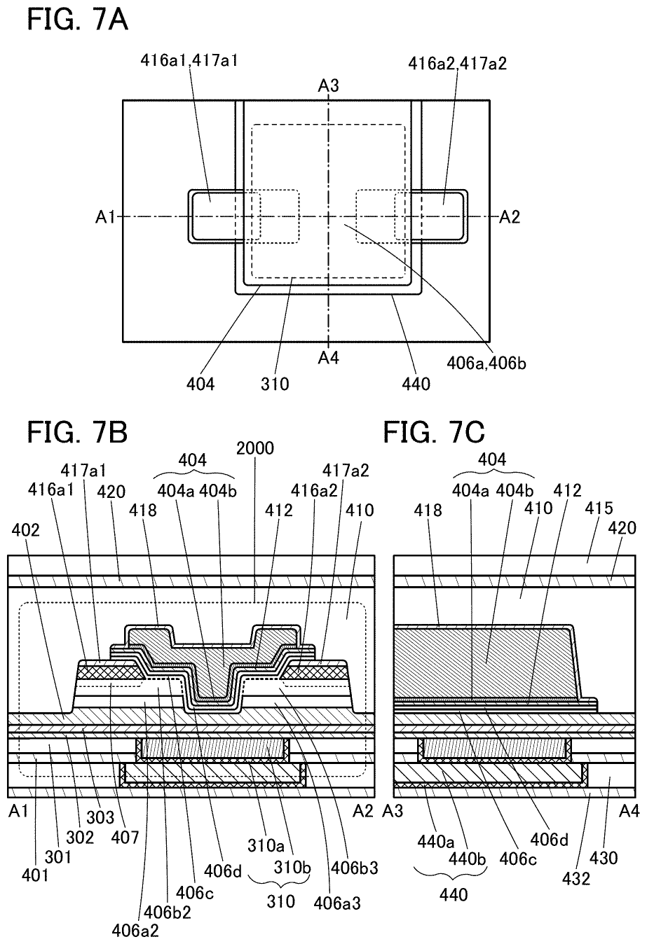

FIG. 7(A) is a top view of a semiconductor device including the transistor 2000. FIG. 7(B) is a cross-sectional view of a portion indicated by a dashed-dotted line A1-A2 in FIG. 7(A), and is a cross-sectional view in the channel length direction of the transistor 2000. FIG. 7(C) is a cross-sectional view of a portion indicated by a dashed-dotted line A3-A4 in FIG. 7(A), and is a cross-sectional view in the channel width direction of the transistor 2000. For clarity of the drawing, some components are not illustrated in the top view of FIG. 7(A).

As illustrated in FIGS. 7(A) to 7(C), the transistor 2000 includes the insulator 402 positioned over the substrate (not illustrated); an oxide 406a2 and an oxide 406a3 over the insulator 402; an oxide 406b2 and an oxide 406b3 over the oxide 406a2 and the oxide 406a3; the conductor 416a1 including a region in contact with a top surface of the oxide 406b3; the conductor 416a2 including a region in contact with a top surface of the oxide 406b2; the regions 407 in the vicinity of the interface where the top surface of the oxide 406b2 and the conductor 416a1 are in contact with each other and in the vicinity of the interface where the top surface of the oxide 406b3 and the conductor 416a2 are in contact with each other; the barrier film 417a1 over the conductor 416a1; the barrier film 417a2 over the conductor 416a2; the oxide 406c including a region in contact with a side surface of the conductor 416a1, a side surface of the conductor 416a2, a top surface and a side surface of the oxide 406b2, a side surface and a top surface of the oxide 406b3, a side surface of the oxide 406a2, and a side surface of the oxide 406a3; the oxide 406d over the oxide 406c; the insulator 412 over the oxide 406d; the conductor 404 over the insulator 412; and the insulator 418 over the conductor 404.

The transistor 2000 may have a structure in which the insulator 432 is positioned over the substrate. A structure may also be employed in which the insulator 430 positioned over the insulator 432 and the conductor 440 positioned to be embedded in the insulator 430 are included. The transistor 2000 may have a structure in which the insulator 401 is positioned over the insulator 430 and the insulator 301 is positioned over the insulator 401. The transistor 2000 may have a structure in which the conductor 310 positioned to be embedded in the insulator 401 and the insulator 301 is included. Here, the conductor 310 is preferably provided over and in contact with the conductor 440 and positioned to overlap with the oxide 406 and the conductor 404. A structure may also be employed in which the insulator 302 positioned over the insulator 301 and the conductor 310, and the insulator 303 positioned over the insulator 302 are included, in which case the insulator 402 is positioned over the insulator 303. Here, the oxide 406a2, the oxide 406b2, the oxide 406b3, the oxide 406c, and the oxide 406d can be referred to as the oxide 406.

In the conductor 440, the conductor 440a is formed in contact with an inner wall of an opening in the insulator 430, and the conductor 440b is formed on the inner side. Here, the level of the top surfaces of the conductor 440a and the conductor 440b and the level of the top surface of the insulator 430 can be substantially the same. Note that although the conductor 440a and the conductor 440b are stacked in the transistor 2000, the present invention is not limited thereto. For example, a structure in which only the conductor 440b is provided may be employed.

In the conductor 310, the conductor 310a is formed in contact with an inner wall of an opening in the insulator 401 and the insulator 301, and the conductor 310b is formed on the inner side. Thus, a structure in which the conductor 310a is in contact with the conductor 440b is preferable. Here, the level of the top surfaces of the conductor 310a and the conductor 310b and the level of the top surface of the insulator 301 can be substantially the same. Note that although the transistor 1000 has a structure in which the conductor 310a and the conductor 310b are stacked, the present invention is not limited thereto. For example, a structure in which only the conductor 310b is provided may be employed.

In the transistor 2000, the conductor 404 has a function of a first gate electrode. Furthermore, the conductor 404 can have a stacked-layer structure including a conductor that has a function of inhibiting the passage of oxygen. For example, when a conductor that has a function of inhibiting the passage of oxygen is deposited in a lower layer, oxidation of the conductor 404 can be prevented. Alternatively, the conductor 404 preferably includes a metal having resistance to oxidation. Alternatively, an oxide conductor or the like may be used. The insulator 412 has a function of a first gate insulator.

The conductor 416a1 and the conductor 416a2 have a function of a source electrode and a drain electrode. In addition, the conductor 416a1 and the conductor 416a2 can each have a stacked-layer structure including a conductor having a function of inhibiting the passage of oxygen. For example, when a conductor having a function of inhibiting the passage of oxygen is deposited in an upper layer, oxidation of the conductor 416a1 and the conductor 416a2 can be prevented. Alternatively, the conductor 416a1 and the conductor 416a2 preferably include a metal having resistance to oxidation. Alternatively, an oxide conductor or the like may be used.

The barrier film 417a1 and the barrier film 417a2 each have a function of inhibiting the passage of oxygen and impurities such as hydrogen. The barrier film 417a1 is located over the conductor 416a1 and prevents diffusion of oxygen into the conductor 416a1. The barrier film 417a2 is located over the conductor 416a2 and prevents diffusion of oxygen into the conductor 416a2.

As illustrated in FIG. 7(B), in the transistor 2000, a layer including the oxide 406a2, the oxide 406b2, and the conductor 416a1 and a layer including the oxide 406a3, the oxide 406b3, and the conductor 416a2 are positioned with a region where part of a top surface of the insulator 402 and the oxide 406c are in contact with each other sandwiched therebetween. Here, a side surface of the layer including the oxide 406a2, the oxide 406b2, and the conductor 416a1 and a side surface of the layer including the oxide 406a3, the oxide 406b3, and the conductor 416a2, which face each other, are each called one side surface, and side surfaces of the layers, which do not face each other, are each called the other side surface.

The oxide 406c includes a region in contact with the one side surface of the conductor 416a1 and a region in contact with the one side surface of the conductor 416a2. Furthermore, the oxide 406c also includes a region in contact with part of a top surface and the one side surface of the oxide 406b2, a region in contact with part of a top surface and the one side surface of the oxide 406b3, a region in contact with the one side surface of the oxide 406a2, and a region in contact with the one side surface of the oxide 406a3. That is, the one side surfaces have step-like shapes in which the conductor 416a1 and the conductor 416a2 recede from the oxide 406b2 and the oxide 406b3, respectively. On the other hand, the other side surfaces of the oxide 406a2, the oxide 406b2, and the conductor 416a1 are substantially aligned with one another, and the other side surfaces of the oxide 406a3, the oxide 406b3, and the conductor 416a2 are substantially aligned with one another. In other words, the other side surfaces have flat shapes.

The transistor 2000 includes the oxide 406d and can be fabricated over the same substrate as the semiconductor device including the transistor 1000.

In the transistor 2000, the resistance of the oxide 406 can be controlled by a potential applied to the conductor 404. That is, conduction or non-conduction between the conductor 416a1 and the conductor 416a2 can be controlled by the potential applied to the conductor 404.

Since the channel is formed in the oxide 406c and the oxide 406d in the transistor 2000, the transistor 2000 has different characteristics from the above-described transistor 1000.

Since the oxide 406a2 and the oxide 406a3 are formed by processing the oxide 406a into the oxide 406a2 and the oxide 406a3, they are oxide semiconductors with the same composition. Similarly, since the oxide 406b2 and the oxide 406b3 are formed by processing the oxide 406b into the oxide 406b2 and the oxide 406b3, they are oxide semiconductors with the same composition.

Here, each of the In-M-Zn oxides used for the oxide 406b2, the oxide 406b3, and the oxide 406c preferably contains more In atoms than element M atoms. Such an oxide is preferable because the mobility of the transistor 2000 increases and the carrier density also increases.

Here, when the oxide 406c and each of the oxide 406b2 and the oxide 406b3 have the same composition or similar compositions, the band gaps and E_{c}s of the oxide 406b2 and the oxide 406b3 and the band gap and E_{c} of the oxide 406c are the same, or the difference therebetween is small. Accordingly, the interface state density between the oxide 406b2 and the oxide 406c and the interface state density between the oxide 406b3 and the oxide 406c can be reduced. These reduced interface state densities can prevent a decrease in on-state current of the transistor 2000. Differences between E_{c} of the oxide 406c and each of E_{c}s of the oxide 406b2 and the oxide 406b3 are preferably small, and preferably greater than or equal to 0 eV and less than or equal to 0.15 eV, further preferably greater than or equal to 0 V and less than or equal to 0.07 eV. In addition, differences between the band gap of the oxide 406c and each of the band gaps of the oxide 406b2 and the oxide 406b3 are preferably small, preferably less than or equal to 0.15 eV.

The In-M-Zn oxide used for the oxide 406d preferably contains more element M atoms than In atoms. Therefore, an oxide semiconductor whose bandgap and E_{c} is different from those of the oxide 406c is used for the oxide 406d. It is preferable that E_{c} of the oxide 406d be smaller than E_{c} of the oxide 406c and the difference between E_{c} of the oxide 406d and E_{c} of the oxide 406c be greater than or equal to 0.2 eV and less than or equal to 0.4 eV. In addition, it is preferable that the band gap of the oxide 406d be larger than the band gap of the oxide 406c, and the difference between the band gap of the oxide 406d and the bandgap of the oxide 406c be greater than or equal to 0.4 eV and less than or equal to 0.7 eV.

In the structure of the transistor 2000, process damage might be caused on top surfaces or side surfaces of the oxide 406b2 and the oxide 406b3 when the source electrode and the drain electrode are formed. That is, a defect due to the process damage might be caused in the vicinity of the interfaces between the oxide 406c and each of the oxide 406b2 and the oxide 406b3. A channel formation region is formed not only in the oxide 406c but also in the vicinity of the interface between the oxide 406c and the oxide 406d whose E_{c} is smaller than that of the oxide 406c.

Therefore, influence of the vicinity of the interfaces between the oxide 406c and each of the oxide 406b2 and the oxide 406b3 subjected to the process damage can be small. Furthermore, the oxide to be the oxide 406c, the oxide to be the oxide 406d, and the insulator to be the insulator 412 having a function of the first gate insulator are deposited to be stacked, and then the oxide to be the oxide 406c, the oxide to be the oxide 406d, and the insulator to be the insulator 412 are processed to form the oxide 406c, the oxide 406d, and the insulator 412, in which case the vicinity of the interface between the oxide 406c and the oxide 406d and the vicinity of the interface between the oxide 406d and the insulator 412 are not influenced by the process damage, which is favorable.

Thus, a current when the transistor 2000 is on (on-state current) can be large. Furthermore, the reliability can be improved.

In the transistor 2000, the conductor 404b having a function of the first gate electrode includes a region overlapping with the conductor 416a1 and the conductor 416a2 having a function of the source electrode and the drain electrode, whereby parasitic capacitance formed between the conductor 404 and the conductor 416a1 and parasitic capacitance formed between the conductor 404 and the conductor 416a2 are included.

The structure of the transistor 2000 including the barrier film 417a1 as well as the insulator 412, the oxide 406c, and the oxide 406d between the conductor 404 and the conductor 416a1 allows a reduction in the parasitic capacitance. Similarly, the structure of the transistor 2000 including the barrier film 417a2 as well as the insulator 412, the oxide 406c, and the oxide 406d between the conductor 404 and the conductor 416a2 allows a reduction in the parasitic capacitance. Thus, the transistor 2000 is a transistor with excellent frequency characteristics.

Furthermore, the above structure of the transistor 2000 allows a reduction or prevention of a leakage current between the conductor 404 and each of the conductor 416a1 and the conductor 416a2 when the transistor 2000 operates, for example, when a potential difference between the conductor 404 and each of the conductor 416a1 and the conductor 416a2 occurs.

In addition, the conductor 310 has a function of a second gate electrode. The conductor 310a has a function of a conductive barrier film. When the conductor 310a is positioned to cover a bottom surface and side surfaces of the conductor 310b, oxidation of the conductor 310b can be prevented.

<Substrate>

Examples of a substrate over which the transistor 1000 and the transistor 2000 are formed include an insulator substrate, a semiconductor substrate, and a conductor substrate. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like, and a compound semiconductor substrate of silicon carbide, silicon germanium, gallium arsenide, indium phosphide, zinc oxide, or gallium oxide. In addition, a semiconductor substrate in which an insulator region is included in the above semiconductor substrate, e.g., an SOI (Silicon On Insulator) substrate and the like are given. Examples of the conductor substrate include a graphite substrate, a metal substrate, an alloy substrate, and a conductive resin substrate. In addition, a substrate including a metal nitride, a substrate including a metal oxide, and the like are given. Furthermore, an insulator substrate provided with a conductor or a semiconductor, a semiconductor substrate provided with a conductor or an insulator, a conductor substrate provided with a semiconductor or an insulator, and the like are given. Alternatively, any of these substrates provided with an element may be used. Examples of the element provided over the substrate include a capacitor, a resistor, a switching element, a light-emitting element, and a memory element.

Moreover, a flexible substrate may be used as the substrate. Note that as a method of providing the transistor over a flexible substrate, there is a method in which the transistor is fabricated over a non-flexible substrate and then the transistor is separated and transferred to the substrate which is a flexible substrate. In that case, a separation layer is preferably provided between the non-flexible substrate and the transistor. Note that as the substrate, a sheet, a film, or a foil containing a fiber may be used. Alternatively, the substrate may have elasticity. The substrate may also have a property of returning to its original shape when bending or pulling is stopped. Alternatively, the substrate may have a property of not returning to its original shape. The substrate includes a region with a thickness of, for example, greater than or equal to 5 μm and less than or equal to 700 μm, preferably greater than or equal to 10 μm and less than or equal to 500 μm, and further preferably greater than or equal to 15 μm and less than or equal to 300 μm. When the substrate has a small thickness, the weight of the semiconductor device including the transistor can be reduced. Moreover, when the substrate has a small thickness, the substrate may have elasticity or a property of returning to its original shape when bending or pulling is stopped, even in the case of using glass or the like. Thus, an impact applied to the semiconductor device over the substrate due to dropping or the like can be reduced. That is, a durable semiconductor device can be provided.

For the substrate which is a flexible substrate, metal, an alloy, a resin, glass, or fiber thereof can be used, for example. The substrate which is a flexible substrate preferably has a lower coefficient of linear expansion because deformation due to an environment is inhibited. For the substrate which is a flexible substrate, a material whose coefficient of linear expansion is lower than or equal to 1×10⁻³/K, lower than or equal to 5×10⁻⁵/K, or lower than or equal to 1×10⁻⁵/K can be used, for example. Examples of the resin include polyester, polyolefin, polyamide (nylon, aramid, or the like), polyimide, polycarbonate, and acrylic. In particular, aramid is preferable for the substrate which is a flexible substrate because of its low coefficient of linear expansion.

<Insulator>

Examples of an insulator include an oxide, a nitride, an oxynitride, a nitride oxide, a metal oxide, a metal oxynitride, and a metal nitride oxide, each of which has an insulating property.

When the transistor is surrounded by an insulator having a function of inhibiting the passage of oxygen and impurities such as hydrogen, the transistor can have stable electrical characteristics. For example, an insulator having a function of inhibiting the passage of oxygen and impurities such as hydrogen can be used as the insulator 432, the insulator 401, the insulator 303, the insulator 408a, the insulator 408b, the insulator 418, the insulator 420, the insulator 422, the insulator 450a, and the insulator 450b.

As the insulator having a function of inhibiting the passage of oxygen and impurities such as hydrogen, for example, a single layer or a stacked layer of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used.

Furthermore, for the insulator 432, the insulator 401, the insulator 303, the insulator 408a, the insulator 408b, the insulator 418, the insulator 420, the insulator 422, the insulator 450a, and the insulator 450b, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; or silicon nitride may be used, for example. Note that the insulator 432, the insulator 401, the insulator 303, the insulator 408a, the insulator 408b, the insulator 418, the insulator 420, the insulator 422, the insulator 450a, and the insulator 450b each preferably contain aluminum oxide.

For example, when the insulator 408a or the insulator 420 is deposited by a sputtering method using plasma containing oxygen, oxygen can be added to an insulator serving as a base layer of the oxide.

As the insulator 430, the insulator 301, the insulator 302, the insulator 402, and the insulator 412, for example, a single layer or a stacked layer including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. For example, the insulator 430, the insulator 301, the insulator 302, the insulator 402, and the insulator 412 each preferably contain silicon oxide, silicon oxynitride, or silicon nitride.

In particular, the insulator 402 and the insulator 412 preferably include an insulator with a high dielectric constant. For example, the insulator 402 and the insulator 412 preferably contain gallium oxide, hafnium oxide, zirconium oxide, an oxide containing aluminum and hafnium, oxynitride containing aluminum and hafnium, an oxide containing silicon and hafnium, oxynitride containing silicon and hafnium, a nitride containing silicon and hafnium, or the like. Alternatively, the insulator 402 and the insulator 412 preferably have a stacked-layer structure of an insulator with a high dielectric constant and silicon oxide or silicon oxynitride. When silicon oxide or silicon oxynitride, which is thermally stable, is combined with an insulator with a high dielectric constant, the stacked-layer structure can have thermal stability and a high dielectric constant. For example, when a structure is employed in which aluminum oxide, gallium oxide, or hafnium oxide is in contact with the oxide 406 in each of the insulator 402 and the insulator 412, silicon contained in silicon oxide or silicon oxynitride can be inhibited from entering the oxide 406. Furthermore, for example, when a structure is employed in which silicon oxide or silicon oxynitride is in contact with the oxide 406 in each of the insulator 402 and the insulator 412, trap centers are formed at the interface between aluminum oxide, gallium oxide, or hafnium oxide and silicon oxide or silicon oxynitride, in some cases. The trap centers can shift the threshold voltage of the transistor in the positive direction by trapping electrons in some cases.

The insulator 410 and the insulator 415 preferably include an insulator with a low dielectric constant. For example, the insulator 410 and the insulator 415 preferably contain silicon oxide, silicon oxynitride, silicon nitride oxide, silicon nitride, silicon oxide to which fluorine is added, silicon oxide to which carbon is added, silicon oxide to which carbon and nitrogen are added, silicon oxide having pores, a resin, or the like. Alternatively, the insulator 410 and the insulator 415 preferably have a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or silicon oxide having pores. When silicon oxide or silicon oxynitride, which is thermally stable, is combined with a resin, the stacked-layer structure can have thermal stability and low dielectric constant. Examples of the resin include polyester, polyolefin, polyamide (e.g., nylon or aramid), polyimide, polycarbonate, and acrylic.

An insulator having a function of inhibiting the passage of oxygen and impurities such as hydrogen may be used for the barrier film 417a1 and the barrier film 417a2. The barrier film 417a1 and the barrier film 417a2 can prevent excess oxygen in the insulator 410 from diffusing into the conductor 416a1 and the conductor 416a2.

For the barrier film 417a1 and the barrier film 417a2, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; or silicon nitride may be used, for example.

<Conductor>

For the conductor 451a, the conductor 451b, the conductor 452a, the conductor 452b, the conductor 453a, the conductor 453b, the conductor 404a, the conductor 404b, the conductor 416a1, the conductor 416a2, the conductor 310a, the conductor 310b, the conductor 440a, and the conductor 440b, a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor with high electrical conductivity, typified by polycrystalline silicon containing an impurity element such as phosphorus, or silicide such as nickel silicide may be used.

Alternatively, a conductive material containing oxygen and a metal element contained in a metal oxide that can be used for the oxide 406 may be used. Furthermore, a conductive material containing the above metal element and nitrogen may be used. For example, a conductive material containing nitrogen, such as titanium nitride or tantalum nitride, may be used. Alternatively, an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon is added may be used. Furthermore, indium gallium zinc oxide containing nitrogen may be used. With the use of such a material, hydrogen contained in the oxide 406 can be captured in some cases. Alternatively, hydrogen entering from an external insulator or the like can be captured in some cases.

Furthermore, a stack of a plurality of conductive layers formed with the above materials may be used. For example, a stacked-layer structure combining a material containing the above metal element and a conductive material containing oxygen may be employed. Alternatively, a stacked-layer structure combining a material containing the above metal element and a conductive material containing nitrogen may be employed. Alternatively, a stacked-layer structure combining a material containing the above metal element, a conductive material containing oxygen, and a conductive material containing nitrogen may be employed.

Note that in the case where an oxide is used for the channel formation region of the transistor, a stacked-layer structure combining a material containing the above metal element and a conductive material containing oxygen is preferably used for the gate electrode. In that case, the conductive material containing oxygen is preferably provided on the channel formation region side. When the conductive material containing oxygen is provided on the channel formation region side, oxygen released from the conductive material is easily supplied to the channel formation region.

<Metal Oxide that can be Used as Oxide 406>

A metal oxide is preferably used as the oxide 406. However, silicon (including strained silicon), germanium, silicon germanium, silicon carbide, gallium arsenide, aluminum gallium arsenide, indium phosphide, gallium nitride, an organic semiconductor, or the like may be used instead of the oxide 406 in some cases.

The oxide 406 of the present invention is described below. A metal oxide functioning as an oxide semiconductor (hereinafter, the metal oxide is also referred to as an oxide semiconductor) is preferably used as the oxide 406.

An oxide semiconductor preferably contains at least indium or zinc. In particular, indium and zinc are preferably contained. Furthermore, aluminum, gallium, yttrium, tin, or the like is preferably contained in addition to them. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the oxide semiconductor is an InMZnO containing indium, the element M, and zinc is considered. Note that the element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, and magnesium. Note that a plurality of the above-described elements may be combined as the element M.

Note that in this specification and the like, a metal oxide containing nitrogen is also collectively referred to as a metal oxide in some cases. Alternatively, a metal oxide containing nitrogen may be referred to as a metal oxynitride.

<Composition of Metal Oxide>

The composition of a CAC (Cloud-Aligned Composite)-OS that can be used for a transistor disclosed in one embodiment of the present invention is described below.

Note that in this specification and the like, “CAAC (c-axis aligned crystal)” or “CAC (Cloud-Aligned Composite)” might be stated. Note that CAAC refers to an example of a crystal structure, and CAC refers to an example of a function or a material composition.

A CAC-OS or a CAC-metal oxide has a conducting function in a part of the material and has an insulating function in another part of the material; as a whole, the CAC-OS or the CAC-metal oxide has a function of a semiconductor. In the case where the CAC-OS or the CAC-metal oxide is used in an active layer of a transistor, the conducting function is to allow electrons (or holes) serving as carriers to flow, and the insulating function is to not allow electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

Furthermore, the CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, the conductive regions are observed to be coupled in a cloud-like manner with their boundaries blurred, in some cases.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide includes components having different bandgaps. For example, the CAC-OS or the CAC-metal oxide includes a component having a wide gap due to the insulating region and a component having a narrow gap due to the conductive region. In the case of the structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, high current driving capability in an on state of the transistor, that is, a high on-state current and high field-effect mobility can be obtained.

In other words, the CAC-OS or the CAC-metal oxide can also be referred to as a matrix composite or a metal matrix composite.

<Structure of Metal Oxide>

Oxide semiconductors can be classified into a single crystal oxide semiconductor and a non-single-crystal oxide semiconductor. Examples of a non-single-crystal oxide semiconductor include a CAAC-OS (c-axis-aligned crystalline oxide semiconductor), a polycrystalline oxide semiconductor, an nc-OS (nanocrystalline oxide semiconductor), an a-like OS (amorphous-like oxide semiconductor), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) cannot be observed even in the vicinity of distortion in the CAAC-OS. That is, formation of a crystal grain boundary is inhibited by the distortion of a lattice arrangement. This is probably because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, In layer) and a layer containing the element M, zinc, and oxygen (hereinafter, (M,Zn) layer) are stacked. Note that indium and the element M can be replaced with each other, and when the element Min the (M,Zn) layer is replaced with indium, the layer can also be referred to as an (InN,Zn) layer. Furthermore, when indium in the In layer is replaced with the element M, the layer can be referred to as an (In,M) layer.

The CAAC-OS is an oxide semiconductor with high crystallinity. On the other hand, a clear crystal grain boundary cannot be observed in the CAAC-OS; thus, it can be said that a reduction in electron mobility due to the crystal grain boundary is less likely to occur. Furthermore, entry of impurities, formation of defects, or the like might decrease the crystallinity of an oxide semiconductor; thus, it can be said that the CAAC-OS has small amounts of impurities and defects (e.g., oxygen vacancies). Thus, an oxide semiconductor including a CAAC-OS is physically stable. Therefore, the oxide semiconductor including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

An a-like OS is an oxide semiconductor having a structure between those of the nc-OS and an amorphous oxide semiconductor. The a-like OS includes a void or a low-density region. That is, the a-like OS has low crystallinity as compared with the nc-OS and the CAAC-OS.

An oxide semiconductor can have various structures which show different properties. Two or more of the amorphous oxide semiconductor, the polycrystalline oxide semiconductor, the a-like OS, the nc-OS, and the CAAC-OS may be included in an oxide semiconductor of one embodiment of the present invention.

<Transistor Including Oxide Semiconductor>

Next, the case where the oxide semiconductor is used for a transistor will be described.

When the oxide semiconductor is used for a transistor, a transistor with high field-effect mobility can be achieved. In addition, a transistor with high reliability can be achieved.

An oxide semiconductor with a low carrier density is preferably used for the transistor. In the case where the carrier density of an oxide semiconductor film is reduced, the impurity concentration in the oxide semiconductor film is reduced to reduce the density of defect states. In this specification and the like, a state with a low impurity concentration and a low density of defect states is referred to as a highly purified intrinsic or substantially highly purified intrinsic state. For example, the carrier density of an oxide semiconductor is lower than 8×10¹¹/cm³, preferably lower than 1×10¹¹/cm³, further preferably lower than 1×10¹⁰/cm³, and greater than or equal to 1×10⁻⁹/cm³.

In addition, a highly purified intrinsic or substantially highly purified intrinsic oxide semiconductor film has a low density of defect states and accordingly has a low density of trap states in some cases.

Furthermore, charges trapped by the trap states in the oxide semiconductor take a long time to disappear and may behave like fixed charges. Thus, a transistor whose channel formation region is formed in an oxide semiconductor with a high density of trap states has unstable electrical characteristics in some cases.

Thus, in order to stabilize electrical characteristics of the transistor, reducing the impurity concentration in the oxide semiconductor is effective. Furthermore, in order to reduce the impurity concentration in the oxide semiconductor, the impurity concentration in an adjacent film is also preferably reduced. Examples of impurities include hydrogen, nitrogen, an alkali metal, an alkaline earth metal, iron, nickel, and silicon.

<Impurity>

Here, the influence of each impurity in the oxide semiconductor is described.

When silicon or carbon, which is one of the Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration measured by secondary ion mass spectrometry (SIMS)) is set lower than or equal to 2×10¹⁸ atoms/cm³, preferably lower than or equal to 2×10¹⁷ atoms/cm³.

Furthermore, when the oxide semiconductor contains alkali metal or alkaline earth metal, defect states are formed and carriers are generated in some cases. Thus, a transistor using an oxide semiconductor that contains alkali metal or alkaline earth metal is likely to have normally-on characteristics. Accordingly, it is preferable to reduce the concentration of alkali metal or alkaline earth metal in the oxide semiconductor. Specifically, the concentration of alkali metal or alkaline earth metal in the oxide semiconductor obtained by SIMS is set lower than or equal to 1×10¹⁸ atoms/cm³, preferably lower than or equal to 2×10¹⁶ atoms/cm³.

Furthermore, when containing nitrogen, the oxide semiconductor easily becomes n-type by generation of electrons serving as carriers and an increase of carrier density. As a result, a transistor using an oxide semiconductor containing nitrogen as a semiconductor is likely to have normally-on characteristics. For this reason, nitrogen in the oxide semiconductor is preferably reduced as much as possible; the nitrogen concentration in the oxide semiconductor obtained by SIMS is set, for example, lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Furthermore, hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor obtained by SIMS is lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurities is used for a channel formation region of a transistor, stable electrical characteristics can be given.

This embodiment can be implemented in appropriate combination with the structures described in the other embodiments, example, and the like.

### Embodiment 2

<Fabricating Method of Semiconductor Device>

A fabricating method of a semiconductor device including the transistor 1000 of one embodiment of the present invention is described below with reference to FIG. 1 and FIG. 8 to FIG. 16. In each of FIG. 1 and FIG. 8 to FIG. 16, figure (A) is a top view. Similarly, figure (B) is a cross-sectional view of a portion indicated by a dashed-dotted line A1-A2 in figure (A). Similarly, figure (C) is a cross-sectional view of a portion indicated by a dashed-dotted line A3-A4 in figure (A).

First, a substrate (not illustrated) is prepared, and the insulator 432 is deposited over the substrate. The insulator 432 can be deposited by a sputtering method, a chemical vapor deposition (CVD) method, a molecular beam epitaxy (MBE) method, a pulsed laser deposition (PLD) method, an atomic layer deposition (ALD) method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma CVD method, a high-quality film can be obtained at a relatively low temperature. Furthermore, a thermal CVD method is a deposition method that does not use plasma and thus enables less plasma damage to an object. For example, a wiring, an electrode, an element (e.g., transistor or capacitor), or the like included in a semiconductor device might be charged up by receiving electric charges from plasma. In that case, accumulated electric charges might break the wiring, electrode, element, or the like included in the semiconductor device. By contrast, such plasma damage is not caused in the case of using a thermal CVD method that does not use plasma, and thus the yield of a semiconductor device can be increased. In addition, a thermal CVD method does not cause plasma damage during deposition, so that a film with few defects can be obtained.

An ALD method is also a deposition method which enables less plasma damage to an object. An ALD method also does not cause plasma damage during deposition, so that a film with few defects can be obtained.

Unlike in a deposition method in which particles ejected from a target or the like are deposited, a CVD method and an ALD method are deposition methods in which a film is formed by reaction at a surface of an object. Thus, a CVD method and an ALD method are deposition methods that are less likely to be influenced by the shape of an object and thus have favorable step coverage. In particular, an ALD method has excellent step coverage and excellent thickness uniformity, and thus is suitable for the case of covering a surface of an opening with a high aspect ratio, for example. On the other hand, an ALD method has a relatively low deposition rate, and thus is preferably used in combination with another deposition method with a high deposition rate such as a CVD method, in some cases.

A CVD method or an ALD method enables control of composition of a film to be obtained with a flow rate ratio of the source gases. For example, by a CVD method or an ALD method, a film with a desired composition can be deposited by adjusting the flow rate ratio of the source gases. Moreover, for example, by a CVD method or an ALD method, by changing the flow rate ratio of the source gases during the deposition, a film whose composition is continuously changed can be deposited. In the case of depositing while changing the flow rate ratio of the source gases, as compared with the case of depositing with the use of a plurality of deposition chambers, time taken for the deposition can be shortened because time taken for transfer and pressure adjustment is omitted. Thus, productivity of semiconductor devices can be improved in some cases.

The insulator 432 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

Next, the insulator 430 is deposited over the insulator 432. The insulator 430 can be deposited by a sputtering method, a CVD method, an MBE method, a PLD method, an ALD method, or the like. In this embodiment, as the insulator 430, silicon oxide is deposited by a CVD method.

Then, a depression portion reaching the insulator 432 is formed in the insulator 430. Examples of the depression portion include a hole and an opening. The depression portion may be formed by wet etching; however, dry etching is preferably used for microfabrication. In addition, as the insulator 432, an insulator functioning as an etching stopper film when forming the depression portion by etching the insulator 430 is preferably selected. For example, in the case where a silicon oxide film is used as the insulator 430 in which the depression portion is to be formed, a silicon nitride film, an aluminum oxide film, or a hafnium oxide film is preferably used as the insulator 432.

After the formation of the depression portion, a conductor to be the conductor 440a is deposited. The conductor to be the conductor 440a desirably includes a conductor having a function of inhibiting the passage of oxygen. For example, tantalum nitride, tungsten nitride, or titanium nitride can be used. Alternatively, a stacked-layer film of the conductor and tantalum, tungsten, titanium, molybdenum, aluminum, copper, or a molybdenum-tungsten alloy can be used. The conductor to be the conductor 440 can be deposited by a sputtering method, a CVD method, an MBE method, a PLD method, an ALD method, or the like.

In this embodiment, tantalum nitride or a film of tantalum nitride and titanium nitride stacked thereover is deposited by a sputtering method as the conductor to be the conductor 440a. With the use of such a metal nitride as the conductor 440a, even when a metal that is easy to diffuse, such as copper, is used for the conductor 440b described later, the metal can be prevented from diffusing outward through the conductor 440a.

Next, a conductor to be the conductor 440b is deposited over the conductor to be the conductor 440a. The conductor to be the conductor 440b can be deposited by a sputtering method, a CVD method, an MBE method, a PLD method, an ALD method, or the like. In this embodiment, a low-resistance conductive material such as copper is deposited for the conductor to be the conductor 440b.

Next, chemical mechanical polishing (CMP) treatment is performed to remove the conductor to be the conductor 440a and the conductor to be the conductor 440b that are over the insulator 430. Consequently, the conductor to be the conductor 440a and the conductor to be the conductor 440b are left only in the depression portion, whereby the conductor 440 including the conductor 440a and the conductor 440b with flat top surfaces can be formed.

Then, the insulator 401 is deposited over the conductor 440 and the insulator 430. The insulator 401 can be deposited by a sputtering method, a CVD method, an MBE method, a PLD method, an ALD method, or the like. In this embodiment, as the insulator 401, silicon nitride is deposited by a CVD method. As described here, an insulator through which copper is less likely to pass, such as silicon nitride, is used as the insulator 401; accordingly, even when a metal that is easy to diffuse, such as copper, is used for the conductor 440b and the like, the metal can be prevented from diffusing into layers above the insulator 401.

Next, the insulator 301 is deposited over the insulator 401. The insulator 301 can be deposited by a sputtering method, a CVD method, an MBE method, a PLD method, an ALD method, or the like.

Next, a depression portion reaching the conductor 440b is formed in the insulator 301 and the insulator 401. Examples of the depression portion include a hole and an opening. The depression portion may be formed by wet etching; however, dry etching is preferably used for microfabrication.

In this embodiment, for the insulator 401, aluminum oxide is deposited by a sputtering method and another aluminum oxide is deposited over the aluminum oxide by an ALD method. In addition, silicon oxide is deposited by a CVD method for the insulator 301.

After the formation of the depression portion, a conductor to be the conductor 310a is deposited. The conductor to be the conductor 310a desirably includes a conductor having a function of inhibiting the passage of oxygen. For example, tantalum nitride, tungsten nitride, or titanium nitride can be used. Alternatively, a stacked-layer film of the conductor and tantalum, tungsten, titanium, molybdenum, aluminum, copper, or a molybdenum-tungsten alloy can be used. The conductor to be the conductor 310a can be deposited by a sputtering method, a CVD method, an MBE method, a PLD method, an ALD method, or the like.

In this embodiment, tantalum nitride is deposited by a sputtering method for the conductor to be the conductor 310a.

Then, a conductor to be the conductor 310b is deposited over the conductor to be the conductor 310a. The conductor to be the conductor 310b can be deposited by a sputtering method, a CVD method, an MBE method, a PLD method, an ALD method, or the like.

In this embodiment, for the conductor to be the conductor 310b, titanium nitride is deposited by a CVD method and tungsten is deposited over the titanium nitride by a CVD method.

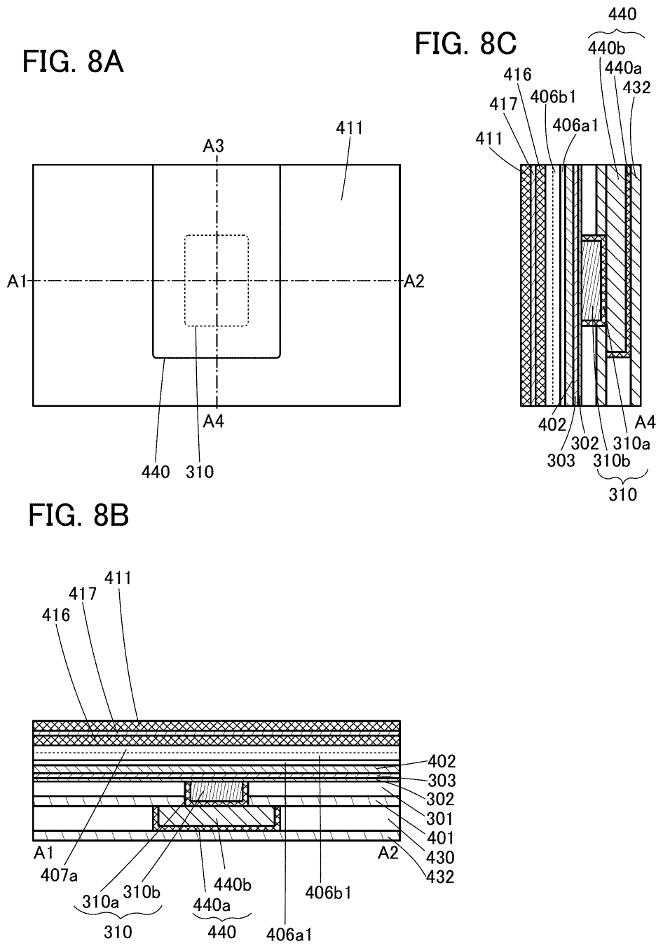

Next, CMP treatment is performed to remove the conductor to be the conductor 310a and the conductor to be the conductor 310b that are over the insulator 301. Consequently, the conductor to be the conductor 310a and the conductor to be the conductor 310b are left only in the depression portion, whereby the conductor 310 that includes the conductor 310a and the conductor 310b with flat top surfaces can be formed (see FIGS. 8(A), 8(B), and 8(C)).

Next, the insulator 302 is deposited over the insulator 301 and over the conductor 310. The insulator 302 can be deposited by a sputtering method, a CVD method, an MBE method, a PLD method, an ALD method, or the like.

Next, the insulator 303 is deposited over the insulator 302. The insulator 303 can be deposited by a sputtering method, a CVD method, an MBE method, a PLD method, an ALD method, or the like.

Next, the insulator 402 is deposited over the insulator 303. The insulator 402 can be deposited by a sputtering method, a CVD method, an MBE method, a PLD method, an ALD method, or the like.

Next, first heat treatment is preferably performed. The first heat treatment can be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The first heat treatment is performed in a nitrogen atmosphere, an inert gas atmosphere, or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen. Through the first heat treatment, impurities such as hydrogen and water contained in the insulator 402 can be removed, for example. In the first heat treatment, plasma treatment containing oxygen may be performed under a reduced pressure. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be generated, and application of the RF to the substrate side allows oxygen radicals generated by the high-density plasma to be efficiently introduced into the insulator 402. Alternatively, after plasma treatment containing an inert gas is performed with this apparatus, plasma treatment containing oxygen may be performed to compensate for released oxygen. Note that the first heat treatment is not necessarily performed in some cases.

The heat treatment can be performed after the deposition of the insulator 302, after the deposition of the insulator 303, and after the deposition of the insulator 402. Although the conditions for the first heat treatment can be used for the heat treatment, the heat treatment after the deposition of the insulator 302 is preferably performed in an atmosphere containing nitrogen.

In this embodiment, the first heat treatment is performed in such a manner that treatment is performed at 400° C. in a nitrogen atmosphere for one hour after the deposition of the insulator 402, and then another treatment is successively performed at 400° C. in an oxygen atmosphere for one hour.

Next, an oxide 406a1 and an oxide 406b1 are deposited in this order over the insulator 402. Note that it is preferable that the oxide 406a1 and the oxide 406b1 be successively deposited without being exposed to the atmosphere. When deposition is performed in such a manner, impurities or moisture from the atmosphere can be prevented from being attached to the oxide 406a1, and the vicinity of an interface between the oxide 406a1 and the oxide 406b1 can be kept clean.

The oxide 406a1 and the oxide 406b1 can be deposited by a sputtering method, a CVD method, an MBE method, a PLD method, an ALD method, or the like.

For example, in the case where the oxide 406a1 and the oxide 406b1 are deposited by a sputtering method, oxygen or a mixed gas of oxygen and a rare gas is used as a sputtering gas. By increasing the proportion of oxygen contained in the sputtering gas, the amount of excess oxygen in the oxide film to be deposited can be increased.

In particular, at the time of the deposition of the oxide 406a1, part of oxygen contained in the sputtering gas is supplied to the insulator 402 in some cases.

Note that the proportion of oxygen contained in the sputtering gas is higher than or equal to 70%, preferably higher than or equal to 80%, and further preferably 100%.

Next, the oxide 406b1 is formed by a sputtering method. At this time, when the proportion of oxygen contained in the sputtering gas is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor, relatively high field-effect mobility can be obtained.

In the case where an oxygen-deficient oxide semiconductor is used for the oxide 406b1, an oxide film containing excess oxygen is preferably used as the oxide 406a1. In addition, oxygen doping treatment may be performed after the deposition of the oxide 406b1.

Note that in the case where the oxide is deposited by a sputtering method, a film with an atomic ratio deviated from the atomic ratio of the target is formed in some cases. For example, depending on the substrate temperature at the time of the deposition, the atomic proportion of zinc (Zn) in the film is lower than the atomic proportion of zinc (Zn) in the target in some cases.

As a specific example, the case where In-M-Zn oxides are deposited as the oxide 406b1 and an oxide 406c1 is described. In a film deposited by a sputtering method using a target with In:Ga:Zn=4:2:4.1 [atomic ratio], the atomic proportion of Zn is particularly low in some cases. Therefore, the atomic ratio of the deposited film varies around In:Ga:Zn=4:2:3 in some cases.

In addition, even in the case where films are deposited using targets with the same atomic ratio, if other deposition conditions are different, strictly, the deposited films have different compositions in some cases. Therefore, in this specification, in the case where the oxide 406b1 and the oxide 406c1 are deposited using targets with the same atomic ratio, the atomic ratios of the deposited films are the same or similar to each other. The description “the composition of the oxide 406b1 is similar to the composition of the oxide 406c1” includes the case where the atomic proportion of indium (In) differs between the oxide 406b1 and the oxide 406c1 within 10 atomic %.

In this embodiment, the oxide 406a1 is deposited by a sputtering method using a target with an atomic ratio of In:Ga:Zn=1:3:4, and the oxide 406b1 is deposited by a sputtering method using a target with an atomic ratio of In:Ga:Zn=4:2:4.1.

After that, second heat treatment may be performed. For the second heat treatment, the conditions for the first heat treatment can be used. Through the second heat treatment, impurities such as hydrogen and water contained in the oxide 406a1 and the oxide 406b1 can be removed, for example. In this embodiment, treatment is performed at 400° C. in a nitrogen atmosphere for one hour, and successively another treatment is performed at 400° C. in an oxygen atmosphere for one hour.

Next, a conductor 416 is deposited over the oxide 406b1. The conductor 416 can be deposited by a sputtering method, a CVD method, an MBE method, a PLD method, an ALD method, or the like. For the conductor 416, an oxide having conductivity such as indium tin oxide (ITO), indium oxide containing tungsten oxide, indium zinc oxide containing tungsten oxide, indium oxide containing titanium oxide, indium tin oxide containing titanium oxide, indium zinc oxide, indium tin oxide to which silicon is added, or indium gallium zinc oxide containing nitrogen is deposited; and a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, and the like, a semiconductor with high electric conductivity, typified by polycrystalline silicon containing an impurity element such as phosphorus, or a silicide such as nickel silicide may be deposited over the oxide.

The oxide has a function of absorbing hydrogen in the oxide 406a1 and the oxide 406b1 and capturing hydrogen diffused from the outside in some cases; thus, the electrical characteristics and reliability of the transistor 1000 are improved in some cases. Alternatively, titanium used instead of the oxide has a similar function in some cases. In this embodiment, tantalum nitride is deposited for the conductor 416.

Note that the vicinity of the top surface of the oxide 406b1 is damaged when the conductor 416 is deposited, whereby the region 407a is formed. The region 407a includes a region in which the resistance of the oxide 406b1 is reduced; thus, the contact resistance between the conductor 416 and the oxide 406b1 is reduced.

Then, a barrier film 417 is deposited over the conductor 416. The barrier film 417 can be deposited by a sputtering method, a CVD method, an MBE method, a PLD method, an ALD method, or the like. In this embodiment, aluminum oxide is deposited for the barrier film 417.

Next, a conductor 411 is deposited over the barrier film 417. The conductor 411 can be deposited by a sputtering method, a CVD method, an MBE method, a PLD method, an ALD method, or the like. In this embodiment, tantalum nitride is deposited for the conductor 411 (see FIGS. 8(A), 8(B), and 8(C)).

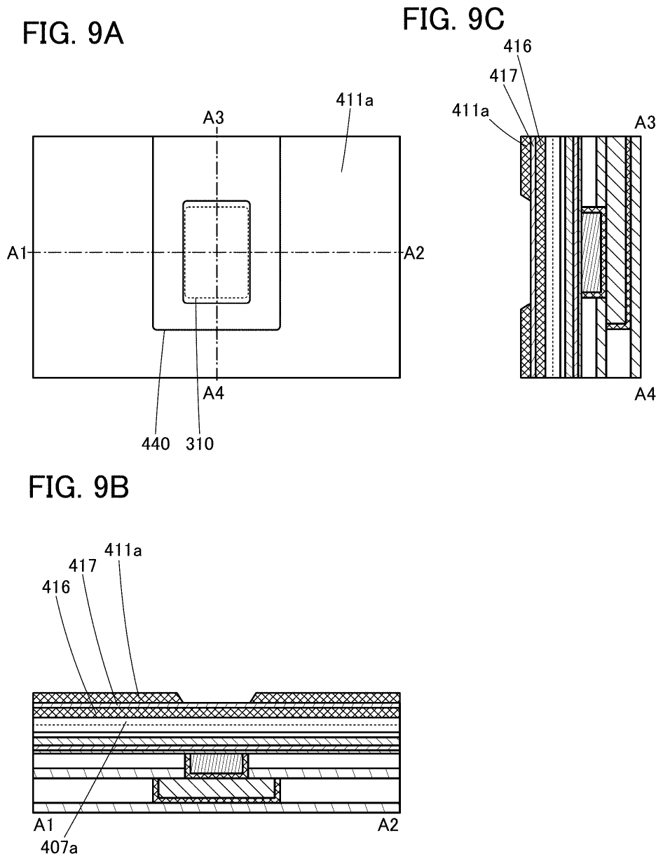

Next, the conductor 411 is processed by a lithography method to form a conductor 411a. Through this processing, a cross section preferably has a tapered shape. The taper angle with respect to a plane parallel to the bottom surface of the substrate is greater than or equal to 30° and less than 75°, preferably greater than or equal to 30° and less than 70°. With such a taper angle, coverage with films deposited in the following process can be improved. In addition, the processing is preferably performed by a dry etching method. The processing by a dry etching method is suitable for microfabrication and the processing for the above-described formation of a tapered shape (see FIGS. 9(A), 9(B), and 9(C)).

Note that in the lithography method, first, a resist is exposed to light through a mask. Next, a region exposed to light is removed or left using a developing solution, so that a resist mask is formed. Then, etching treatment through the resist mask is performed, so that the conductor, the semiconductor, the insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a portion between a substrate and a projection lens is filled with liquid (e.g., water) to perform light exposure. Furthermore, an electron beam or an ion beam may be used instead of the above-described light. Note that a mask is not necessary in the case of using an electron beam or an ion beam. Note that for removal of the resist mask, dry etching treatment such as ashing can be performed, wet etching treatment can be performed, wet etching treatment can be performed after dry etching treatment, or dry etching treatment can be performed after wet etching treatment.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, a structure may be employed in which different high-frequency power sources are applied to one of the parallel plate type electrodes. Alternatively, a structure may be employed in which high-frequency power sources with the same frequency are applied to the parallel plate type electrodes. Alternatively, a structure may be employed in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

Next, a resist 421 is formed by a lithography method.

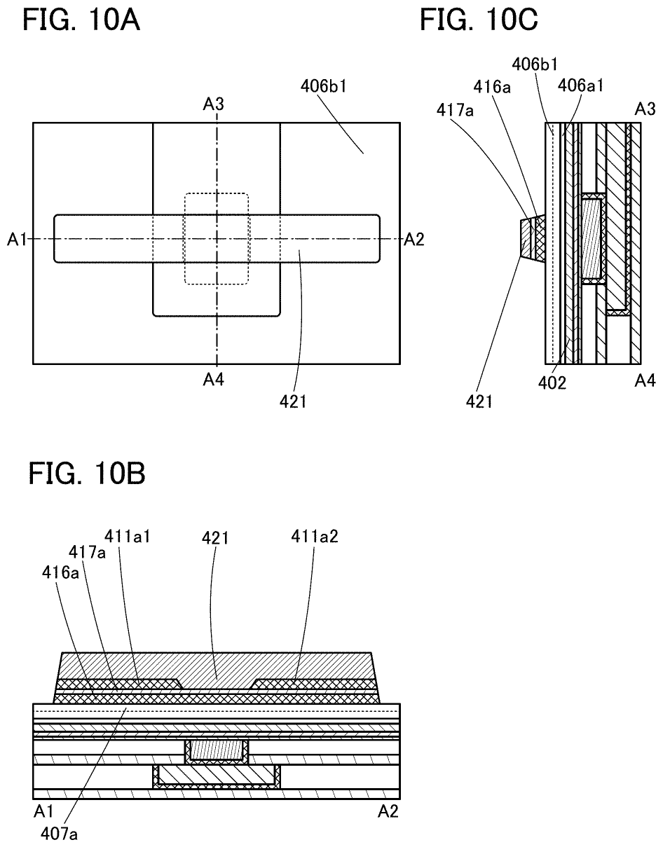

Next, the conductor 411a, the barrier film 417, and the conductor 416 are etched with the use of the resist 421 as an etching mask to form a conductor 411a1, a conductor 411a2, a barrier film 417a, and a conductor 416a (see FIGS. 10(A), 10(B), and 10(C)).

Next, after the resist 421 is removed, the barrier film 417a in a region that is over the conductor 416a and sandwiched between the conductor 411a1 and the conductor 411a2 is etched, whereby the barrier film 417a1 and the barrier film 417a2 are formed.

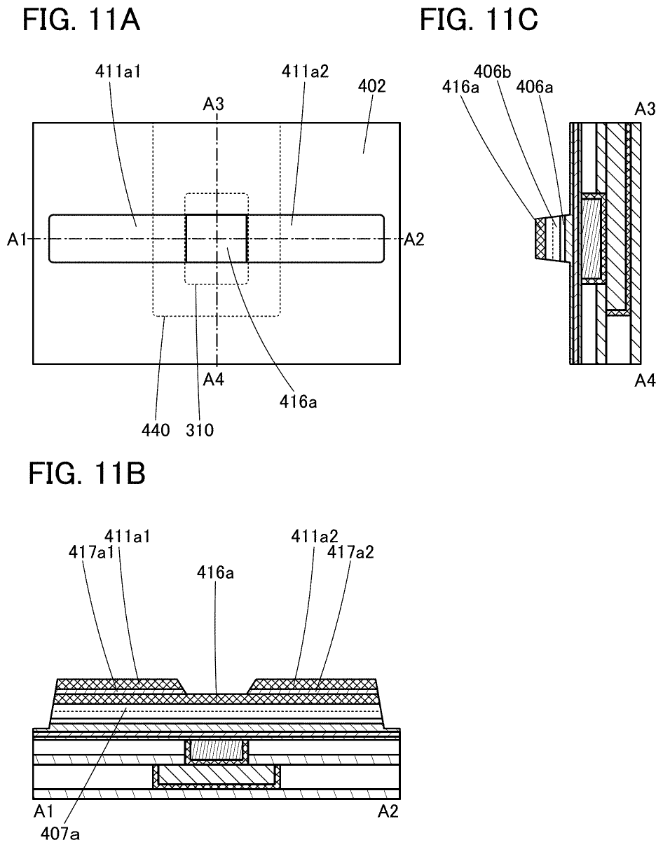

Next, the oxide 406a1 and the oxide 406b1 are formed with the use of the conductor 411a1, the conductor 411a2, and an exposed portion of the surface of the conductor 416a as etching masks. Since tantalum nitride is used for the conductor 411a1, the conductor 411a2, and the conductor 416a in this embodiment, processing is preferably performed using an etching condition in which the etching rates of the oxide 406a1 and the oxide 406b1 are higher than the etching rate of tantalum nitride. When the etching rate of tantalum nitride is regarded as 1, the etching rates of the oxide 406a1 and the oxide 406b1 are higher than or equal to 3 and lower than or equal to 50, preferably higher than or equal to 5 and lower than or equal to 30 (see FIGS. 11(A), 11(B), and 11(C)).

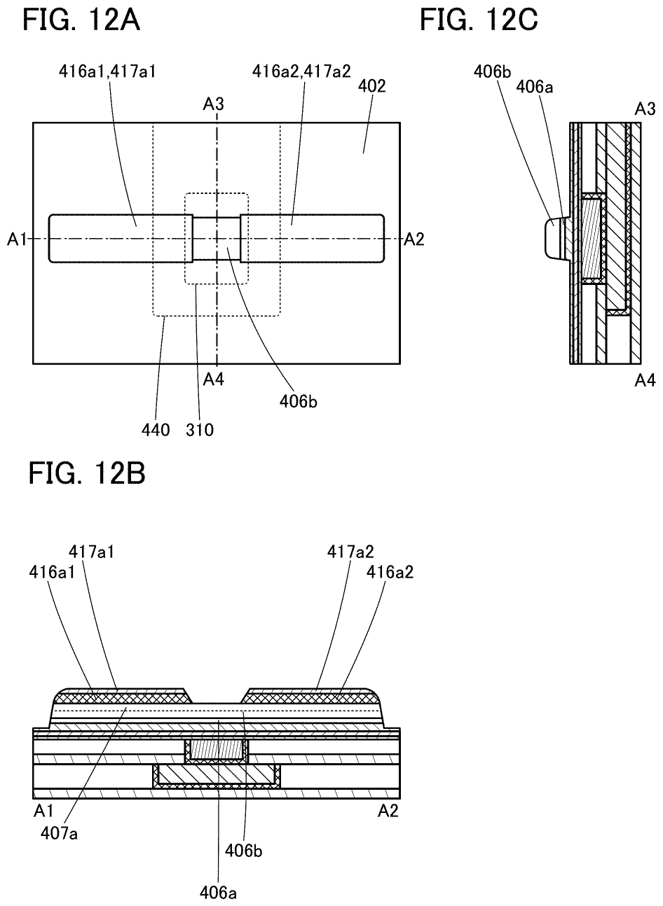

Next, the conductor 411a1, the conductor 411a2, and the exposed portion of the surface of the conductor 416a are etched to form the conductor 416a1 and the conductor 416a2 (see FIGS. 12(A), 12(B), and 12(C)).

In some cases, treatment such as dry etching performed in the above process causes the attachment or diffusion of impurities due to an etching gas or the like to a surface or an inside of the oxide 406a, the oxide 406b, and the like. Examples of the impurities include fluorine and chlorine.

In order to remove the above impurities, cleaning is performed. Examples of the cleaning method include wet cleaning using a cleaning solution, plasma treatment using plasma, and cleaning by heat treatment, and any of these cleanings may be performed in appropriate combination.

As the wet cleaning, cleaning treatment may be performed using an aqueous solution obtained by diluting an oxalic acid, a phosphoric acid, a hydrofluoric acid, or the like with pure water or carbonated water. Alternatively, ultrasonic cleaning using pure water or carbonated water may be performed. In this embodiment, the ultrasonic cleaning using pure water or carbonated water is performed.

Next, third heat treatment may be performed. For the heat treatment, the conditions for the first heat treatment can be used. Note that the third heat treatment is not necessarily performed in some cases. In this embodiment, the third heat treatment is not performed.

When the above-described wet cleaning and/or the third heat treatment are/is performed, the concentration of these impurities can be reduced. Furthermore, the moisture concentration and the hydrogen concentration in the oxide 406a film and the oxide 406b film can be reduced.

Next, an oxide 406c1 is deposited. The oxide 406c1 can be deposited by a sputtering method, a CVD method, an MBE method, a PLD method, an ALD method, or the like. In particular, a sputtering method is preferably used for the deposition. As the oxide 406c1 to be the oxide 406c, an oxide with the same composition as the oxide 406b is preferably deposited. When the oxide 406b and the oxide 406c have the same composition, the electron affinity of the oxide 406b and the band gap and E_{c} of the oxide 406c are the same or the difference therebetween is small. Accordingly, the interface state density between the oxide 406b and the oxide 406b can be low. Low interface state density can prevent a decrease in on-state current of the transistor 1000.

For example, in the case where In-M-Zn oxides are used as the oxide 406c1 and the oxide 406b1, it is preferable to deposit the oxides to have substantially the same atomic ratio of metal elements. Specifically, in the case where a sputtering method is used for the deposition, targets with the same atomic ratio of metal elements are preferably used for the deposition. Furthermore, a mixed gas of oxygen and argon is used as a sputtering gas, and the proportion of oxygen contained in the sputtering gas is greater than or equal to 0%, preferably greater than or equal to 80%, further preferably 100%.

In this embodiment, the oxide 406c1 is deposited by a sputtering method using a target with In:Ga:Zn=4:2:4.1 [atomic ratio], and the proportion of oxygen contained in the sputtering gas is 100%.

The oxide 406c1 is preferably deposited under the above conditions, in which case oxygen can be added to the oxide 406a, the oxide 406b, and the insulator 402.

Furthermore, in the region 407a that is a low-resistance region of the oxide 406b, the low-resistance region not in contact with the conductor 416a1 or the conductor 416a2 has high resistance; thus, the regions 407 are the low-resistance regions of the oxide 406b.

Next, an oxide 406d1 is deposited over the oxide 406c1. The oxide 406d1 can be deposited by a sputtering method, a CVD method, an MBE method, a PLD method, an ALD method, or the like. In particular, the deposition is preferably performed by a sputtering method. As the oxide 406d1 to be the oxide 406d, an oxide with the same composition as the oxide 406a is preferably deposited. When the oxide 406a and the oxide 406d have the same composition, the band gap and E_{c} of the oxide 406a and the band gap and E_{c} of the oxide 406d are the same, or the difference therebetween is small.

For example, in the case where an In-M-Zn oxide is used as the oxide 406d1, the oxide is preferably deposited to have substantially the same atomic ratio of metal elements as the oxide 406a. Specifically, when a sputtering method is used for the deposition, targets with the same atomic ratio of metal elements are preferably used for the deposition. Furthermore, a mixed gas of oxygen and argon is used as a sputtering gas, and the proportion of oxygen contained in the sputtering gas is greater than or equal to 0%, preferably greater than or equal to 80%, further preferably 100%.

In this embodiment, in this embodiment, the oxide 406d1 is deposited by a sputtering method using a target with In:Ga:Zn=1:3:4 [atomic ratio], and the proportion of oxygen contained in the sputtering gas is 100%.

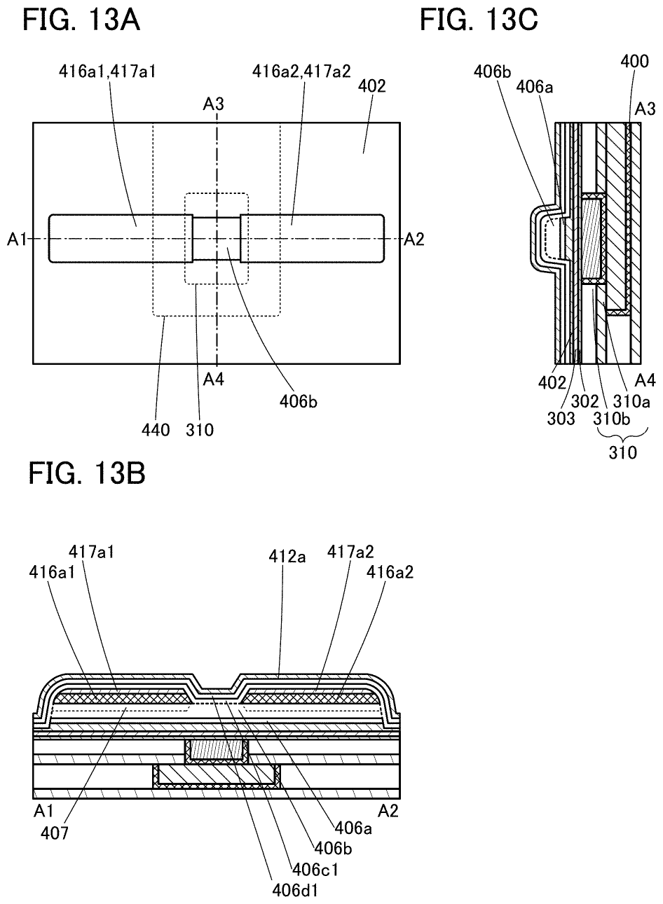

Next, an insulator 412a is deposited over the oxide 406d1. The insulator 412a can be deposited by a sputtering method, a CVD method, an MBE method, a PLD method, an ALD method, or the like (see FIGS. 13(A), 13(B), and 13(C)).

Here, fourth heat treatment can be performed. For the heat treatment, the conditions for the first heat treatment can be used. Through the heat treatment, the moisture concentration and the hydrogen concentration in the insulator 412a can be reduced. Note that the fourth heat treatment is not necessarily performed in some cases. In this embodiment, the fourth heat treatment is not performed.

Next, a conductor to be the conductor 404 is deposited. The conductor to be the conductor 404 can be deposited by a sputtering method, a CVD method, an MBE method, a PLD method, an ALD method, or the like.

The conductor 404 may be a multilayer film. For example, as the conductor to be the conductor 404, an oxide is deposited under conditions similar to those for the oxide 406c1, whereby oxygen can be added to the insulator 412a. Note that the oxygen added to the insulator 412a serves as excess oxygen.

Next, a conductor is deposited over the oxide by a sputtering method, whereby the oxide has reduced electric resistance and can be a conductor. Such a conductor can be referred to as an oxide conductor (OC) electrode. A conductor may be further deposited over the conductor over the OC electrode by a sputtering method or the like.

In this embodiment, titanium nitride is deposited by a sputtering method as a conductor to be the conductor 404a, and tungsten is deposited by a sputtering method as a conductor to be the conductor 404b.

Here, fifth heat treatment can be performed. For the heat treatment, the conditions for the first heat treatment can be used. Note that the fifth heat treatment is not necessarily performed in some cases. In this embodiment, the fifth heat treatment is not performed.

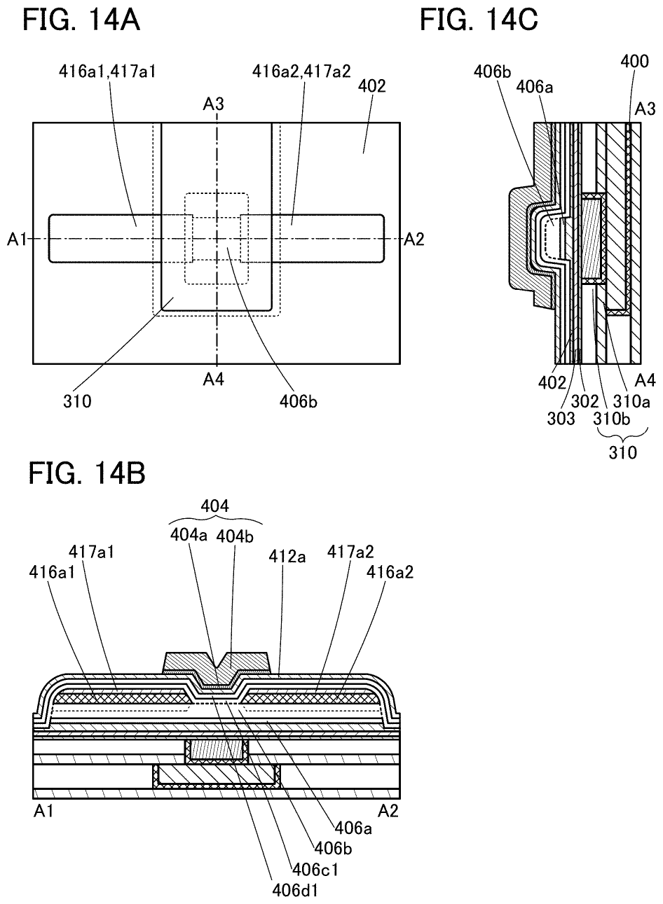

The conductor to be the conductor 404a and the conductor to be the conductor 404b are processed by a lithography method to form the conductor 404a and the conductor 404b (see FIGS. 14(A), 14(B), and 14(C)).

Next, an oxide to be the insulator 418 may be deposited. A metal oxide is preferably used for the deposition of the oxide to be the insulator 418, which can be performed by a sputtering method, a CVD method, an MBE method, a PLD method, an ALD method, or the like. For example, when aluminum oxide is deposited by an ALD method, the oxide to be the insulator 418 can be deposited to have few pinholes and uniform thickness on the top and side surfaces of the conductor 404, so that oxidation of the conductor 404 can be prevented. In this embodiment, aluminum oxide is deposited by an ALD method.

Next, the oxide to be the insulator 418, the insulator 412a, the oxide 406c1, and the oxide 406d1 are processed by a lithography method to form the insulator 418, the insulator 412, the oxide 230c, and the oxide 406d. An interface between the insulator 412 and the oxide 406c formed in this manner is hardly subjected to damage, which is preferable.

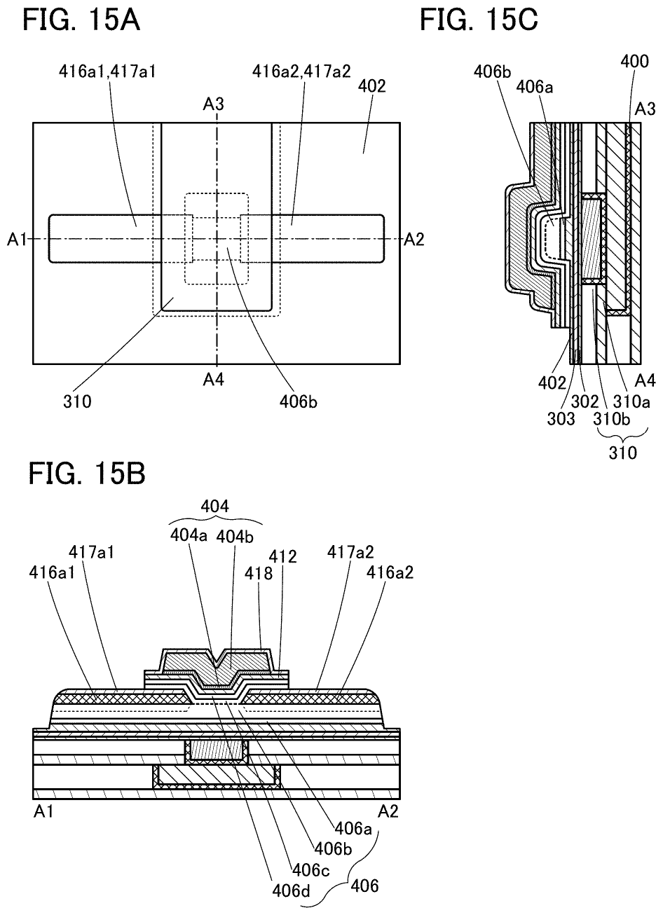

Here, end portions of the insulator 418, end portions of the insulator 412, end portions of the oxide 406c and the oxide 406d are aligned and positioned over the barrier film 417a1 and the barrier film 417a2 in the channel length direction, whereas they are positioned over the insulator 402 in one channel width direction (see FIGS. 15(A), 15(B), and 15(C)).

Next, the insulator 410 is deposited. The insulator 410 can be deposited by a sputtering method, a CVD method, an MBE method, a PLD method, an ALD method, or the like. Alternatively, a spin coating method, a dipping method, a droplet discharging method (such as an ink-jet method), a printing method (such as screen printing or offset printing), a doctor knife method, a roll coater method, a curtain coater method, or the like can be used.

The insulator 410 may be formed to have a flat top surface. For example, the top surface of the insulator 410 may have flatness immediately after the deposition. Alternatively, for example, the insulator 410 may have flatness by removing the insulator and the like from the top surface after the deposition so that the top surface becomes parallel to a reference surface such as a rear surface of the substrate. Such treatment is referred to as planarization treatment. Examples of the planarization treatment include CMP treatment and dry etching treatment. However, the top surface of the insulator 410 does not necessarily have flatness.

Next, the insulator 420 is deposited over the insulator 410. A metal oxide is preferably used for the deposition of the insulator 420, which can be performed by a sputtering method, a CVD method, an MBE method, a PLD method, an ALD method, or the like.

When aluminum oxide is deposited by a sputtering method using oxygen plasma for the insulator 420, oxygen can be added to the insulator 410. The added oxygen serves as excess oxygen in the insulator 410.

The insulator 420 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

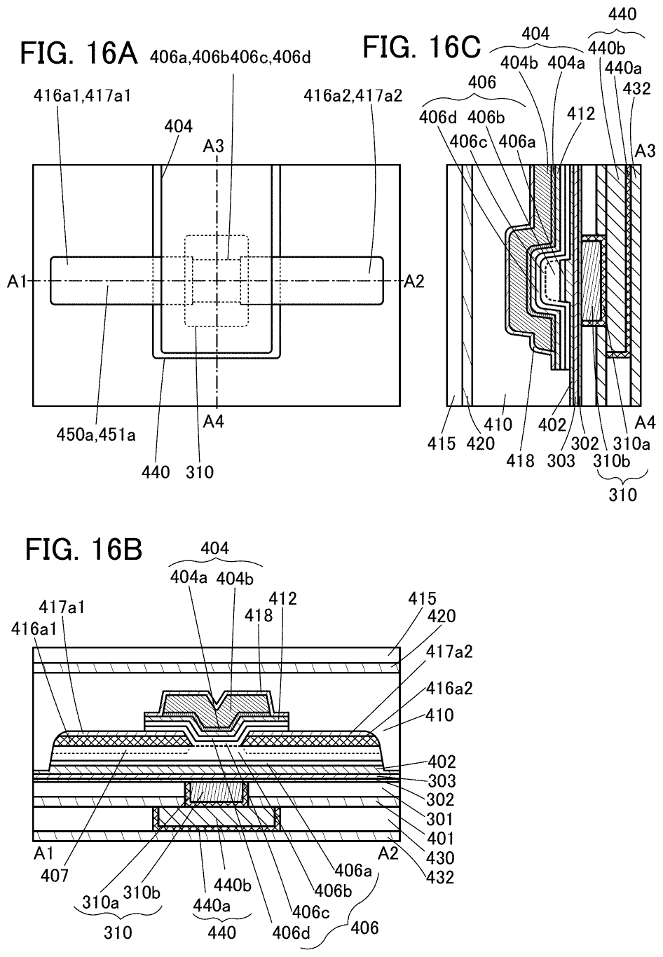

Here, sixth heat treatment can be performed. For the heat treatment, the conditions for the first heat treatment can be used. In this embodiment, the treatment is performed at 350° C. in an oxygen atmosphere for one hour (see FIGS. 16 (A), 16(B), and 16(C)).

Then, the insulator 415 is deposited over the insulator 420. A metal oxide is preferably used for the deposition of the insulator 415, which can be performed by a sputtering method, a CVD method, an MBE method, a PLD method, an ALD method, or the like.

Next, an opening reaching the conductor 416a1 through the insulator 415, the insulator 420, the insulator 410, and the barrier film 417a1, and an opening reaching the conductor 416a2 through the insulator 415, the insulator 420, the insulator 410, and the barrier film 417a2 are formed. The openings can be formed by a lithography method.

After that, an insulator to be the insulator 450a and the insulator 450b is deposited. The insulator to be the insulator 450a and the insulator 450b is preferably deposited using a metal oxide, which can be deposited by a sputtering method, a CVD method, an MBE method, a PLD method, an ALD method, or the like. In this embodiment, aluminum oxide is deposited by an ALD method.

Then, the insulator to be the insulator 450a and the insulator 450b is anisotropically etched by a dry etching method, whereby the insulators at the bottom surfaces of the openings and at the top surface of the insulator 415 are etched, whereas the insulator at the side surfaces of the openings are not etched, so that the insulator 450a and the insulator 450b are formed.

Next, a conductor to be the conductor 451a and the conductor 451b is deposited. The conductor to be the conductor 451a and the conductor 451b can be deposited by a sputtering method, a CVD method, an MBE method, a PLD method, an ALD method, or the like.

The conductor to be the conductor 451a and the conductor 451b can be a multilayer film. For example, a stacked-layer film of tungsten and tantalum nitride or titanium nitride can be employed. In this embodiment, a two-layer film of titanium nitride and tungsten is deposited.

Next, a conductor to be the conductor 452a and the conductor 452b is deposited, and then processed by a photolithography method to form the conductor 452a and the conductor 452b. The conductor to be the conductor 452a and the conductor 452b can be deposited by a sputtering method, a CVD method, an MBE method, a PLD method, an ALD method, or the like. The conductor 452a and the conductor 452b may be formed to be embedded in the insulator, in a manner similar to that of the conductor 440 or the like.

Through the above process, the semiconductor device including the transistor 1000 can be fabricated (see FIG. 1).

This embodiment can be implemented in appropriate combination with the structures described in the other embodiments, example, and the like.

### Embodiment 3

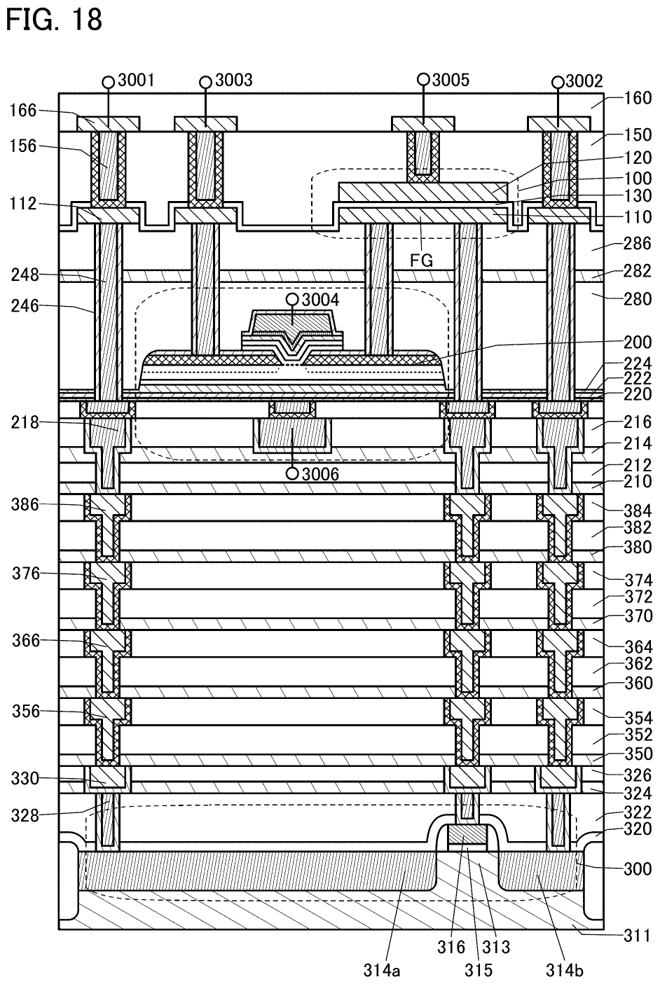

In this embodiment, one embodiment of a semiconductor device is described with reference to FIG. 18 to FIG. 23.

[Memory Device 1]

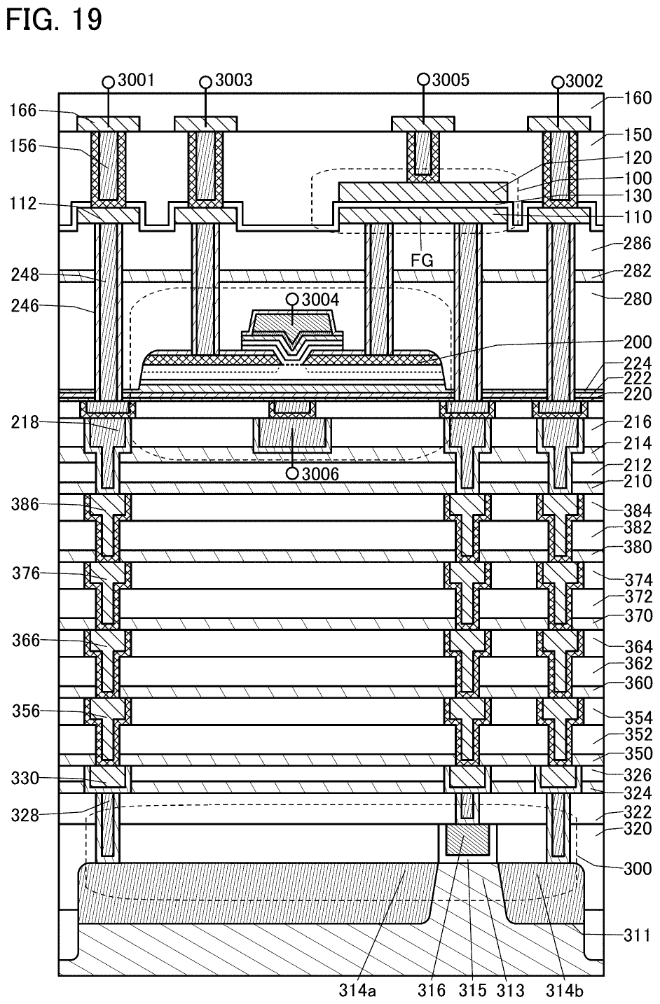

Semiconductor devices illustrated in FIG. 18 and FIG. 19 each include a transistor 300, a transistor 200, and a capacitor 100.

The transistor 200 is a transistor in which a channel is formed in a semiconductor layer including an oxide semiconductor. Since the off-state current of the transistor 200 is small, a memory device using the transistor 200 can retain stored data for a long time. In other words, since refresh operation is not required or frequency of refresh operation is extremely low, the power consumption of the memory device can be sufficiently reduced.

In FIG. 18 and FIG. 19, a wiring 3001 is electrically connected to a source of the transistor 300, and a wiring 3002 is electrically connected to a drain of the transistor 300. In addition, 3003 is electrically connected to one of a source and a drain of the transistor 200, a wiring 3004 is electrically connected to a first gate of the transistor 200, and a wiring 3006 is electrically connected to a second gate of the transistor 200. A gate of the transistor 300 and the other of the source and the drain of the transistor 200 are electrically connected to one electrode of the capacitor 100, and a wiring 3005 is electrically connected to the other electrode of the capacitor 100.

The semiconductor devices illustrated in FIG. 18 and FIG. 19 each have a feature that the potential of the gate of the transistor 300 can be retained, and thus enable writing, retaining, and reading of data as described below.

Writing and retaining of data will be described. First, the potential of the wiring 3004 is set to a potential at which the transistor 200 is brought into a conduction state, so that the transistor 200 is brought into a conduction state. Accordingly, the potential of the wiring 3003 is supplied to a node FG where the gate of the transistor 300 and the one electrode of the capacitor 100 are electrically connected to each other. That is, a predetermined charge is supplied to the gate of the transistor 300 (writing). Here, either of two charges providing different potential levels (hereinafter referred to as a Low-level charge and a High-level charge) is supplied. After that, the potential of the wiring 3004 is set to a potential at which the transistor 200 is brought into a non-conduction state, so that the transistor 200 is brought into a non-conduction state; thus, the charge is retained in the node FG (retaining).

In the case where the off-state current of the transistor 200 is small, the charge in the node FG is retained for a long time.

Next, reading of data will be described. An appropriate potential (a reading potential) is supplied to the wiring 3005 while a predetermined potential (a constant potential) is supplied to the wiring 3001, whereby the potential of the wiring 3002 varies depending on the amount of charge retained in the node FG. This is because when the transistor 300 is of an n-channel type, an apparent threshold voltage V_{th_H} in the case where the High-level charge is supplied to the gate of the transistor 300 is lower than an apparent threshold voltage V_{th_L} in the case where the Low-level charge is supplied to the gate of the transistor 300. Here, an apparent threshold voltage refers to the potential of the wiring 3005 which is needed to bring the transistor 300 into a “conduction state”. Thus, the potential of the wiring 3005 is set to a potential V₀ which is between V_{th_H} and V_{th_L}, whereby charge supplied to the node FG can be determined. For example, in the case where the High-level charge is supplied to the node FG in writing and the potential of the wiring 3005 is V₀ (>V_{th_H}), the transistor 300 is brought into a “conduction state”. On the other hand, in the case where the Low-level charge is supplied to the node FG, the transistor 300 remains in a “non-conduction state” even when the potential of the wiring 3005 is V₀ (<V_{th_L}). Thus, the data retained in the node FG can be read by determining the potential of the wiring 3002.

<Structure of Semiconductor Device 1>

The semiconductor device of one embodiment of the present invention includes the transistor 300, the transistor 200, and the capacitor 100 as illustrated in FIG. 18. The transistor 200 is provided above the transistor 300, and the capacitor 100 is provided above the transistor 300 and the transistor 200.

The transistor 300 is provided over a substrate 311 and includes a conductor 316, an insulator 315, a semiconductor region 313 that is part of the substrate 311, and a low-resistance region 314a and a low-resistance region 314b functioning as a source region and a drain region.

The transistor 300 is of either a p-channel type or an n-channel type.

A region of the semiconductor region 313 where a channel is formed, a region in the vicinity thereof, the low-resistance region 314a and the low-resistance region 314b functioning as a source region and a drain region, and the like preferably contain a semiconductor such as a silicon-based semiconductor, further preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing is used. Alternatively, the transistor 300 may be an HEMT (High Electron Mobility Transistor) using GaAs and GaAlAs, or the like.

The low-resistance region 314a and the low-resistance region 314b contain an element which imparts n-type conductivity, such as arsenic or phosphorus, or an element which imparts p-type conductivity, such as boron, in addition to the semiconductor material used for the semiconductor region 313.

For the conductor 316 functioning as a gate electrode, a semiconductor material such as silicon containing the element which imparts n-type conductivity, such as arsenic or phosphorus, or the element which imparts p-type conductivity, such as boron, or a conductive material such as a metal material, an alloy material, or a metal oxide material can be used.

Note that a work function of a conductor is determined by a material thereof, whereby the threshold voltage can be adjusted. Specifically, it is preferable to use a material such as titanium nitride, tantalum nitride, or the like for the conductor. Furthermore, in order to ensure both conductivity and embeddability, it is preferable to use a stacked layer of metal materials such as tungsten and aluminum for the conductor, and it is particularly preferable to use tungsten in terms of heat resistance.

Note that the transistor 300 illustrated in FIG. 18 is just an example and the structure is not limited thereto; an appropriate transistor can be used in accordance with a circuit configuration or a driving method.

An insulator 320, an insulator 322, an insulator 324, and an insulator 326 are provided to be stacked in this order to cover the transistor 300.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

The insulator 322 may have a function of a planarization film for planarizing a level difference caused by the transistor 300 or the like provided below the insulator 322. For example, the top surface of the insulator 322 may be planarized by planarization treatment using a chemical mechanical polishing (CMP) method or the like to improve planarity.

As the insulator 324, it is preferable to use a film having a barrier property that prevents diffusion of impurities and hydrogen from the substrate 311, the transistor 300, or the like into a region where the transistor 200 is provided.

As an example of the film having a barrier property against hydrogen, silicon nitride formed by a CVD method can be used. Here, the diffusion of hydrogen into a semiconductor element including an oxide semiconductor, such as the transistor 200, degrades the characteristics of the semiconductor element in some cases. Therefore, a film that inhibits diffusion of hydrogen is preferably used between the transistor 200 and the transistor 300. Specifically, the film that inhibits diffusion of hydrogen is a film from which a small amount of hydrogen is released.

The amount of released hydrogen can be analyzed by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm² in the TDS analysis in the range of 50° C. to 500° C., for example.

Note that the permittivity of the insulator 326 is preferably lower than that of the insulator 324. For example, the dielectric constant of the insulator 326 is preferably lower than 4, further preferably lower than 3. For example, the dielectric constant of the insulator 326 is preferably 0.7 times or less that of the insulator 324, further preferably 0.6 times or less that of the insulator 324. When a material with a low permittivity is used for an interlayer film, the parasitic capacitance between wirings can be reduced.

Moreover, a conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 each have a function of a plug or a wiring. In addition, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and part of a conductor functions as a plug.

As a material for each of the plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is particularly preferable to use tungsten. Alternatively, it is preferable to form the plugs and wirings with a low-resistance conductive material such as aluminum or copper. The use of a low-resistance conductive material can reduce wiring resistance.

A wiring layer may be provided over the insulator 326 and the conductor 330. For example, in FIG. 18, an insulator 350, an insulator 352, and an insulator 354 are provided to be stacked in this order. Furthermore, a conductor 356 is formed in the insulator 350, the insulator 352, and the insulator 354. The conductor 356 has a function of a plug or a wiring. Note that the conductor 356 can be provided using a material similar to those for the conductor 328 and the conductor 330.

Note that for example, as the insulator 350, an insulator having a barrier property against hydrogen is preferably used, like the insulator 324. Furthermore, the conductor 356 preferably includes a conductor having a barrier property against hydrogen. The conductor having a barrier property against hydrogen is formed particularly in an opening included in the insulator 350 having a barrier property against hydrogen. In such a structure, the transistor 300 and the transistor 200 can be separated by a barrier layer, so that diffusion of hydrogen from the transistor 300 into the transistor 200 can be inhibited.

Note that as the conductor having a barrier property against hydrogen, tantalum nitride is preferably used, for example. In addition, by stacking tantalum nitride and tungsten, which has high conductivity, the diffusion of hydrogen from the transistor 300 can be inhibited while the conductivity as a wiring is kept. In that case, it is preferable to have a structure in which a tantalum nitride layer having a barrier property against hydrogen is in contact with the insulator 350 having a barrier property against hydrogen.

A wiring layer may be provided over the insulator 354 and the conductor 356. For example, in FIG. 18, an insulator 360, an insulator 362, and an insulator 364 are provided to be stacked in this order. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

Note that for example, as the insulator 360, an insulator having a barrier property against hydrogen is preferably used, like the insulator 324. Furthermore, the conductor 366 preferably includes a conductor having a barrier property against hydrogen. The conductor having a barrier property against hydrogen is formed particularly in an opening included in the insulator 360 having a barrier property against hydrogen. In such a structure, the transistor 300 and the transistor 200 can be separated by a barrier layer, so that the diffusion of hydrogen from the transistor 300 into the transistor 200 can be inhibited.

A wiring layer may be provided over the insulator 364 and the conductor 366. For example, in FIG. 18, an insulator 370, an insulator 372, and an insulator 374 are stacked in this order. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

Note that for example, as the insulator 370, an insulator having a barrier property against hydrogen is preferably used, like the insulator 324. Furthermore, the conductor 376 preferably includes a conductor having a barrier property against hydrogen. The conductor having a barrier property against hydrogen is formed particularly in an opening included in the insulator 370 having a barrier property against hydrogen. In such a structure, the transistor 300 and the transistor 200 can be separated by a barrier layer, so that the diffusion of hydrogen from the transistor 300 into the transistor 200 can be inhibited.

A wiring layer may be provided over the insulator 374 and the conductor 376. For example, in FIG. 18, an insulator 380, an insulator 382, and an insulator 384 are provided to be stacked in this order. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

Note that for example, as the insulator 380, an insulator having a barrier property against hydrogen is preferably used, like the insulator 324. Furthermore, the conductor 386 preferably includes a conductor having a barrier property against hydrogen. The conductor having a barrier property against hydrogen is formed particularly in an opening included in the insulator 380 having a barrier property against hydrogen. In such a structure, the transistor 300 and the transistor 200 can be separated by a barrier layer, so that the diffusion of hydrogen from the transistor 300 into the transistor 200 can be inhibited.

An insulator 210, an insulator 212, an insulator 214, and an insulator 216 are provided stacked over the insulator 384 in this order. A material having a barrier property against oxygen and hydrogen is preferably used for any of the insulator 210, the insulator 212, the insulator 214, and the insulator 216.

As the insulator 210 and the insulator 214, for example, it is preferably to use a film having a barrier property that inhibits diffusion of hydrogen and impurities from the substrate 311, a region where the transistor 300 is provided, or the like into a region where the transistor 200 is provided. Therefore, a material similar to that for the insulator 324 can be used.

As an example of the film having a barrier property against hydrogen, silicon nitride formed by a CVD method can be used. Here, the diffusion of hydrogen into a semiconductor element including an oxide semiconductor, such as the transistor 200, degrades the characteristics of the semiconductor element in some cases. Therefore, a film that inhibits diffusion of hydrogen is preferably used between the transistor 200 and the transistor 300. Specifically, the film that inhibits diffusion of hydrogen is a film from which a small amount of hydrogen is released.

As the film having a barrier property against hydrogen, for example, a metal oxide such as aluminum oxide, hafnium oxide, or tantalum oxide is preferably used for each of the insulator 210 and the insulator 214.

In particular, aluminum oxide has an excellent blocking effect that inhibits the passage of both oxygen and impurities such as hydrogen and moisture which are factors of a change in electrical characteristics of the transistor. Accordingly, aluminum oxide can prevent entry of impurities such as hydrogen and moisture into the transistor 200 in a manufacturing process and after manufacturing of the transistor. In addition, release of oxygen from the oxide included in the transistor 200 can be inhibited. Therefore, aluminum oxide is suitably used as a protective film for the transistor 200.

For example, for the insulator 212 and the insulator 216, a material similar to that for the insulator 320 can be used. Furthermore, when a material with a relatively low permittivity is used for an interlayer film, the parasitic capacitance between wirings can be reduced. For example, a silicon oxide film, a silicon oxynitride film, or the like can be used as the insulator 212 and the insulator 216.

Moreover, a conductor 218, and a conductor and the like included in the transistor 200 are embedded in the insulator 210, the insulator 212, the insulator 214, and the insulator 216. Note that the conductor 218 has a function of a plug or a wiring that is electrically connected to the capacitor 100 or the transistor 300. The conductor 218 can be provided using a material similar to those for the conductor 328 and the conductor 330.

In particular, the conductor 218 in a region in contact with the insulator 210 and the insulator 214 is preferably a conductor having a barrier property against oxygen, hydrogen, and water. In such a structure, the transistor 300 and the transistor 200 can be separated by a layer having a barrier property against oxygen, hydrogen, and water; thus, the diffusion of hydrogen from the transistor 300 into the transistor 200 can be inhibited.

The transistor 200 is provided above the insulator 216. Note that the structure of the transistor included in the semiconductor device described in the above embodiments is used as that of the transistor 200. Note that the transistor 200 illustrated in FIG. 18 is just an example and the structure is not limited thereto; an appropriate transistor may be used in accordance with a circuit configuration or a driving method.

The insulator 280 is provided above the transistor 200. In the insulator 280, an excess-oxygen region is preferably formed. In particular, in the case of using an oxide semiconductor in the transistor 200, when an insulator including an excess-oxygen region is provided for an interlayer film or the like in the vicinity of the transistor 200, oxygen vacancies in the oxide included in the transistor 200 are reduced, whereby the reliability can be improved. The insulator 280 that covers the transistor 200 may function as a planarization film that covers an uneven shape thereunder.

As the insulator including an excess-oxygen region, specifically, an oxide material that releases part of oxygen by heating is preferably used. An oxide that releases part of oxygen by heating is an oxide film in which the amount of released oxygen converted into oxygen atoms is greater than or equal to 1.0×10¹⁸ atoms/cm³, preferably greater than or equal to 3.0×10²⁰ atoms/cm³ in TDS analysis. Note that the temperature of the film surface in the TDS analysis is preferably higher than or equal to 100° C. and lower than or equal to 700° C., or higher than or equal to 100° C. and lower than or equal to 500° C.

For example, as such a material, a material containing silicon oxide or silicon oxynitride is preferably used. Alternatively, a metal oxide can be used. Note that in this specification, silicon oxynitride refers to a material that contains oxygen at a higher proportion than nitrogen, and silicon nitride oxide refers to a material that contains nitrogen at a higher proportion than oxygen.

The insulator 282 is provided over the insulator 280. A material having a barrier property against oxygen and hydrogen is preferably used for the insulator 282. Thus, a material similar to that for the insulator 214 can be used for the insulator 282. For the insulator 282, a metal oxide such as aluminum oxide, hafnium oxide, or tantalum oxide is preferably used, for example.

In particular, aluminum oxide has an excellent blocking effect that inhibits the passage of both oxygen and impurities such as hydrogen and moisture which are factors of a change in electrical characteristics of the transistor. Accordingly, aluminum oxide can prevent entry of impurities such as hydrogen and moisture into the transistor 200 in a manufacturing process and after manufacturing of the transistor. In addition, release of oxygen from the oxide included in the transistor 200 can be inhibited. Therefore, aluminum oxide is suitably used as a protective film for the transistor 200.

An insulator 286 is provided over the insulator 282. A material similar to that for the insulator 320 can be used for the insulator 286. When a material with a relatively low permittivity is used for an interlayer film, the parasitic capacitance between wirings can be reduced. For example, a silicon oxide film, a silicon oxynitride film, or the like can be used for the insulator 286.

An insulator 246, a conductor 248, and the like are embedded in the insulator 220, the insulator 222, the insulator 224, the insulator 280, the insulator 282, and the insulator 286.

The insulator 246 is formed in the following manner: an opening is formed, an insulator is deposited in contact with the inner wall of the opening by an ALD method or the like, and then the insulator at the bottom portion of the opening and top surface portion of the insulator 286 is removed by a dry etching method, whereby the insulator is formed in contact with the inner wall of the opening. The insulator 246 preferably has a function of inhibiting the passage of impurities such as hydrogen and water. For the insulator 246, a metal oxide such as aluminum oxide, hafnium oxide, or tantalum oxide can be used, for example.

The insulator 246 prevents excess oxygen contained in the insulator 280 from diffusing into the conductor 248 and oxidizing the conductor 248. Furthermore, impurities such as hydrogen and water contained in the conductor 248 can be prevented from diffusing outward.

The conductor 248 has a function of a plug or a wiring that is electrically connected to the capacitor 100, the transistor 200, or the transistor 300. The conductor 248 can be provided using a material similar to those for the conductor 328 and the conductor 330.

The capacitor 100 is provided above the transistor 200. The capacitor 100 includes a conductor 110, a conductor 120, and an insulator 130.

A conductor 112 may be provided over the insulator 246 and the conductor 248. Note that the conductor 112 has a function of a plug or a wiring that is electrically connected to the capacitor 100, the transistor 200, or the transistor 300. The conductor 110 has a function of the electrode of the capacitor 100. Note that the conductor 112 and the conductor 110 can be formed at the same time.

As the conductor 112 and the conductor 110, a metal film containing an element selected from molybdenum, titanium, tantalum, tungsten, aluminum, copper, chromium, neodymium, and scandium; a metal nitride film containing any of the above elements as its component (e.g., a tantalum nitride film, a titanium nitride film, a molybdenum nitride film, or a tungsten nitride film); or the like can be used. Alternatively, a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added can be used.

Although the conductor 112 and the conductor 110 having a single-layer structure are illustrated in FIG. 18, the structure is not limited thereto; a stacked-layer structure of two or more layers may be employed. For example, between a conductor having a barrier property and a conductor having high conductivity, a conductor which is highly adhesive to the conductor having a barrier property and the conductor having high conductivity may be formed.

As a dielectric of the capacitor 100, the insulator 130 is provided over the conductor 112 and the conductor 110. The insulator 130 can be provided to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like.

For example, a material with high dielectric strength, such as silicon oxynitride, is preferably used for the insulator 130. In the capacitor 100 with the structure, owing to the insulator 130, the dielectric strength can be increased and the electrostatic breakdown of the capacitor 100 can be inhibited.

Over the insulator 130, the conductor 120 is provided to overlap with the conductor 110. Note that a conductive material such as a metal material, an alloy material, or a metal oxide material can be used for the conductor 120. It is preferable to use a high-melting-point material which has both heat resistance and conductivity, such as tungsten or molybdenum, and it is particularly preferable to use tungsten. Furthermore, in the case where the conductor 120 is formed concurrently with another component such as a conductor, Cu (copper), A1 (aluminum), or the like which is a low-resistance metal material is used.

An insulator 150 is provided over the conductor 120 and the insulator 130. The insulator 150 can be provided using a material similar to that for the insulator 320. Furthermore, the insulator 150 may function as a planarization film that covers an uneven shape thereunder.

The above is the description of the structure example. With the use of the structure, a change in electrical characteristics can be reduced and reliability can be improved in a semiconductor device using a transistor including an oxide semiconductor. Alternatively, a transistor including an oxide semiconductor with a high on-state current can be provided. Alternatively, a transistor including an oxide semiconductor with a low off-state current can be provided. Alternatively, a semiconductor device with low power consumption can be provided.

<Modification Example 1 of Memory Device 1>

FIG. 19 illustrates a modification example of this embodiment. FIG. 19 is different from FIG. 18 in the structure of the transistor 300.

In the transistor 300 illustrated in FIG. 19, the semiconductor region 313 (part of the substrate 311) where the channel is formed has a protruding shape. Furthermore, the conductor 316 is provided to cover the top surface and side surfaces of the semiconductor region 313 with the insulator 315 therebetween. Note that a material for adjusting the work function may be used for the conductor 316. Such a transistor 300 is also referred to as a FIN transistor because a protruding portion of the semiconductor substrate is utilized. Note that an insulator functioning as a mask for forming the protruding portion may be provided in contact with the top surface of the protruding portion. Although the case where the protruding portion is formed by processing part of the semiconductor substrate is described here, a semiconductor film having a protruding shape may be formed by processing an SOI substrate.

The above is the description of the modification example. With the use of the structure, a change in electrical characteristics can be reduced and reliability can be improved in a semiconductor device using a transistor including an oxide semiconductor. Alternatively, a transistor including an oxide semiconductor with a high on-state current can be provided. Alternatively, a transistor including an oxide semiconductor with a low off-state current can be provided. Alternatively, a semiconductor device with low power consumption can be provided.

<Modification Example 2 of Memory Device 1>

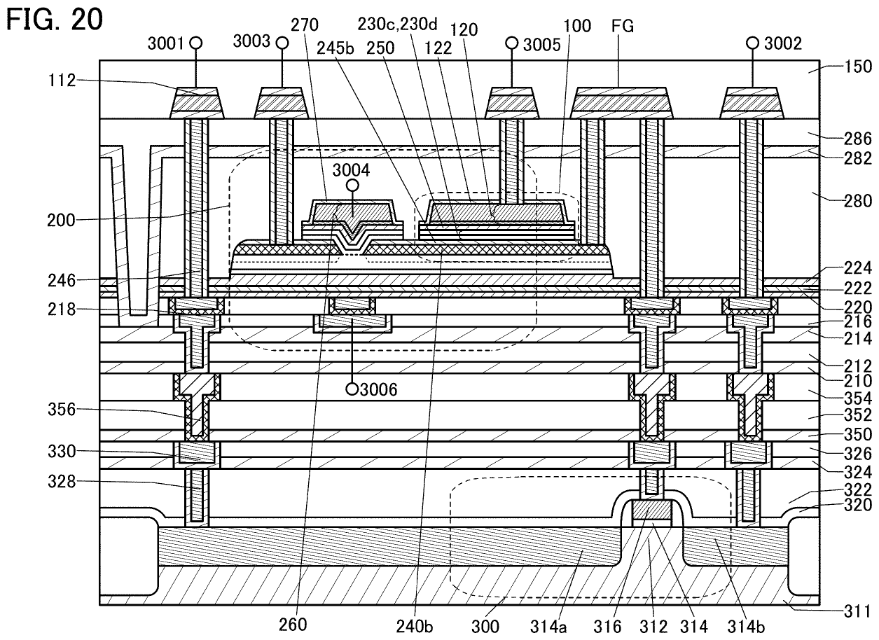

FIG. 20 illustrates a modification example of the memory device. FIG. 20 is different from FIG. 18 and FIG. 19 in the position of the capacitor 100 and the like.

The capacitor 100 illustrated in FIG. 20 is formed in the same layer as the transistor 200. The capacitor 100 illustrated in FIG. 20 includes a barrier layer 122, the conductor 120, an insulator 250, an oxide 230c, an oxide 230d, a barrier layer 245b, and a conductor 240b. The conductor 120 and the conductor 240b have a function of the electrodes of the capacitor 100, and the barrier layer 245b, the oxide 230c, the oxide 230d, and the insulator 250 have a function of a dielectric of the capacitor 100. Note that the barrier layer 122 has a function of preventing oxidation of the conductor 120.

The conductor 120 is in the same layer as a conductor 260 and the barrier layer 122 is in the same layer as a barrier layer 270. Thus, the conductor 120 can be formed in the same step as the conductor 260. Similarly, the barrier layer 122 can be formed in the same step as the barrier layer 270. Accordingly, the process can be shortened and the productivity can be improved.

Furthermore, with the use of the structure illustrated in FIG. 20, the transistor 200 and the capacitor 100 is formed concurrently, whereby the process can be shortened.

With the use of the structure, a change in electrical characteristics can be reduced and reliability can be improved in a memory device using a transistor including an oxide semiconductor. Alternatively, a transistor including an oxide semiconductor with a high on-state current can be provided. Alternatively, a transistor including an oxide semiconductor with a low off-state current can be provided. Alternatively, a memory device with low power consumption can be provided.

The above is the description of the modification example. With the use of the structure, a change in electrical characteristics can be reduced and reliability can be improved in a semiconductor device using a transistor including an oxide semiconductor. Alternatively, a transistor including an oxide semiconductor with a high on-state current can be provided. Alternatively, a transistor including an oxide semiconductor with a low off-state current can be provided. Alternatively, a semiconductor device with low power consumption can be provided.

<Structure of Memory Cell Array>

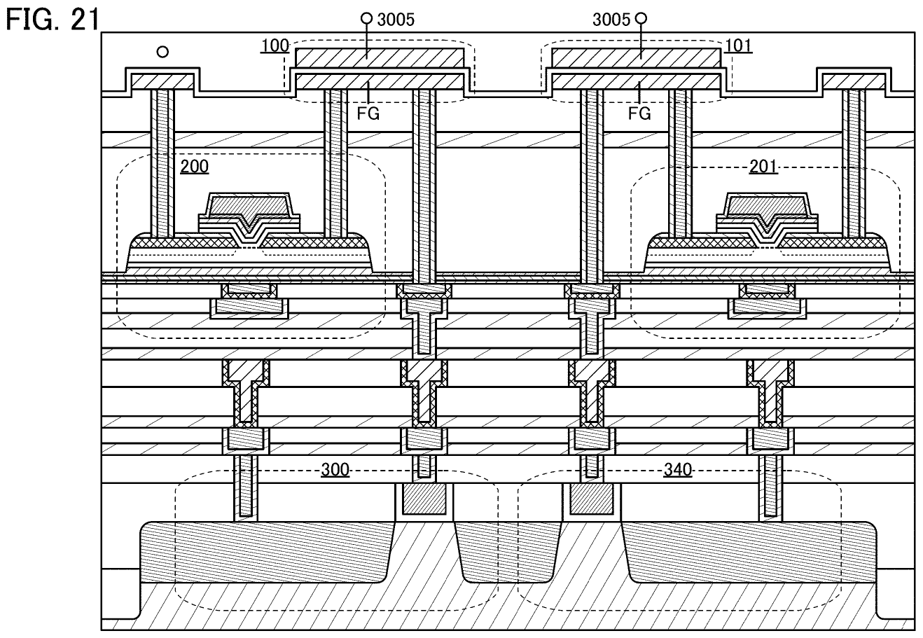

FIG. 21 illustrates an example of a memory cell array of this embodiment. By arranging semiconductor devices illustrated in FIG. 18 and FIG. 19 in a matrix, a memory cell array can be formed. FIG. 21 is a cross-sectional view which illustrates an extracted part of a row in which the memory devices illustrated in FIG. 18 are arranged in a matrix.

In FIG. 21, the semiconductor device including the transistor 300, the transistor 200, and the capacitor 100 and a semiconductor device including a semiconductor device including a transistor 340, a transistor 201, and a capacitor 101 are arranged in the same row.

As illustrated in FIG. 21, the memory cell array includes a plurality of transistors (the transistor 200, the transistor 201, the transistor 300, and the transistor 340 in the drawing).

Note that in the case where memory cells are arranged in an array, data of a desired memory cell needs to be read at the time of reading. For example, in the case where the transistor 300 is of an n-channel type and a memory cell array has a NOR-type structure, only data of a desired memory cell can be read by bringing the transistors 300 of memory cells from which data is not read into a non-conduction state. In that case, a potential at which the transistor 300 is brought into a “non-conduction state” regardless of the charge supplied to the node FG, that is, a potential lower than V_{th_H} is supplied to the wiring 3005 connected to the memory cells from which data is not read. Alternatively, in the case where the transistor 300 is of an n-channel type and a memory cell array has a NAND-type structure, for example, only data of a desired memory cell can be read by bringing the transistors 300 of memory cells from which data is not read into a conduction state. In that case, a potential at which the transistor 300 is brought into a “conduction state” regardless of the charge supplied to the node FG, that is, a potential higher than V_{th_L} is supplied to the wiring 3005 connected to the memory cells from which data is not read. The above description is applied to the transistor 340.

[Memory Device 2]

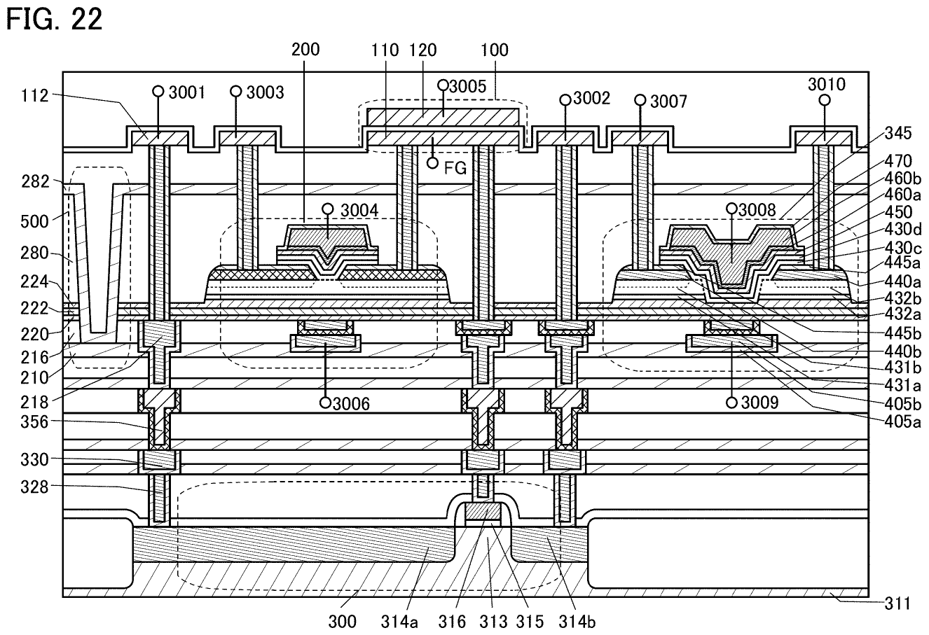

FIG. 22 illustrates an example of a memory device using the semiconductor device of one embodiment of the present invention.

The memory device illustrated in FIG. 22 includes a transistor 345 in addition to the semiconductor device illustrated in FIG. 18 that includes the transistor 200, the transistor 300, and the capacitor 100.

The transistor 345 can control a second gate voltage of the transistor 200. For example, a structure is employed in which a first gate and a second gate of the transistor 345 are diode-connected to a source thereof, and the source of the transistor 345 is connected to the second gate of the transistor 200. When a negative potential of the second gate of the transistor 200 is retained in this structure, a first gate-source voltage and a second gate-source voltage of the transistor 345 are 0 V. In the transistor 345, a drain current when the second gate voltage and the first gate voltage are 0 V is extremely low; thus, the negative potential of the second gate of the transistor 200 can be maintained for a long time even without power supply to the transistor 200 and the transistor 345. Accordingly, the memory device including the transistor 200 and the transistor 345 can retain stored data for a long time.

In FIG. 22, the wiring 3001 is electrically connected to the source of the transistor 300 and the wiring 3002 is electrically connected to the drain of the transistor 300. The wiring 3003 is electrically connected to one of the source and the drain of the transistor 200, the wiring 3004 is electrically connected to a gate of the transistor 200, and the wiring 3006 is electrically connected to a back gate of the transistor 200. The gate of the transistor 300 and the other of the source and the drain of the transistor 200 are electrically connected to one electrode of the capacitor 100, and the wiring 3005 is electrically connected to the other electrode of the capacitor 100. A wiring 3007 is electrically connected to the source of the transistor 345, a wiring 3008 is electrically connected to a gate of the transistor 345, a wiring 3009 is electrically connected to a back gate of the transistor 345, and a wiring 3010 is electrically connected to a drain of the transistor 345. Here, the wiring 3006, the wiring 3007, the wiring 3008, and the wiring 3009 are electrically connected to each other.

The memory device illustrated in FIG. 22 has a feature that the potential of the gate of the transistor 300 can be retained and thus enables writing, retaining, and reading of data as described below.

When the memory devices illustrated in FIG. 22 are arranged in a matrix like the memory devices illustrated in FIG. 18, a memory cell array can be formed. Note that one transistor 345 can control second gate voltages of the plurality of transistors 200. For this reason, a smaller number of the transistors 345 than the transistors 200 are preferably provided.

<Structure of Memory Device 2>

The transistor 345 is a transistor formed in the same layer as the transistor 200 and thus can be fabricated in parallel. The transistor 345 includes a conductor 460 (a conductor 460a and a conductor 460b) functioning as a first gate electrode; a conductor 405 (a conductor 405a and a conductor 405b) functioning as a second gate electrode; a barrier layer 470 in contact with the conductor 460; the insulator 220, the insulator 222, the insulator 224, and the insulator 450 functioning as gate insulating layers; an oxide 430c and an oxide 430d including a region where a channel is formed; a conductor 440a, an oxide 431a, and an oxide 431b functioning as one of the source and the drain; a conductor 440b, an oxide 432a, and an oxide 432b functioning as the other of the source and the drain; and a barrier layer 445 (a barrier layer 445a and a barrier layer 445b).

In the oxide 430c functioning as an active layer of the transistor 345, oxygen vacancies are reduced and impurities such as hydrogen and water are also reduced. Accordingly, the threshold voltage of the transistor 345 can be higher than 0 V, an off-state current can be reduced, and the drain current when the second gate voltage and the first gate voltage are 0 V can be extremely low.

Furthermore, a dicing line (also referred to as a scribe line, a dividing line, or a cutting line) that is provided when a large-sized substrate is divided into semiconductor elements so that a plurality of semiconductor devices are obtained in a chip form will be described. Examples of a dividing method include the case where a groove (a dicing line) for dividing the semiconductor elements is formed on the substrate, and then the substrate is cut along the dicing line to divide (split) it into a plurality of semiconductor devices. For example, a structure 500 illustrated in FIG. 22 illustrates a cross section in the vicinity of the dicing line.

As illustrated in the structure 500, for example, an opening is provided in the insulator 280, the insulator 224, the insulator 222, the insulator 220, and the insulator 216 in the vicinity of a region overlapping with the dicing line provided in an end portion of the memory cell including the transistor 200 or the transistor 345. Furthermore, the insulator 282 is provided to cover side surfaces of the insulator 280, the insulator 224, the insulator 222, the insulator 220, and the insulator 216.

Thus, in the opening portion, the insulator 222 and the insulator 210 are in contact with the insulator 282. In that case, when at least one of the insulator 222 and the insulator 210 is formed using the same material and the same method as those for the insulator 282, the adhesion therebetween can be improved. For example, aluminum oxide can be used.

With the structure, the insulator 280, the transistor 200, and the transistor 345 can be enclosed with the insulator 210, the insulator 222, and the insulator 282. The insulator 210, the insulator 222, and the insulator 282 have a function of inhibiting the diffusion of oxygen, hydrogen, and water; thus, even when the substrate is divided for each circuit region where the semiconductor element of this embodiment is formed, to be processed into a plurality of chips, the entry and diffusion of impurities such as hydrogen and water from the direction of a side surface of the divided substrate to the transistor 200 or the transistor 345 can be prevented.

Furthermore, with the structure, excess oxygen in the insulator 280 can be prevented from diffusing to the outside of the insulator 282 and the insulator 222. Accordingly, excess oxygen in the insulator 280 is efficiently supplied to the oxide where the channel is formed in the transistor 200 or the transistor 345. The oxygen can reduce oxygen vacancies in the oxide where the channel is formed in the transistor 200 or the transistor 345. Thus, the oxide where the channel is formed in the transistor 200 or the transistor 345 can be an oxide semiconductor having a low density of defect states and stable characteristics. That is, a change in electrical characteristics of the transistor 200 or the transistor 345 can be reduced and the reliability can be improved.

<Modification Example 1 of Memory Device 2>

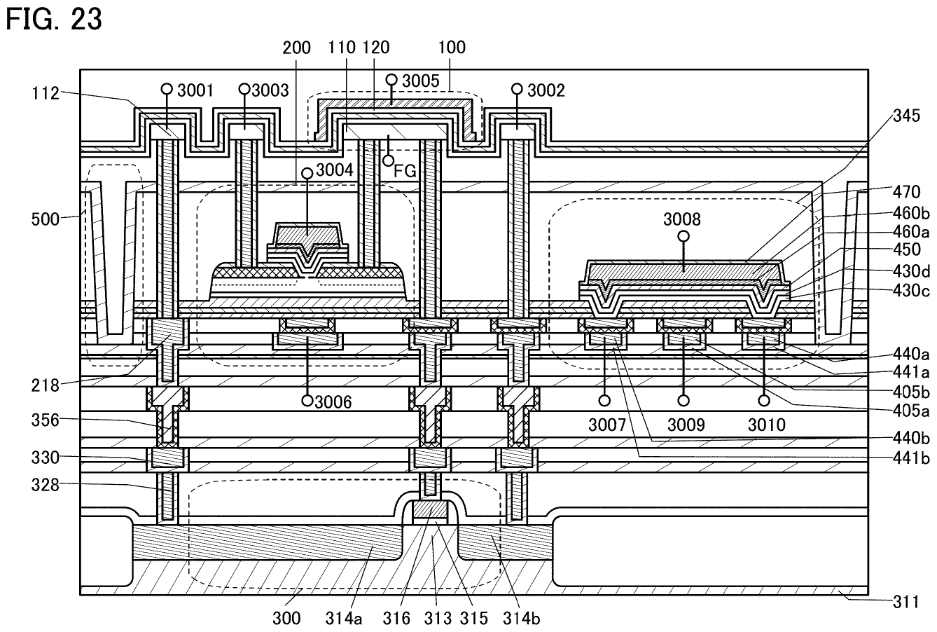

Furthermore, FIG. 23 illustrates a modification example of this embodiment. FIG. 23 is different from FIG. 22 in the structure of the transistor 345.

In the transistor 345 illustrated in FIG. 23, the conductor 440a, a conductor 441a, the conductor 440b, and a conductor 441b are provided in the same layer as the conductor 405. That is, the source electrode and the drain electrode of the transistor 345 can be provided concurrently with the second gate electrode.

The above is the description of the modification example. With the use of the structure, a change in electrical characteristics due to the arrangement density of transistor and variation in reliability can be reduced and reliability can be improved in a semiconductor device using a transistor including an oxide semiconductor. Alternatively, a transistor including an oxide semiconductor with a high on-state current can be provided. Alternatively, a transistor including an oxide semiconductor with a low off-state current can be provided. Alternatively, a semiconductor device with low power consumption can be provided. Alternatively, owing to the independence on the arrangement density of transistor, a semiconductor device with a high design flexibility can be provided.

This embodiment can be implemented in appropriate combination with the structures described in the other embodiments, example, and the like.

### Embodiment 4

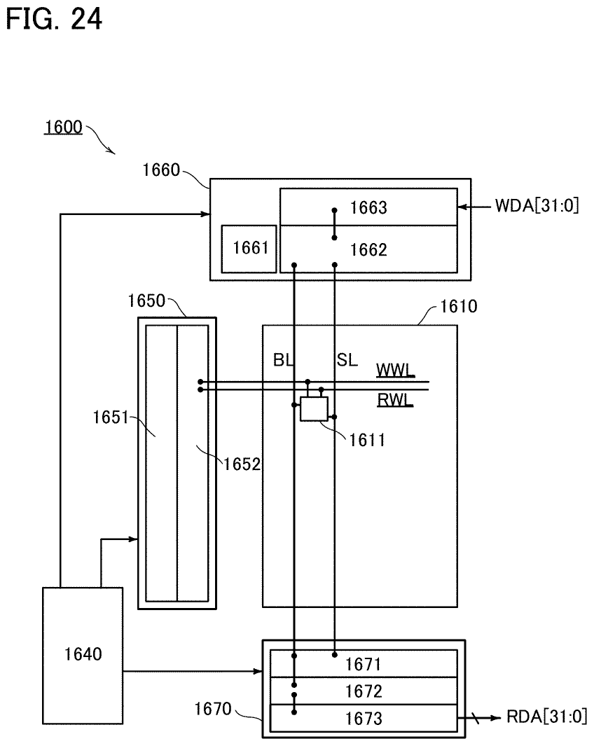

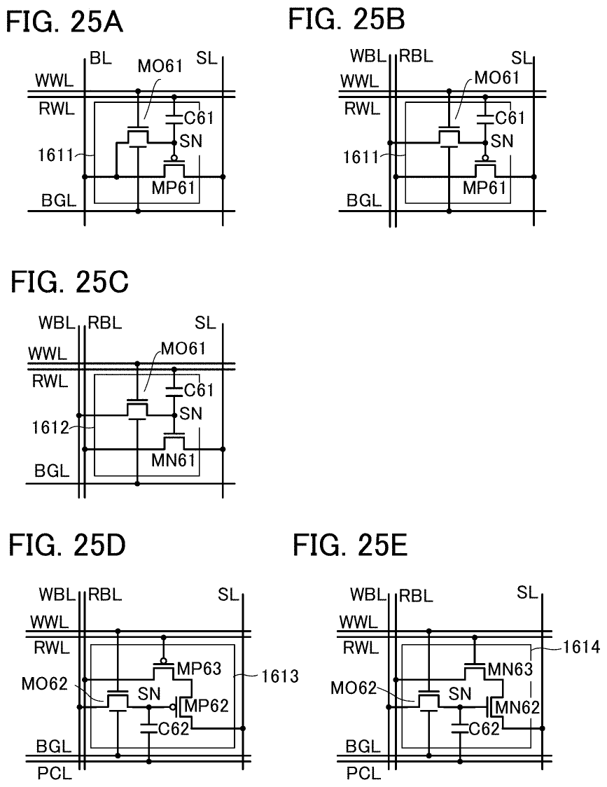

In this embodiment, a NOSRAM is described as an example of a memory device of one embodiment of the present invention, which includes a capacitor and a transistor using an oxide as a semiconductor (hereinafter referred to as an OS transistor) with reference to FIG. 24 and FIG. 25. A NOSRAM (registered trademark) is an abbreviation of “Nonvolatile Oxide Semiconductor RAM”, which indicates RAM including a gain cell (2T or 3T) memory cell. Note that hereinafter, a memory device using an OS transistor, such as the NOSRAM, is referred to as an OS memory in some cases.

A memory device in which OS transistors are used in memory cells (hereinafter referred to as an “OS memory”) is used in the NOSRAM. The OS memory is a memory including at least a capacitor and an OS transistor that controls charging and discharging of the capacitor. Since the OS transistor is a transistor with an extremely low off-state current, the OS memory has excellent retention characteristics and thus can function as a nonvolatile memory.

<<NOSRAM>>

FIG. 24 shows a configuration example of the NOSRAM. A NOSRAM 1600 shown in FIG. 24 includes a memory cell array 1610, a controller 1640, a row driver 1650, a column driver 1660, and an output driver 1670. Note that the NOSRAM 1600 is a multilevel NOSRAM in which one memory cell stores multilevel data.

The memory cell array 1610 includes a plurality of memory cells 1611, a plurality of word lines WWL, a plurality of word lines RWL, a plurality of bit lines BL, and a plurality of source lines SL. The word lines WWL are write word lines and the word lines RWL are read word lines. In the NOSRAM 1600, one memory cell 1611 stores 3-bit (8-level) data.

The controller 1640 controls the NOSRAM 1600 as a whole and writes data WDA[31:0] and reads out data RDA[31:0]. The controller 1640 processes command signals from the outside (e.g., a chip enable signal and a write enable signal) to generate control signals for the row driver 1650, the column driver 1660, and the output driver 1670.

The row driver 1650 has a function of selecting a row to be accessed. The row driver 1650 includes a row decoder 1651 and a word line driver 1652.

The column driver 1660 drives the source line SL and the bit line BL. The column driver 1660 includes a column decoder 1661, a write driver 1662, and a DAC (digital-analog converter circuit) 1663.

The DAC 1663 converts 3-bit digital data into an analog voltage. The DAC 1663 converts 32-bit data WDA[31:0] into an analog voltage per 3 bits.

The write driver 1662 has a function of precharging the source line SL, a function of bringing the source line SL into an electrically floating state, a function of selecting the source line SL, a function of inputting a writing voltage generated by the DAC 1663 to the selected source line SL, a function of precharging the bit line BL, a function of bringing the bit line BL into an electrically floating state, and the like.

The output driver 1670 includes a selector 1671, an ADC (analog-digital converter circuit) 1672, and an output buffer 1673. The selector 1671 selects the source line SL to be accessed and transmits a voltage of the selected source line SL to the ADC 1672. The ADC 1672 has a function of converting an analog voltage into 3-bit digital data. The voltage of the source line SL is converted into 3-bit data in the ADC 1672, and the output buffer 1673 retains the data output from the ADC 1672.

<Memory Cell>

FIG. 25(A) is a circuit diagram showing a configuration example of the memory cell 1611. The memory cell 1611 is a 2T gain cell, and the memory cell 1611 is electrically connected to the word lines WWL and RWL, the bit line BL, the source line SL, and a wiring BGL. The memory cell 1611 includes a node SN, an OS transistor MO61, a transistor MP61, and a capacitor C61. The OS transistor MO61 is a write transistor. The transistor MP61 is a read transistor and is formed using a p-channel Si transistor, for example. The capacitor C61 is a storage capacitor for retaining the voltage of the node SN. The node SN is a data retaining node and corresponds to a gate of the transistor MP61 here.

The write transistor of the memory cell 1611 is formed using the OS transistor MO61; thus, the NOSRAM 1600 can retain data for a long time.

In the example of FIG. 25(A), a write bit line and a read bit line are a common bit line; however, as shown in FIG. 25(B), a write bit line WBL and a read bit line RBL may be provided.

FIG. 25(C) to FIG. 25(E) show other configuration examples of the memory cell. FIG. 25(C) to FIG. 25(E) show examples where the write bit line and the read bit line are provided; however, as shown in FIG. 25(A), a bit line shared in writing and reading may be provided.

A memory cell 1612 shown in FIG. 25(C) is a modification example of the memory cell 1611 where the read transistor is changed into an n-channel transistor (MN61). The transistor MN61 may be an OS transistor or a Si transistor.

In the memory cells 1611 and 1612, the OS transistor MO61 may be an OS transistor with no back gate.

A memory cell 1613 shown in FIG. 25(D) is a 3T gain cell and is electrically connected to the word lines WWL and RWL, the bit lines WBL and RBL, the source line SL, the wiring BGL, and a wiring PCL. The memory cell 1613 includes the node SN, an OS transistor MO62, a transistor MP62, a transistor MP63, and a capacitor C62. The OS transistor MO62 is a write transistor. The transistor MP62 is a read transistor and the transistor MP63 is a selection transistor.

The memory cell 1614 shown in FIG. 25(E) is a modification example of the memory cell 1613 where the read transistor and the selection transistor are changed into n-channel transistors (MN62 and MN63). Each of the transistors MN62 and MN63 may be an OS transistor or a Si transistor.

The OS transistors provided in the memory cells 1611 to 1614 may each be a transistor with no back gate or a transistor with a back gate.

There is theoretically no limitation on the number of rewriting operations of the NOSRAM 1600 because data is rewritten by charging and discharging of the capacitor C61; and data can be written and read with low energy. Furthermore, since data can be retained for a long time, the refresh rate can be reduced.

In the case where the semiconductor device described in any of the above embodiments is used for the memory cells 1611, 1612, 1613, and 1614, the transistor 200 can be used as the OS transistors MO61 and MO62, the capacitor 100 can be used as the capacitors C61 and C62, and the transistor 300 can be used as the transistors MP61 and MN62.

This embodiment can be implemented in appropriate combination with the structures described in the other embodiments, example, and the like.

### Embodiment 5

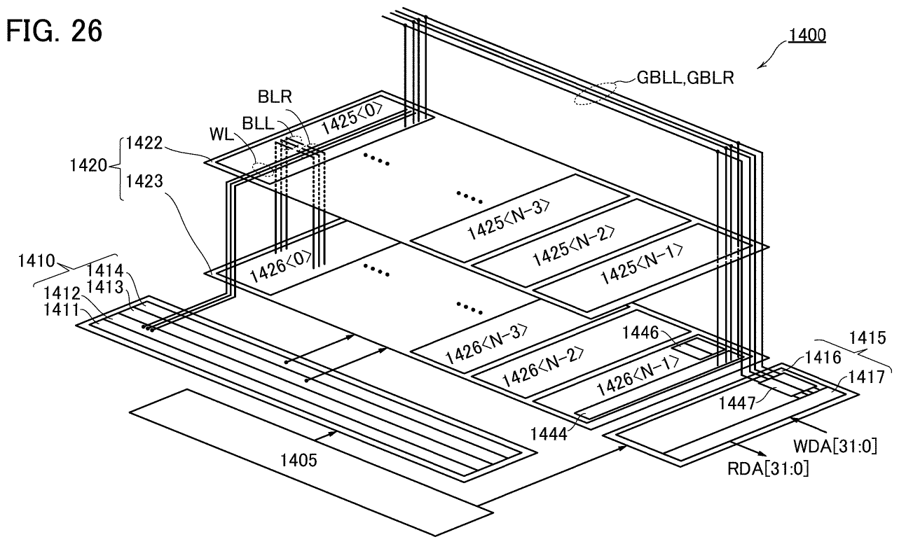

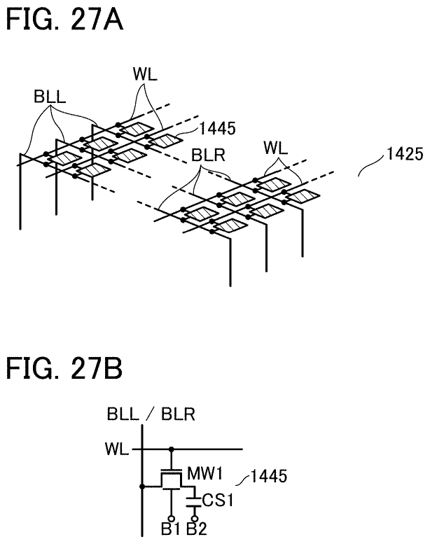

In this embodiment, a DOSRAM is described as another example of the memory device of one embodiment of the present invention, which includes an OS transistor and a capacitor, with reference to FIG. 26 and FIG. 27. A DOSRAM (registered trademark) is an abbreviation of “Dynamic Oxide Semiconductor RAM,” which is a RAM including a 1T (transistor) 1C (capacitor) memory cell. As in the NOSRAM, an OS memory is used in the DOSRAM.

<<DOSRAM 1400>>

FIG. 26 shows a configuration example of a DOSRAM. As shown in FIG. 26, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

(MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts, as the bit-line structure, a hierarchical bit line structure hierarchized with local bit lines and global bit lines.

The memory cell array 1422 includes N local memory cell arrays 1425<0> to 1425<N−1> (N is an integer greater than or equal to 2). FIG. 27(A) shows a configuration example of the local memory cell array 1425. The local memory cell array 1425 includes a plurality of memory cells 1445, a plurality of word lines WL, and a plurality of bit lines BLL and BLR. In the example of FIG. 27(A), the local memory cell array 1425 has an open bit-line architecture but may have a folded bit-line architecture.

FIG. 27(B) shows a circuit configuration example of the memory cell 1445. The memory cell 1445 includes a transistor MW1, a capacitor CS1, a terminal B1, and a terminal B2. The transistor MW1 has a function of controlling charging and discharging of the capacitor CS1. A gate of the transistor MW1 is electrically connected to the word line, a first terminal of the transistor MW1 is electrically connected to the bit line, and a second terminal of the transistor MW1 is electrically connected to a first terminal of the capacitor CS1. A second terminal of the capacitor CS1 is electrically connected to the terminal B2. A constant voltage (e.g., a low power supply voltage) is input to the terminal B2.

In the case where the semiconductor device described in any of the above embodiments is used in the memory cell 1445, the transistor 200 can be used as the transistor MW1, and the capacitor 100 can be used as the capacitor CS1.

The transistor MW1 includes a back gate, and the back gate is electrically connected to the terminal B1. This makes it possible to change the threshold voltage of the transistor MW1 with a voltage of the terminal B1. For example, the voltage of the terminal B1 may be a fixed voltage (e.g., a negative constant voltage), or the voltage of the terminal B1 may be changed in response to the operation of the DOSRAM 1400.

The back gate of the transistor MW1 may be electrically connected to the gate, the first terminal, or the second terminal of the transistor MW1. Alternatively, the back gate is not necessarily provided in the transistor MW1.

The sense amplifier array 1423 includes N local sense amplifier arrays 1426<0> to 1426<N−1>. The local sense amplifier array 1426 includes one switch array 1444 and a plurality of sense amplifiers 1446. A bit line pair is electrically connected to the sense amplifier 1446. The sense amplifier 1446 has a function of precharging the bit line pair, a function of amplifying a voltage difference between the bit line pair, and a function of retaining the voltage difference. The switch array 1444 has a function of selecting a bit line pair and bringing the selected bit line pair and a global bit line pair into a conduction state.

Here, the bit line pair refers to two bit lines which are compared by the sense amplifier at the same time. The global bit line pair refers to two global bit lines which are compared by the global sense amplifier at the same time. The bit line pair can be referred to as a pair of bit lines, and the global bit line pair can be referred to as a pair of global bit lines. Here, the bit line BLL and the bit line BLR form one bit line pair. The global bit line GBLL and the global bit line GBLR form one global bit line pair. In the following description, the expressions “bit line pair (BLL, BLR)” and “global bit line pair (GBLL, GBLR)” are also used.

(Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

(Row Circuit 1410)

The row circuit 1410 has a function of driving the MC-SA array 1420. The decoder 1411 has a function of decoding an address signal. The word line driver circuit 1412 generates a selection signal for selecting the word line WL of a target row that is to be accessed.

The column selector 1413 and the sense amplifier driver circuit 1414 are circuits for driving the sense amplifier array 1423. The column selector 1413 has a function of generating a selection signal for selecting the bit line of a target column that is to be accessed. With the selection signal from the column selector 1413, the switch array 1444 of each local sense amplifier array 1426 is controlled. With the control signal from the sense amplifier driver circuit 1414, the plurality of local sense amplifier arrays 1426 are independently driven.

(Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference between the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a target column. The local sense amplifier array 1426 amplifies the written data and retains the amplified data. In the specified local memory cell array 1425, the word line WL of a target row is selected by the row circuit 1410, and the data retained at the local sense amplifier array 1426 is written to the memory cell 1445 of the selected row.

The read operation of the DOSRAM 1400 is briefly described. One row of the local memory cell array 1425 is specified by an address signal. In the specified local memory cell array 1425, the word line WL of a target row is in a selected state, and data of the memory cell 1445 is written to the bit line. The local sense amplifier array 1426 detects a voltage difference between the bit line pair of each column as data, and retains the data. Among the data retained at the local sense amplifier array 1426, the data of a column specified by the address signal is written to the global bit line pair by the switch array 1444. The global sense amplifier array 1416 detects and retains the data of the global bit line pair. The data retained at the global sense amplifier array 1416 is output to the input/output circuit 1417. Thus, the read operation is completed.

There is theoretically no limitation on the number of rewriting operations of the DOSRAM 1400 because data is rewritten by charging and discharging of the capacitor CS1; and data can be written and read with low energy. In addition, the memory cell 1445 has a simple circuit configuration, and thus the capacity can be easily increased.

The transistor MW1 is an OS transistor. The extremely low off-state current of the OS transistor can inhibit charge leakage from the capacitor CS1. Therefore, the retention time of the DOSRAM 1400 is much longer than that of a DRAM. This allows less frequent refresh, which can reduce power needed for refresh operations. Thus, the DOSRAM 1400 is suitable for a memory device that rewrites a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which can reduce the storage capacitance of the memory cell 1445. In addition, providing the switch array 1444 in the local sense amplifier array 1426 can reduce the number of long bit lines. For the reasons described above, a driving load during access to the DOSRAM 1400 is reduced, enabling a reduction in power consumption.

This embodiment can be implemented in appropriate combination with the structures described in the other embodiments, example, and the like.

### Embodiment 6

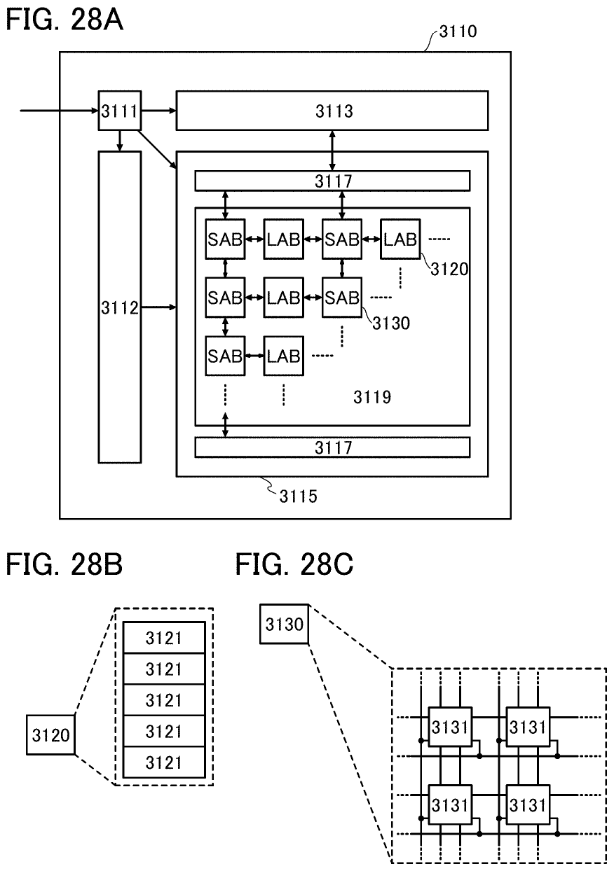

In this embodiment, an FPGA (field-programmable gate array) is described as an example of a semiconductor device of one embodiment of the present invention in which an OS transistor and a capacitor are used, with reference to FIG. 28 to FIG. 31. In the FPGA of this embodiment, an OS memory is used for a configuration memory and a register. Here, such an FPGA is referred to as an “OS-FPGA”.

<<OS-FPGA>>

FIG. 28(A) illustrates a configuration example of an OS-FPGA. An OS-FPGA 3110 illustrated in FIG. 28(A) is capable of NOFF (normally-off) computing that executes context switching by a multi-context configuration and fine-grained power gating in each PLE. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of PLEs 3121. FIG. 28(B) illustrates an example in which the LAB 3120 includes five PLEs 3121. As illustrated in FIG. 28(C), the SAB 3130 includes a plurality of switch blocks (SBs) 3131 arranged in an array. The LAB 3120 is connected to the LABs 3120 in four directions (on the left, right, top, and bottom sides) through its input terminals and the SABs 3130.

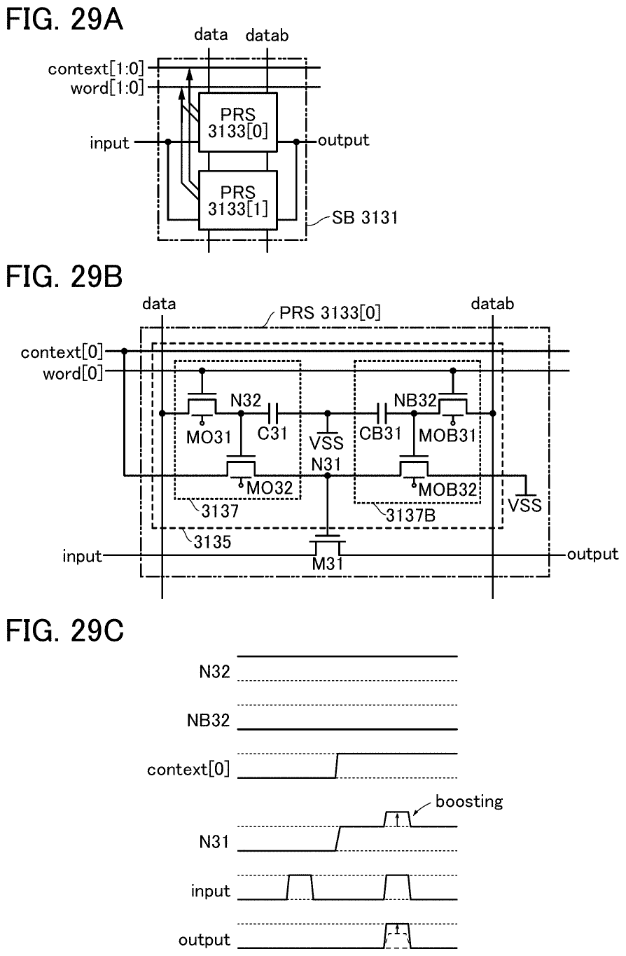

The SB 3131 is described with reference to FIG. 29(A) to FIG. 29(C). To the SB 3131 illustrated in FIG. 29(A), data, datab, signals context[1:0], and signals word[1:0] are input. The data and the datab are configuration data, and the logics of the data and the datab have a complementary relationship. The number of contexts in the OS-FPGA 3110 is two, and the signals context[1:0] are context selection signals. The signals word[1:0] are word line selection signals, and wirings to which the signals word[1:0] are input are each a word line.

The SB 3131 includes a PRS (programmable routing switch) 3133[0] and a PRS 3133[1]. The PRSs 3133[0] and 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 29(B) illustrates a circuit configuration example of the PRS 3133[0]. The PRS 3133[0] and the PRS 3133[1] have the same circuit configuration. The PRS 3133[0] and the PRS 3133[1] are different from each other in a context selection signal and a word line selection signal that are input. The signals context[0] and word[0] are input to the PRS 3133[0], and the signals context[1] and word[1] are input to the PRS 3133[1]. For example, in the SB 3131, when the signal context[0] is set to “H”, the PRS 3133[0] is activated.

The PRS 3133[0] includes a CM 3135 and a Si transistor M31. The Si transistor M31 is a pass transistor that is controlled by the CM 3135. The CM 3135 includes a memory circuit 3137 and a memory circuit 3137B. The memory circuits 3137 and 3137B have the same circuit configuration. The memory circuit 3137 includes a capacitor C31, an OS transistor MO31, and an OS transistor MO32. The memory circuit 3137B includes a capacitor CB31, an OS transistor MOB31, and an OS transistor MOB32.

In the case where the semiconductor device described in any of the above embodiments is used in the SAB 3130, the transistor 200 can be used as the OS transistors MO31 and MOB31, and the capacitor 100 can be used as the capacitors C31 and CB31.

The OS transistors MO31, MO32, MOB31, and MOB32 each include a back gate, and each of these back gates are electrically connected to a power supply line that supplies a fixed voltage.

A gate of the Si transistor M31, a gate of the OS transistor MO32, and a gate of the OS transistor MOB32 correspond to a node N31, a node N32, and a node NB32, respectively. The nodes N32 and NB32 are each a charge retention node of the CM 3135. The OS transistor MO32 controls the conduction state between the node N31 and a signal line for the signal context[0]. The OS transistor MOB32 controls the conduction state between the node N31 and a low-potential power supply line VSS.

Logics of data retained at the memory circuits 3137 and 3137B have a complementary relationship. Thus, either the OS transistor MO32 or the OS transistor MOB32 is turned on.

The operation example of the PRS 3133[0] is described with reference to FIG. 29(C). In the PRS 3133[0], to which configuration data has already been written, the node N32 is at “H”, whereas the node NB32 is at “L”.

The PRS 3133[0] is inactive while the signal context[0] is at “L”. During this period, even when an input terminal (input) of the PRS 3133[0] is transferred to “H”, the gate of the Si transistor M31 is kept at “L” and an output terminal (output) of the PRS 3133[0] is also kept at “L”.

The PRS 3133[0] is active while the signal context[0] is at “H”. When the signal context[0] is transferred to “H”, the gate of the Si transistor M31 is transferred to “H” by the configuration data stored in the CM 3135.

While the PRS 3133[0] is active, when the input terminal is transferred to “H”, the gate voltage of the Si transistor M31 is increased by boosting because the OS transistor MO32 of the memory circuit 3137 is a source follower. As a result, the OS transistor MO32 of the memory circuit 3137 loses the driving capability, and the gate of the Si transistor M31 is brought into a floating state.

In the PRS 3133 with a multi-context function, the CM 3135 also has a function of a multiplexer.

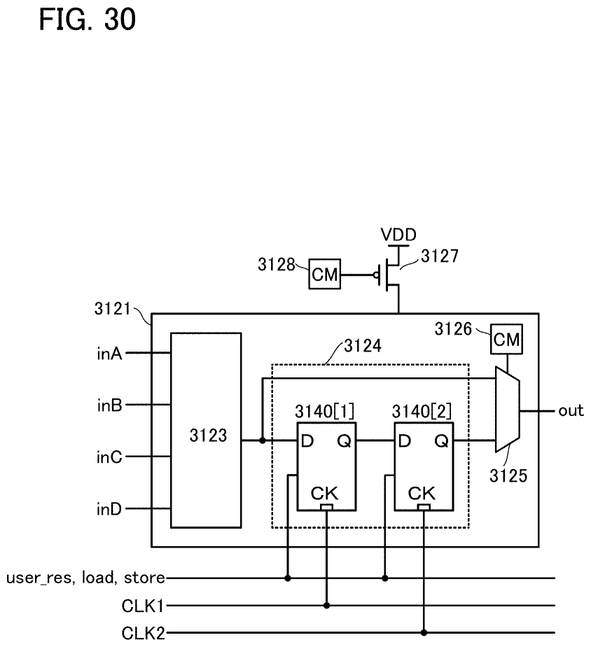

FIG. 30 illustrates a configuration example of the PLE 3121. The PLE 3121 includes an LUT (lookup table) block 3123, a register block 3124, a selector 3125, and a CM 3126. The LUT block 3123 is configured to select and output data in the LUT block in accordance with inputs inA, inB, inC, and inD. The selector 3125 selects an output of the LUT block 3123 or an output of the register block 3124 (out) in accordance with the configuration data stored in the CM 3126.

The PLE 3121 is electrically connected to a power supply line for a voltage VDD through a power switch 3127. Whether the power switch 3127 is turned on or off is determined in accordance with the configuration data stored in a CM 3128. Providing the power switch 3127 for each PLE 3121 enables fine-grained power gating. The PLE 3121 that is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as an [OS-FF]).

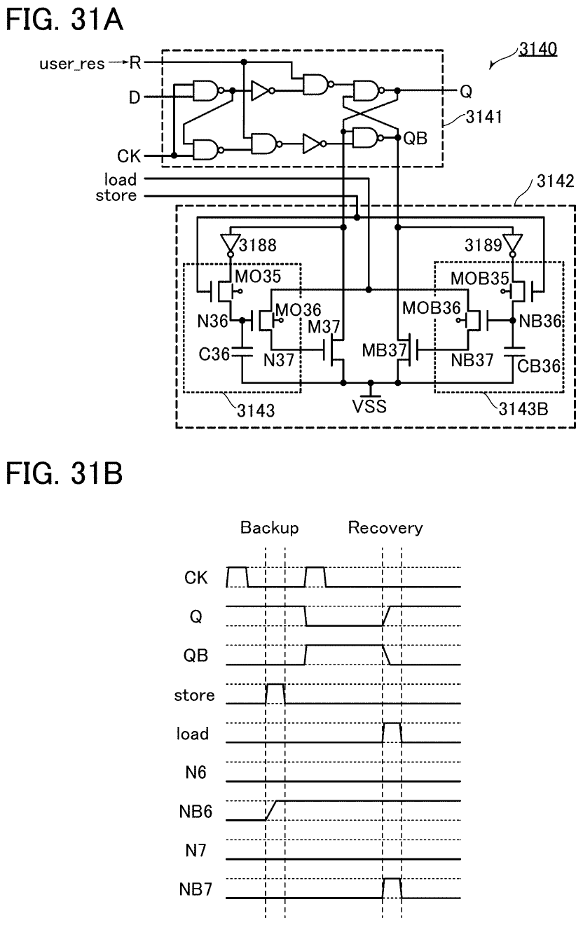

The register block 3124 includes an OS-FF 3140[1] and an OS-FF 3140[2]. A signal user_res, a signal load, and a signal store are input to the OS-FFs 3140[1] and 3140[2]. A clock signal CLK1 is input to the OS-FF 3140[1] and a clock signal CLK2 is input to the OS-FF 3140[2]. FIG. 31(A) illustrates a configuration example of the OS-FF 3140.

The OS-FF 3140 includes an FF 3141 and a shadow register 3142. The FF 3141 includes a node CK, a node R, a node D, a node Q, and a node QB. A clock signal is input to the node CK. The signal user_res is input to the node R. The signal user_res is a reset signal. The node D is a data input node, and the node Q is a data output node. The logics of the node Q and the node QB have a complementary relationship.

The shadow register 3142 functions as a backup circuit of the FF 3141. The shadow register 3142 backs up data of the nodes Q and QB in accordance with the signal store and writes back the backed up data to the nodes Q and QB in accordance with the signal load.

The shadow register 3142 includes an inverter circuit 3188, an inverter circuit 3189, a Si transistor M37, a Si transistor MB37, a memory circuit 3143, and a memory circuit 3143B. The memory circuits 3143 and 3143B have the same circuit configuration as the memory circuit 3137 of the PRS 3133. The memory circuit 3143 includes a capacitor C36, an OS transistor MO35, and an OS transistor MO36. The memory circuit 3143B includes a capacitor CB36, an OS transistor MOB35, and an OS transistor MOB36. A node N36 and a node NB36 correspond to a gate of the OS transistor MO36 and a gate of the OS transistor MOB36, respectively, and are each a charge retention node. A node N37 and a node NB37 correspond to gates of the Si transistors M37 and MB37, respectively.

In the case where the semiconductor device described in any of the above embodiments is used in the LAB 3120, the transistor 200 can be used as the OS transistors MO35 and MOB35, and the capacitor 100 can be used as the capacitors C36 and CB36.

The OS transistors MO35, MO36, MOB35, and MOB36 each include a back gate, and each of these back gates are electrically connected to a power supply line that supplies a fixed voltage.

An example of an operation method of the OS-FF 3140 is described with reference to FIG. 31(B).

(Backup)

When the signal store at “H” is input to the OS-FF 3140, the shadow register 3142 backs up the data of the FF 3141. The node N36 becomes “L” when the data of the node Q is written thereto, and the node NB36 becomes “H” when the data of the node QB is written thereto. After that, power gating is performed and the power switch 3127 is turned off. Although the data of the nodes Q and QB of the FF 3141 are lost, the shadow register 3142 retains the backed up data even when power is off

(Recovery)

The power switch 3127 is turned on to supply power to the PLE 3121. After that, when the signal load at “H” is input to the OS-FF 3140, the shadow register 3142 writes back the backed up data to the FF 3141. The node N37 is kept at “L” because the node N36 is at “L”, and the node NB37 becomes “H” because the node NB36 is at “H”. Thus, the node Q becomes “H” and the node QB becomes “L”. That is, the OS-FF 3140 is recovered to a state at the backup operation.

A combination of the fine-grained power gating and backup/recovery operation of the OS-FF 3140 allows power consumption of the OS-FPGA 3110 to be effectively reduced.

As an error that might occur in a memory circuit, a soft error due to the entry of radiation is given. The soft error is a phenomenon in which a malfunction such as inversion of data stored in a memory is caused by electron-hole pair generation when a transistor is irradiated with a rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory using an OS transistor has a high soft-error tolerance. Therefore, the OS-FPGA 3110 with high reliability can be provided when an OS memory is included therein.

This embodiment can be implemented in appropriate combination with the structures described in the other embodiments, example, and the like.

### Embodiment 7

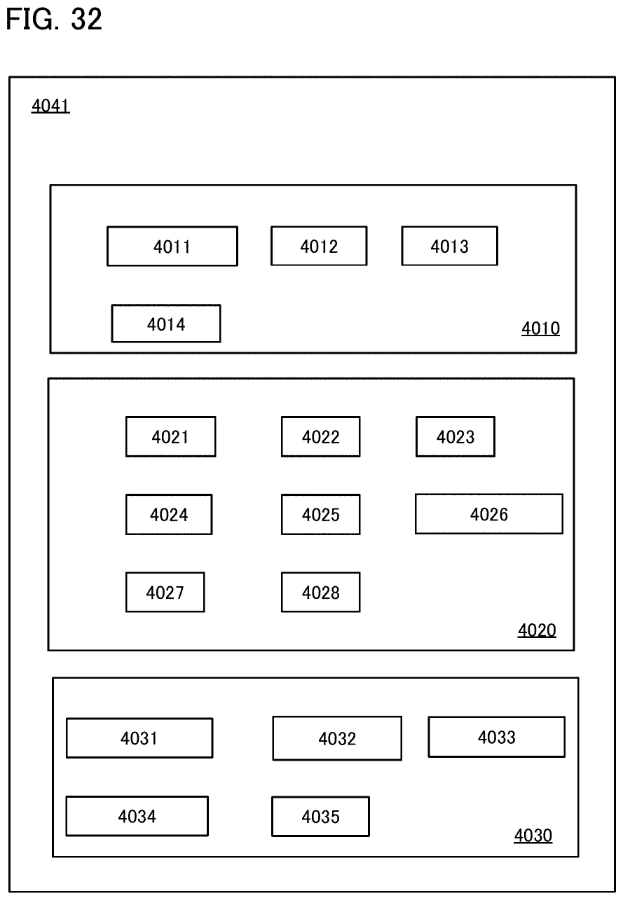

In this embodiment, an AI system in which the semiconductor device of any of the above embodiments is used is described with reference to FIG. 32.

FIG. 32 is a block diagram illustrating a structure example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400, the NOSRAM 1600, and the OS-FPGA 3110 described in the above embodiments can be used as the DOSRAM 4012, the NOSRAM 4013, and the FPGA 4014, respectively.

The control portion 4020 includes a CPU (Central Processing Unit) 4021, a GPU (Graphics Processing Unit) 4022, a PLL (Phase Locked Loop) 4023, an SRAM (Static Random Access Memory) 4024, a PROM (Programmable Read Only Memory) 4025, a memory controller 4026, a power supply circuit 4027, and a PMU (Power Management Unit) 4028.

The input/output portion 4030 includes an external memory control circuit 4031, an audio codec 4032, a video codec 4033, a general-purpose input/output module 4034, and a communication module 4035.

The arithmetic portion 4010 can execute learning or inference by a neural network.

The analog arithmetic circuit 4011 includes an A/D (analog/digital) converter circuit, a D/A (digital/analog) converter circuit, and a product-sum operation circuit.

The analog arithmetic circuit 4011 is preferably formed using an OS transistor. The analog arithmetic circuit 4011 using an OS transistor includes an analog memory and can execute a product-sum operation necessary for the learning or inference with low power consumption.

The DOSRAM 4012 is a DRAM formed using an OS transistor, and is a memory that temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in an SRAM, the input data have to be stored piece by piece because of the circuit area limitation and small storage capacity of the SRAM. The DOSRAM 4012 has a larger storage capacity than an SRAM because the memory cells can be highly integrated even in a limited circuit area. Therefore, the DOSRAM 4012 can efficiently store the input data.

The NOSRAM 4013 is a nonvolatile memory using an OS transistor. The NOSRAM 4013 consumes less power in writing data than the other nonvolatile memories such as a flash memory, a ReRAM (Resistive Random Access Memory), and an MRAM (Magnetoresistive Random Access Memory). Furthermore, unlike a flash memory and a ReRAM in which elements deteriorate by data writing, the NOSRAM has no limitation on the number of times of data writing.

Furthermore, the NOSRAM 4013 can store multilevel data of two or more bits as well as one-bit binary data. The multilevel data storage in the NOSRAM 4013 leads to a reduction in the memory cell area per bit.

Furthermore, the NOSRAM 4013 can store analog data as well as digital data. Thus, the analog arithmetic circuit 4011 can use the NOSRAM 4013 as an analog memory. The NOSRAM 4013 can store analog data as it is, and thus a D/A converter circuit and an A/D converter circuit are unnecessary. Therefore, the area of a peripheral circuit for the NOSRAM 4013 can be reduced. In this specification, analog data refers to data having a resolution of three bits (eight levels) or more. The above-described multilevel data is included in the analog data in some cases.

Data and parameters used in the neural network calculation can be once stored in the NOSRAM 4013. The data and parameters may be stored in a memory provided outside the AI system 4041 via the CPU 4021; however, the NOSRAM 4013 provided inside the AI system 4041 can store the data and parameters more quickly with lower power consumption. Furthermore, the NOSRAM 4013 enables a longer bit line than the DOSRAM 4012 and thus can have an increased storage capacity.

The FPGA 4014 is an FPGA using an OS transistor. With the use of the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), or a deep belief network (DBN) described later, with a hardware. Establishing the connection of the neural network with a hardware enables higher speed performance.

The FPGA 4014 is an OS-FPGA. An OS-FPGA can have a smaller memory area than an FPGA including an SRAM. Thus, adding a context switching function only causes a small increase in area. Moreover, an OS-FPGA can transmit data and parameters at high speed by boosting.

In the AI system 4041, the analog arithmetic circuit 4011, the DOSRAM 4012, the NOSRAM 4013, and the FPGA 4014 can be provided on one die (chip). Thus, the AI system 4041 can execute calculation of the neural network quickly with low power consumption. In addition, the analog arithmetic circuit 4011, the DOSRAM 4012, the NOSRAM 4013, and the FPGA 4014 can be fabricated through the same manufacturing process. Therefore, the AI system 4041 can be fabricated at low cost.

Note that the arithmetic portion 4010 does not necessarily include all of the following: the DOSRAM 4012, the NOSRAM 4013, and the FPGA 4014. One or more memories selected from the DOSRAM 4012, the NOSRAM 4013, and the FPGA 4014 are provided in accordance with a problem that is desired to be solved by the AI system 4041.

The AI system 4041 can execute a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for executing at least one of these methods. Furthermore, part or the whole of the program may be stored in the NOSRAM 4013.

Most of the existing programs used as libraries are premised on processing with a GPU. Therefore, the AI system 4041 preferably includes the GPU 4022. The AI system 4041 can execute the bottleneck product-sum operation among all the product-sum operations used for learning and inference in the arithmetic portion 4010, and execute the other product-sum operations in the GPU 4022. In this manner, the learning and inference can be executed at high speed.

The power supply circuit 4027 generates not only a low power supply potential for a logic circuit but also a potential for an analog operation. The power supply circuit 4027 may use an OS memory. When a reference potential is stored in the OS memory, the power consumption of the power supply circuit 4027 can be reduced.

The PMU 4028 has a function of temporarily stopping the power supply to the AI system 4041.

The CPU 4021 and the GPU 4022 preferably include OS memories as registers. By including the OS memories, the CPU 4021 and the GPU 4022 can retain data (logic values) in the OS memories even when power supply is stopped. As a result, the AI system 4041 can save the power.

The PLL 4023 has a function of generating a clock. The AI system 4041 performs an operation on the basis of the clock generated by the PLL 4023. The PLL 4023 preferably includes an OS memory. By including the OS memory, the PLL 4023 can retain an analog potential with which the clock oscillation frequency is controlled.

The AI system 4041 may store data in an external memory such as a DRAM. For this reason, the AI system 4041 preferably includes the memory controller 4026 functioning as an interface with the external DRAM. Furthermore, the memory controller 4026 is preferably positioned near the CPU 4021 or the GPU 4022. Thus, data transmission can be performed at high speed.

Some or all of the circuits illustrated in the control portion 4020 can be formed on the same die as the arithmetic portion 4010. Thus, the AI system 4041 can execute the neural network calculation at high speed with low power consumption.

Data used for the neural network calculation is stored in an external storage device [such as an HDD (Hard Disk Drive) or an SDD (Solid State Drive)] in many cases. Therefore, the AI system 4041 preferably includes the external memory control circuit 4031 functioning as an interface with the external storage device.

Because the neural network often deals with audio and video for learning and inference, the AI system 4041 includes the audio codec 4032 and the video codec 4033. The audio codec 4032 encodes and decodes audio data, and the video codec 4033 encodes and decodes video data.

The AI system 4041 can perform learning or inference using data obtained from an external sensor. For this reason, the AI system 4041 includes the general-purpose input/output module 4034. The general-purpose input/output module 4034 includes a USB (Universal Serial Bus), an I2C (Inter-Integrated Circuit), or the like, for example.

The AI system 4041 can perform learning or inference using data obtained via the Internet. For this reason, the AI system 4041 preferably includes the communication module 4035.

The analog arithmetic circuit 4011 may use a multi-level flash memory as an analog memory. However, the flash memory has a limitation on the number of rewriting times. In addition, the multi-level flash memory is extremely difficult to embed (to form the arithmetic circuit and the memory on the same die).

Alternatively, the analog arithmetic circuit 4011 may use a ReRAM as an analog memory. However, the ReRAM has a limitation on the number of rewriting times and also has a problem in storage accuracy. Moreover, the ReRAM is a two-terminal element, and thus has a complicated circuit design for separating data writing and data reading.

Further alternatively, the analog arithmetic circuit 4011 may use an MRAM as an analog memory. However, the MRAM has a problem in storage accuracy because of its low magnetoresistive ratio.

In consideration of the above, the analog arithmetic circuit 4011 preferably uses an OS memory as an analog memory.

This embodiment can be implemented in appropriate combination with the structures described in the other embodiments, example, and the like.

### Embodiment 8

<Application Example of AI System>

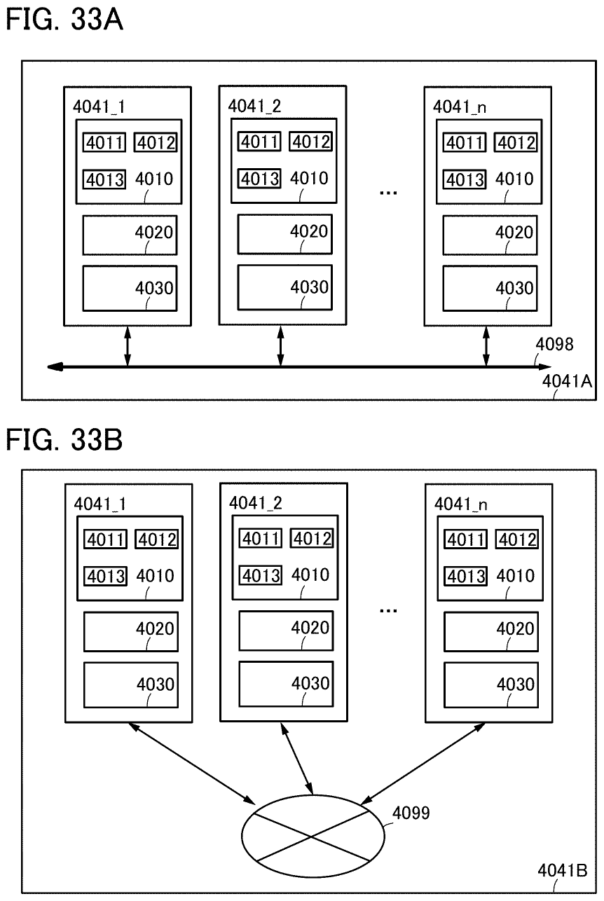

In this embodiment, application examples of the AI system described in the above embodiment are described with reference to FIG. 33.

FIG. 33(A) is an AI system 4041A in which the AI systems 4041 described with FIG. 32 are arranged in parallel and a signal can be transmitted between the systems via a bus line.

The AI system 4041A illustrated in FIG. 33(A) includes a plurality of AI systems 4041_1 to 4041_n (n is a natural number). The AI system 4041_1 to the AI system 4041_n are connected to each other via a bus line 4098.

FIG. 33(B) is an AI system 4041B in which the AI systems 4041 described with FIG. 30 are arranged in parallel as in FIG. 33(A) and a signal can be transmitted between the systems via a network.

The AI system 4041B illustrated in FIG. 33(B) includes the plurality of AI systems 4041_1 to 4041_n. The AI system 4041_1 to the AI system 4041_n are connected to each other via a network 4099.

A structure may be employed in which a communication module is provided in each of the AI system 4041_1 to the AI system 4041_n to perform wireless or wired communication via the network 4099. A communication module can perform communication via an antenna. For example, the communication can be performed in such a manner that an electronic device is connected to a computer network such as the Internet that is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case of performing wireless communication, it is possible to use, as a communication protocol or a communication technology, a communications standard such as LTE (Long Term Evolution), GSM (Global System for Mobile Communication: registered trademark), EDGE (Enhanced Data Rates for GSM Evolution), CDMA 2000 (Code Division Multiple Access 2000), or W-CDMA (registered trademark), or a communications standard developed by IEEE such as Wi-Fi (registered trademark), Bluetooth (registered trademark), or ZigBee (registered trademark).

With the structure illustrated in FIG. 33(A) or 33(B), analog signals obtained with external sensors or the like can be processed by different AI systems. For example, biological information such as brain waves, a pulse, blood pressure, and body temperature is obtained with a variety of sensors such as a brain wave sensor, a pulse wave sensor, a blood pressure sensor, and a temperature sensor, and analog signals can be processed by different AI systems. When the signal processing or learning is performed by different AI systems, the amount of information processed by each AI system can be reduced. Accordingly, the signal processing or learning can be performed with a smaller amount of arithmetic processing. As a result, recognition accuracy can be increased. The information obtained with each AI system is expected to enable instant understanding of collective biological information that irregularly changes.

This embodiment can be implemented in appropriate combination with the structures described in the other embodiments, example, and the like.

### Embodiment 9

In this embodiment, an example of an IC incorporating the AI system described in the above embodiment is described.

In the AI system described in the above embodiment, a digital processing circuit such as a CPU that includes a Si transistor, an analog arithmetic circuit that uses an OS transistor, an OS-FPGA, and an OS memory such as a DOSRAM or a NOSRAM can be integrated into one die.

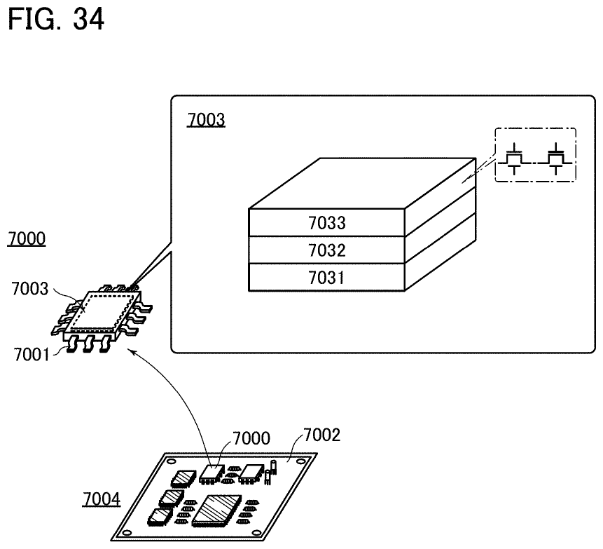

FIG. 34 illustrates the example of the IC incorporating the AI system. An AI system IC 7000 illustrated in FIG. 34 includes a lead 7001 and a circuit portion 7003. The AI system IC 7000 is mounted on a printed circuit board 7002, for example. A plurality of such IC chips are combined and electrically connected to each other on the printed circuit board 7002; thus, a board on which electronic components are mounted (a circuit board 7004) is completed. In the circuit portion 7003, the various circuits described in the above embodiment are provided on one die. The circuit portion 7003 has a stacked-layer structure, for example, as illustrated in FIG. 18 in the above embodiment, which is broadly divided into a Si transistor layer 7031, a wiring layer 7032, and an OS transistor layer 7033. Since the OS transistor layer 7033 can be provided to be stacked over the Si transistor layer 7031, the size of the AI system IC 7000 can be easily reduced.

Although a QFP (Quad Flat Package) is used as a package of the AI system IC 7000 in FIG. 34, the embodiment of the package is not limited thereto.

The digital processing circuit such as a CPU, the analog arithmetic circuit that uses an OS transistor, the OS-FPGA, and the OS memory such as a DOSRAM or a NOSRAM can all be formed in the Si transistor layer 7031, the wiring layer 7032, and the OS transistor layer 7033. In other words, elements included in the AI system can be formed through the same manufacturing process. Thus, the number of steps in the manufacturing process of the IC described in this embodiment does not need to be increased even when the number of elements is increased, and accordingly the AI system can be incorporated into the IC at low cost.

This embodiment can be implemented in appropriate combination with the structures described in the other embodiments, example, and the like.

### Embodiment 10

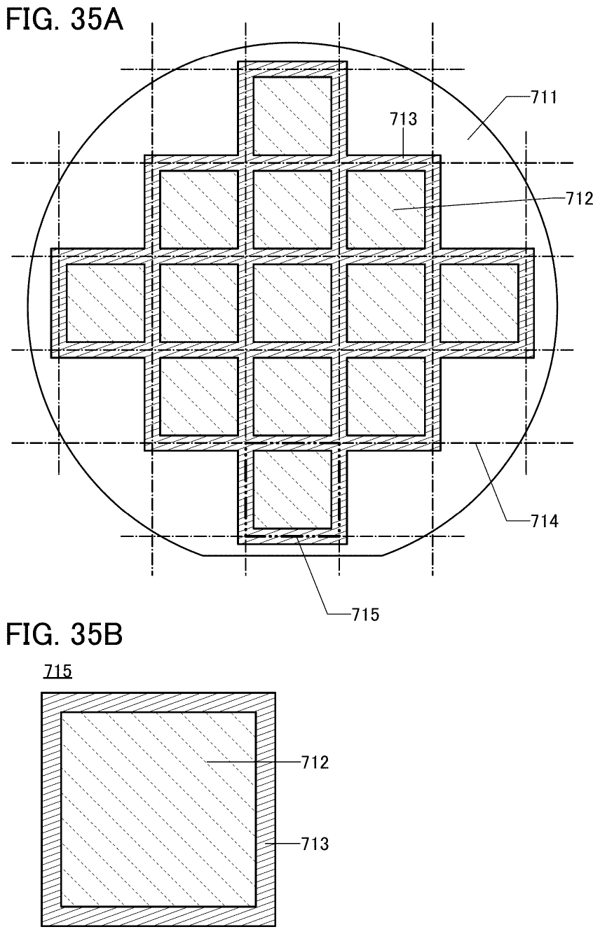

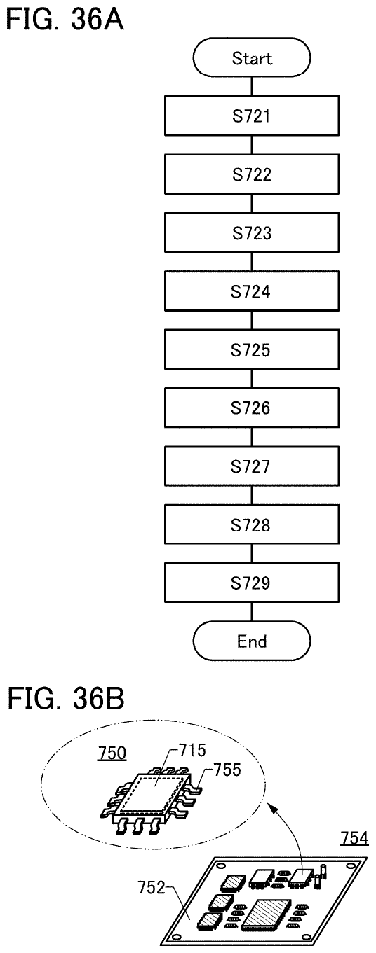

In this embodiment, one embodiment of a semiconductor device is described with reference to FIG. 35 and FIG. 36.

<Semiconductor Wafer and Chip>

FIG. 35(A) is a top view of a substrate 711 before dicing treatment is performed. As the substrate 711, a semiconductor substrate (also referred to as a “semiconductor wafer”) can be used, for example. A plurality of circuit regions 712 are provided over the substrate 711. A semiconductor device and the like of one embodiment of the present invention can be provided in the circuit region 712.

The plurality of circuit regions 712 are each surrounded by a separation region 713. Separation lines (also referred to as “dicing lines”) 714 are set at a position overlapping with the separation regions 713. The substrate 711 is cut along the separation lines 714, whereby chips 715 including the circuit regions 712 can be cut out. FIG. 35(B) illustrates an enlarged view of the chip 715.

In addition, a conductive layer, a semiconductor layer, or the like may be provided in the separation regions 713. Providing a conductive layer, a semiconductor layer, or the like in the separation regions 713 relieves ESD that might be caused in a dicing step, preventing a decrease in the yield due to the dicing step. Moreover, a dicing step is generally performed while pure water whose specific resistance is decreased by dissolution of a carbonic acid gas or the like is supplied to a cut portion, in order to cool down a substrate, remove swarf, and prevent electrification, for example. Providing a conductive layer, a semiconductor layer, or the like in the separation regions 713 allows a reduction in the usage of the pure water. Therefore, the manufacturing cost of semiconductor devices can be reduced. Thus, the productivity of semiconductor devices can be improved.

<Electronic Component>

An example of an electronic component using the chip 715 is described with reference to FIG. 36(A) and FIG. 36(B). Note that the electronic component is also referred to as a semiconductor package or an IC package. The electronic component has a plurality of standards, names, and the like depending on a terminal extraction direction, a terminal shape, and the like.

The electronic component is completed when the semiconductor device described in the above embodiment is combined with components other than the semiconductor device in an assembly process (post-process).

The post-process is described with reference to a flow chart of FIG. 36(A). After the semiconductor device and the like of one embodiment of the present invention are formed over the substrate 711 in a pre-process, a “back surface grinding step” for grinding a back surface (a surface where the semiconductor device and the like are not formed) of the substrate 711 is performed (Step S721). When the substrate 711 is thinned by the grinding, the size of the electronic component can be reduced.

Next, a “dicing step” for dividing the substrate 711 into a plurality of chips 715 is performed (Step S722). Then, a “die bonding step” for individually bonding the divided chips 715 to a lead frame is performed (Step S723). To bond the chip 715 and a lead frame in the die bonding step, a method such as resin bonding or tape-automated bonding is selected as appropriate depending on products. Note that the chip 715 may be bonded to an interposer substrate instead of the lead frame.

Next, a “wire bonding step” for electrically connecting a lead of the lead frame and an electrode on the chip 715 through a metal wire is performed (Step S724). As the metal wire, a silver wire, a gold wire, or the like can be used. In addition, ball bonding or wedge bonding can be used as the wire bonding, for example.

The wire-bonded chip 715 is subjected to a “sealing step (molding step)” for sealing the chip with an epoxy resin or the like (Step S725). Through the sealing step, the inside of the electronic component is filled with a resin, so that a wire for connecting the chip 715 to the lead can be protected from external mechanical force, and deterioration of characteristics (decrease in reliability) due to moisture, dust, or the like can be reduced.

Subsequently, a “lead plating step” for plating the lead of the lead frame is performed (Step S726). This plate processing prevents corrosion of the lead and enables more reliable soldering at the time of mounting the electronic component on a printed circuit board in a later step. Then, a “formation step” for cutting and processing the lead is performed (Step S727).

Next, a “marking step” for printing (marking) a surface of the package is performed (Step S728). Then, after a “testing step” (Step S729) for checking the quality of an external shape, the presence of malfunction, and the like, the electronic component is completed.

FIG. 36(B) illustrates a perspective schematic view of the completed electronic component. FIG. 36(B) illustrates a perspective schematic view of a QFP (Quad Flat Package) as an example of the electronic component. An electronic component 750 illustrated in FIG. 36(B) includes a lead 755 and the chip 715. The electronic component 750 may include a plurality of chips 715.

The electronic component 750 in FIG. 36(B) is mounted on a printed circuit board 752, for example. A plurality of such electronic components 750 are combined and electrically connected to each other on the printed circuit board 752; thus, a board on which the electronic components are mounted (a circuit board 754) is completed. The completed circuit board 754 is used for an electronic device or the like.

This embodiment can be implemented in appropriate combination with the structures described in the other embodiments, example, and the like.

### Embodiment 11

<Electronic Device>

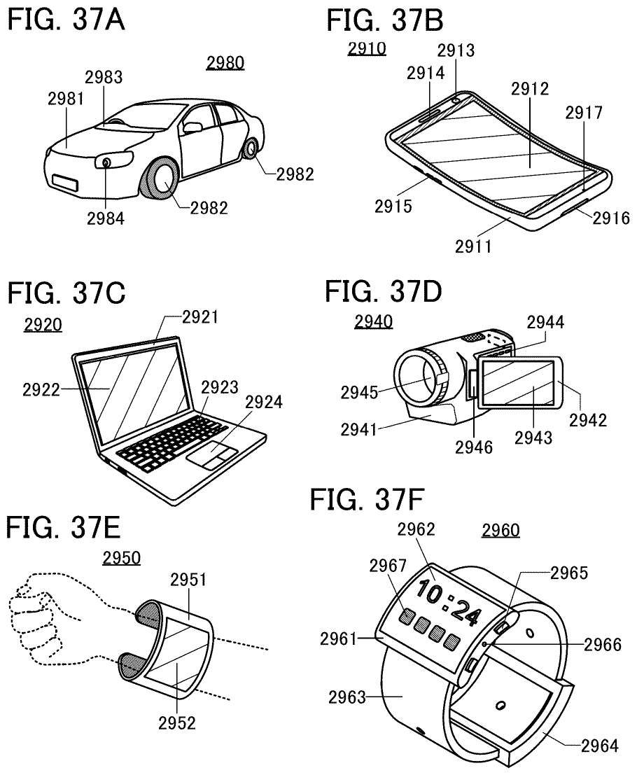

A semiconductor device of one embodiment of the present invention can be used for a variety of electronic devices. FIG. 37 illustrates specific examples of the electronic devices using the semiconductor device of one embodiment of the present invention.

FIG. 37(A) is an external view illustrating an example of a car. A car 2980 includes a car body 2981, wheels 2982, a dashboard 2983, lights 2984, and the like. The car 2980 also includes an antenna, a battery, and the like.

An information terminal 2910 illustrated in FIG. 37(B) includes a housing 2911, a display portion 2912, a microphone 2917, a speaker portion 2914, a camera 2913, an external connection portion 2916, operation switches 2915, and the like. A display panel and a touch screen that use a flexible substrate are provided in the display portion 2912. The information terminal 2910 also includes an antenna, a battery, and the like inside the housing 2911. The information terminal 2910 can be used as, for example, a smartphone, a mobile phone, a tablet information terminal, a tablet personal computer, or an e-book reader.

A notebook personal computer 2920 illustrated in FIG. 37(C) includes a housing 2921, a display portion 2922, a keyboard 2923, a pointing device 2924, and the like. In addition, the notebook personal computer 2920 includes an antenna, a battery, and the like inside the housing 2921.

A video camera 2940 illustrated in FIG. 37(D) includes a housing 2941, a housing 2942, a display portion 2943, operation switches 2944, a lens 2945, a joint 2946, and the like. The operation switches 2944 and the lens 2945 are provided in the housing 2941, and the display portion 2943 is provided in the housing 2942. The video camera 2940 also includes an antenna, a battery, and the like inside the housing 2941. The housing 2941 and the housing 2942 are connected to each other with the joint 2946, and the angle between the housing 2941 and the housing 2942 can be changed with the joint 2946. The orientation of an image displayed on the display portion 2943 may be changed and display and non-display of an image can be switched depending on the angle between the housing 2941 and the housing 2942.

FIG. 37(E) illustrates an example of a bangle-type information terminal. An information terminal 2950 includes a housing 2951, a display portion 2952, and the like. The information terminal 2950 also includes an antenna, a battery, and the like inside the housing 2951. The display portion 2952 is supported by the housing 2951 having a curved surface. A display panel using a flexible substrate is provided in the display portion 2952, whereby the user-friendly information terminal 2950 that is flexible and lightweight can be provided.

FIG. 37(F) illustrates an example of a watch-type information terminal. An information terminal 2960 includes a housing 2961, a display portion 2962, a band 2963, a buckle 2964, operation switches 2965, an input/output terminal 2966, and the like. The information terminal 2960 also includes an antenna, a battery, and the like inside the housing 2961. The information terminal 2960 is capable of executing a variety of applications such as mobile phone calls, e-mailing, viewing and editing texts, music reproduction, Internet communication, and a computer game.

The display surface of the display portion 2962 is curved, and display can be performed along the curved display surface. In addition, the display portion 2962 includes a touch sensor, and operation can be performed by touching the screen with a finger, a stylus, or the like. For example, by touching an icon 2967 displayed on the display portion 2962, an application can be started. The operation switches 2965 can have a variety of functions such as time setting, power on/off operation, turning on/off operation of wireless communication, setting and cancellation of a silent mode, and setting and cancellation of a power saving mode. For example, the functions of the operation switches 2965 can be set by the operation system incorporated in the information terminal 2960.

Furthermore, the information terminal 2960 can execute near field communication conformable to a communication standard. For example, mutual communication with a headset capable of wireless communication enables hands-free calling. Moreover, the information terminal 2960 includes the input/output terminal 2966, and thus can perform direct data transmission with another information terminal through a connector. In addition, charging can be performed via the input/output terminal 2966. Note that the charging operation may be performed by wireless power feeding without through the input/output terminal 2966.

For example, a memory device using the semiconductor device of one embodiment of the present invention can retain control data, a control program, or the like of the above electronic device for a long time. With the use of the semiconductor device of one embodiment of the present invention, a highly reliable electronic device can be achieved.

This embodiment can be implemented in an appropriate combination with any of the structures described in the other embodiments, example, and the like.

### Example

In this example, the transistor 1000 included in the semiconductor device of one embodiment of the present invention illustrated in FIG. 1 was fabricated (Sample A). For comparison, a transistor that does not include the oxide 406d (S4) was also fabricated (Sample B). Measurement of the electrical characteristics and a reliability test were performed on each transistor.

To fabricate the transistor 1000, a 400-nm-thick silicon oxide film was deposited over a p-type single crystal silicon wafer by a thermal oxidation method. Next, a 40-nm-thick first aluminum oxide film was deposited over the silicon oxide film by a sputtering method. Then, a 150-nm-thick first silicon oxynitride film was deposited over the first aluminum oxide film by a CVD method.

Next, a 35-nm-thick first tungsten film was deposited over the first silicon oxynitride film by a sputtering method. Then, the first tungsten film was processed by a lithography method, so that a hard mask including the first tungsten film was formed.

Subsequently, the first silicon oxynitride film was processed, so that a groove reaching the first aluminum oxide film was formed. Then, in the groove, a first tantalum nitride film was deposited by a sputtering method and a first titanium nitride film and a second tungsten film were deposited over the first tantalum nitride film by an ALD method and a CVD method. Then, the second tungsten film, the first titanium nitride film, the first tantalum nitride film, and the first tungsten film were polished by first CMP treatment so as to reach the top surface of the first silicon oxynitride film, and the second tungsten film, the first titanium nitride film, and the first tantalum nitride film were embedded in the groove; accordingly, a wiring layer and a second gate electrode were formed.

Next, a 10-nm-thick second silicon oxynitride film was deposited by a CVD method. Then, a 20-nm-thick hafnium oxide film was deposited by an ALD method. Then, a 30-nm-thick third silicon oxynitride film was deposited by a CVD method. The second silicon oxynitride film, the hafnium oxide film, and the third silicon oxynitride film have a function of a second gate insulating film. Then, first heat treatment was performed. As the first heat treatment, treatment was performed at 400° C. in an atmosphere containing nitrogen for one hour, and subsequently another treatment was performed at 400° C. in an atmosphere containing oxygen for one hour.

Next, as a first oxide (S1), a 5-nm-thick In-Ga—Zn oxide was deposited by a sputtering method. The S1 was deposited under the following conditions: a target with In:Ga:Zn=1:3:4 [atomic ratio] was used, the oxygen gas flow rate was 45 sccm, the pressure was 0.7 Pa, and the substrate temperature was 200° C.

Then, as a second oxide (S2), a 15-nm-thick In-Ga—Zn oxide was deposited over the Si by a sputtering method. The S2 was deposited under the following conditions: a target with In:Ga:Zn=4:2:4.1 [atomic ratio] was used, the argon gas flow rate was 40 sccm, the oxygen gas flow rate was 5 sccm, the pressure was 0.7 Pa, and the substrate temperature was 130° C. Note that the S1 and the S2 were successively deposited without being exposed to an air atmosphere.

Then, second heat treatment was performed. As the second heat treatment, treatment was performed at 400° C. in an atmosphere containing nitrogen for one hour, and subsequently another treatment was performed at 400° C. in an atmosphere containing oxygen for one hour.

Next, a 20-nm-thick second tantalum nitride film was deposited over the S2 by a sputtering method. Then, a 5-nm-thick second aluminum oxide film was deposited over the second tantalum nitride film by an ALD method. Next, a 15-nm-thick third tantalum nitride film was deposited over the second aluminum oxide film by a sputtering method.

Then, the third tantalum nitride film in a portion where a channel was formed was etched by a lithography method. A dry etching method was used for the etching.

Then, by a lithography method, a resist mask was formed and the third tantalum nitride film, the second aluminum oxide, and the second tantalum nitride film were etched in this order with the use of the resist mask as an etching mask. After that, the resist mask was removed using oxygen plasma, and the second aluminum oxide in a portion where a channel was formed was etched. Then, unnecessary portions of the S2 and the S1 were etched in this order. A dry etching method was used for the etching.

Then, the second tantalum nitride film in a portion where a channel was formed was etched. The third tantalum nitride film over the third aluminum oxide was concurrently etched by the etching. A dry etching method was used for the etching.

In Sample A, a third oxide (S3) and a fourth oxide (S4) were successively deposited, whereas in Sample B, the S3 was deposited, but the S4 was not deposited.

As the S3 in Sample A, a 5-nm-thick In-Ga—Zn oxide was deposited by a sputtering method. The S3 was deposited under the following conditions: a target with In:Ga:Zn=4:2:4.1 [atomic ratio] was used, the oxygen gas flow rate was 45 sccm, the pressure was 0.7 Pa, and the substrate temperature was 130° C.

Sequentially, as the S4, a 5-nm-thick In-Ga—Zn oxide was deposited by a sputtering method. The S4 was deposited under the following conditions: a target with In:Ga:Zn=1:3:4 [atomic ratio] was used, the oxygen gas flow rate was 45 sccm, the pressure was 0.7 Pa, and the substrate temperature was 200° C.

As the S3 in Sample B, a 5-nm-thick In-Ga—Zn oxide was deposited by a sputtering method. The S3 was deposited under the following conditions: a target with In:Ga:Zn=4:2:4.1 [atomic ratio] was used, the oxygen gas flow rate was 45 sccm, the pressure was 0.7 Pa, and the substrate temperature was 130° C.

Then, a 10-nm-thick fourth silicon oxynitride film having a function of a first gate oxide film was deposited over the S4 in Sample A, and over the S3 in Sample B, by a CVD method.

Then, a 10-nm-thick second titanium nitride film was deposited over the fourth silicon oxynitride film by a sputtering method, and a 30-nm-thick fourth tungsten film was deposited over the second titanium nitride film by a sputtering method. The second titanium nitride film and the fourth tungsten film were successively deposited.

Next, the fourth tungsten film and the second titanium nitride film were etched in this order by a lithography method, so that a gate electrode was formed. For the etching of the fourth tungsten film and the second titanium nitride film, a dry etching method was used.

Next, a 7-nm-thick third aluminum oxide film was deposited by an ALD method. The substrate temperature was 250° C.

Next, in Sample A, part of the third aluminum oxide, part of the fourth silicon oxynitride film, part of the S4, and part of the S3 were etched by a lithography method. A wet method was used for the third aluminum, a dry etching method was used for the fourth silicon oxynitride film, and a wet etching method was used for the S4 and the S3.

In Sample B, part of the third aluminum oxide, part of the fourth silicon oxynitride film, and part of the S3 were etched by a lithography method. A wet method was used for the third aluminum, a dry etching method was used for the fourth silicon oxynitride film, and a wet etching method was used for the S3.

Next, a 310-nm-thick fifth silicon oxynitride film was deposited by a CVD method. Then, second CMP treatment was performed to polish the fifth silicon oxynitride film so that the surface of the fifth silicon oxynitride film was planarized.

Then, a 40-nm-thick fourth aluminum oxide film was deposited over the fifth silicon oxynitride film by a sputtering method under the following conditions: the argon gas flow rate was 25 sccm, the oxygen gas flow rate was 25 sccm, the pressure was 0.4 Pa, and the substrate temperature was 250° C.

Then, third heat treatment was performed. As the third heat treatment, treatment was performed at 350° C. in an atmosphere containing oxygen for one hour.

Next, a 100-nm-thick sixth silicon oxynitride film was deposited by a CVD method.

Then, a 90-nm-thick fifth tungsten film was deposited by a sputtering method. Next, a 130-nm-thick silicon nitride film was deposited by a sputtering method.

Then, a contact hole reaching the second tungsten film (second gate electrode), a contact hole reaching the fourth tungsten film (first gate electrode), and a contact hole reaching the second tantalum nitride film (source electrode and drain electrode) were formed by a lithography method using the fifth tungsten film and the silicon nitride film as etching masks; a 20-nm-thick third titanium nitride film was deposited by an ALD method; and a 150-nm-thick sixth tungsten film was deposited by a CVD method.

Next, third CMP treatment was performed to polish the sixth tungsten film, the third titanium nitride film, the silicon nitride film, and the fifth tungsten film to reach the sixth silicon oxynitride film, so that the sixth tungsten film and the third titanium nitride film were embedded in each contact hole to form plugs.

Next, a 50-nm-thick seventh tungsten film was deposited by a sputtering method. Then, the seventh tungsten film was etched by a lithography method to form a wiring layer.

Next, fourth heat treatment was performed at 250° C. for one hour.

Next, a 1-μm-thick photoresist was formed by a coating method. Then, a portion of the photoresist that is to be a measurement terminal (measurement pad) was removed by a lithography method.

Through the above steps, the transistor 1000 (Sample A) and the comparative sample (Sample B) were fabricated.

Then, electrical characteristics of Sample A and Sample B were measured. Each of Sample A and Sample B is a 5-inch-square substrate, and the transistors are positioned over the substrate.

The electrical characteristics of Sample A and Sample B were measured by measuring change in source-drain current (hereinafter referred to as a drain current I_{d}) when a source-gate potential (hereinafter referred to as a gate potential V_{g}) changed from −4.0 V to +4.0 V at a source potential (Vₛ) of 0 V and a source-drain potential (hereinafter referred to as a drain potential V_{d}) of 0.1 V or 1.2 V. That is, I_{d}-V_{g} characteristics were measured. The gate potential V_{g} refers to a potential of a first gate electrode (top gate electrode), and the same applies hereinafter. In this measurement, the potential of a second gate electrode (back gate electrode) was set to 0 V. The potential of the back gate electrode is referred to as Vb_{g}.

Sample A is a transistor that includes the S4. Sample A is a sample in which the S2 and the S3 were deposited by a sputtering method using a target with In:Ga:Zn=4:2:4.1 [atomic ratio]. Therefore, the S2 and the S3 each have a composition containing more In atoms than Ga atoms, and have the same composition or similar compositions. In addition, Sample A is a sample in which the 51 and the S4 were deposited using a target with In:Ga:Zn=1:3:4 [atomic ratio]. Therefore, the 51 and the S4 each have a composition containing more Ga atoms than In atoms, and have the same composition or similar compositions.

Sample B is a transistor that does not include the S4. Sample B is a sample in which the S2 and the S3 were deposited by a sputtering method using a target with In:Ga:Zn=4:2:4.1 [atomic ratio]. Therefore, the S2 and the S3 each have a composition containing more In atoms than Ga atoms, and have the same composition or similar compositions. In addition, Sample B is a sample in which the S1 was deposited using a target with In:Ga:Zn=1:3:4. Therefore, the 51 has a composition containing more Ga atoms than In atoms.

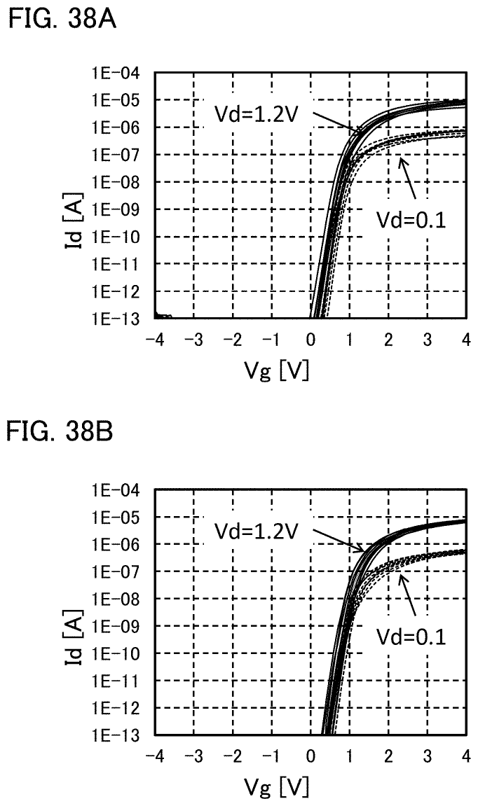

FIG. 38(A) shows the I_{d}-V_{g} characteristics of Sample A and FIG. 38(B) shows the I_{d}-V_{g} characteristics of Sample B. Both of Samples A and B were normally off, and favorable characteristics with a sharp rise from an off state to an on state were obtained.

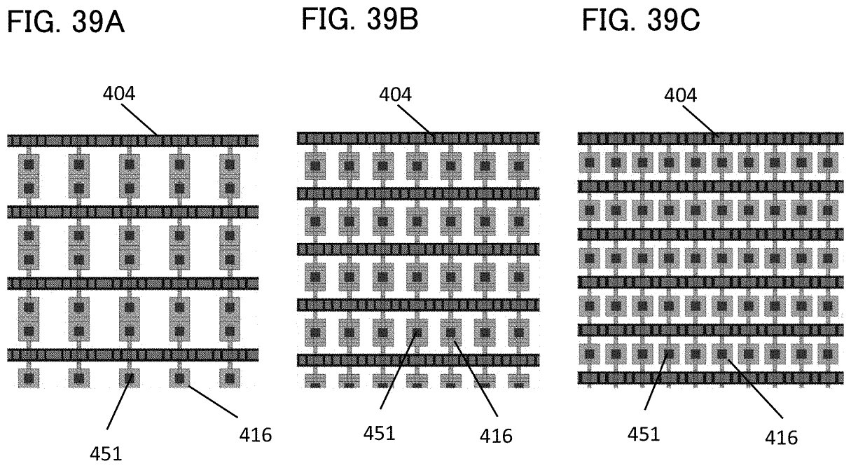

Next, transistors of Sample A and Sample B each arranged at different transistor densities were subjected to the reliability test. In this example, the transistor density is expressed as density /μm². For example, a density of 1.0/μm² shows that one transistor is placed per 1 μm². In this example, the transistors arranged at a density of 1.0/μm², a density of 2.0/μm², and a density of 2.9/μm² were subjected to the reliability test. FIGS. 39(A), 39(B), and 39(C) show layout views of a density of 1.0/μm², a density of 2.0/μm², and a density of 2.9/μm², respectively. In addition, the conductor 404 functioning as a gate electrode, the conductor 451 functioning as a contact electrode, and the conductor 416 functioning as a source electrode or a drain electrode are shown in each of FIGS. 39(A), 39(B), and 39(C).

As the reliability test, a +GBT (Gate Bias Temperature) stress test was performed. The +GBT stress test is one of the most important reliability test items in the reliability test of a transistor.

The +GBT stress test was performed under the following conditions: the sample temperature was 125° C., V_{g} was set to +3.63 V, V_{d} and Vₛ were set to 0 V, and stress was applied for 12 hours (43200 secs) at a maximum. During the stress test, I_{d}-V_{g} measurement was performed at 125° C. after 100 secs (0.028 hr), after 300 secs (0.083 hr), after 600 secs (0.17 hr), after 1000 secs (0.28 hr), after 1800 secs (0.5 hr), after 3600 secs (1 hr), after 7200 secs (2 hrs), after 10000 secs (2.8 hrs), after 18000 secs (5 hrs), after 32400 secs (9 hrs), and after 43200 secs (12 hrs) from the beginning of the stress application. In the I_{d}-V_{g} measurement, I_{d} was measured while V_{g} changed from −3.3 V to +3.3 V. Note that the potential of the second gate electrode was set to 0 V.

Here, as indexes of the amount of change in electrical characteristics of the transistor caused by stress, ΔI_{ds} (%) which shows a rate of change in I_{ds} and ΔVₛₕ (V) which shows a rate of time-dependent change in Vₛₕ were used. In this specification, Vₛₕ is defined as, in the I_{d}-V_{g} curve, a gate voltage at the intersection point of the line of I_{d}=1.0×10⁻¹² [A] and the tangent to the curve at a point where the slope of the curve is the steepest. I_{ds} is I_{d} when V_{d} is 1.2 V and V_{g} is 3.3 V. Aids (%) is a rate of change in difference between I_{ds} when stress application was started and I_{ds} when stress time has passed. ΔVₛₕ is a difference between Vₛₕ when stress application was started and Vₛₕ when stress time has passed.

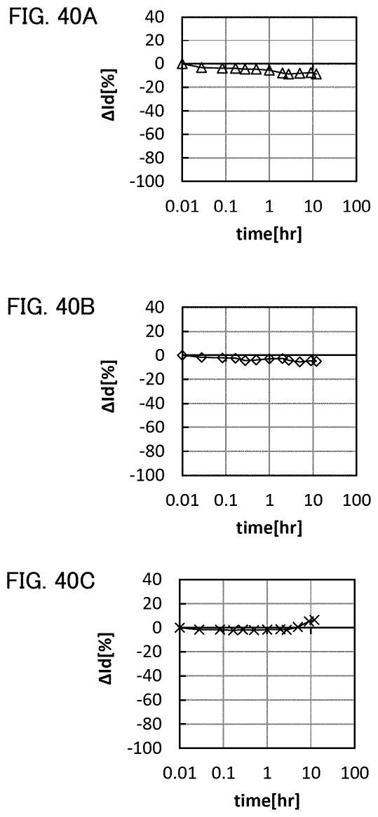

FIG. 40 is a graph showing the +GBT stress time dependence of Aids in Sample A. FIG. 40(A) is a graph showing the stress time dependence of Aids at a density of 1.0/μm², FIG. 40(B) is a graph showing the stress time dependence of Aids at a density of 2.0/μm², and FIG. 40(C) is a graph showing the stress time dependence of Aids at a density of 2.9/μm². At each density, the rate of change after a stress elapsed time of 12 hrs was within 10%.

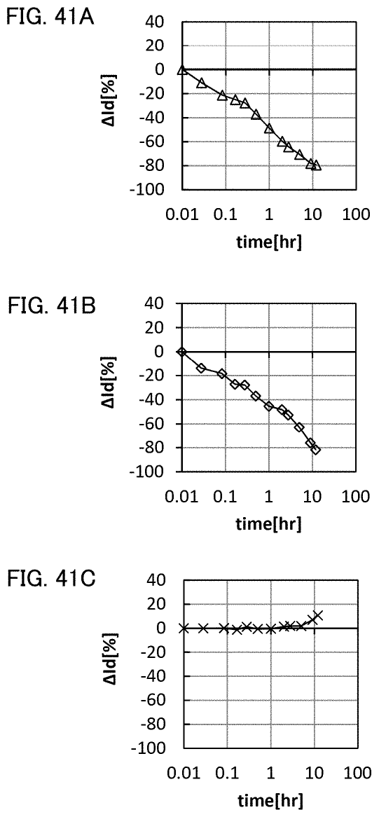

FIG. 41 is a graph showing the +GBT stress time dependence of Aids in Sample B. FIG. 41(A) is a graph showing the stress time dependence of Aids at a density of 1.0/μm², FIG. 41(B) is a graph showing the stress time dependence of Aids at a density of 2.0/μm², and FIG. 41(C) is a graph showing the stress time dependence of Aids at a density of 2.9/μm². At the density of 1.0/μm² and the density of 2.0/μm², the rate of change after a stress elapsed time of 12 hrs was approximately 80%, which indicated a significant deterioration. In addition, at the density of 2.9/μm², the rate of change was approximately +10% after a stress elapsed time of 12 hrs. That is, it is found that the amount of change in I_{ds} depends on density, and as the density is lower, deterioration becomes more significant.

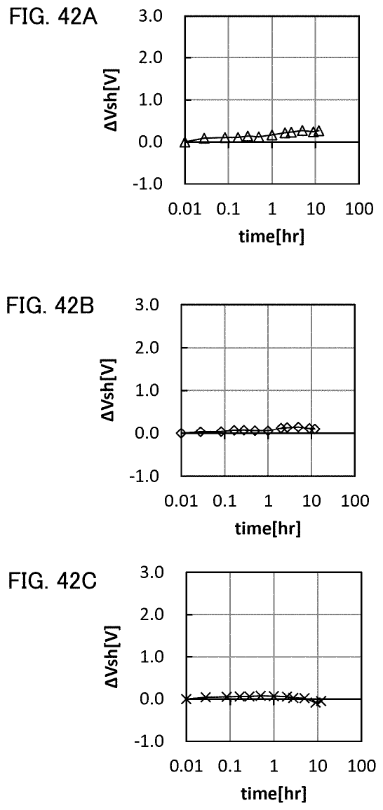

FIG. 42 is a graph showing the +GBT stress time dependence of ΔVₛₕ in Sample A. FIG. 42(A) is a graph showing the stress time dependence of ΔVₛₕ at a density of 1.0/μm², FIG. 42(B) is a graph showing the stress time dependence of ΔVₛₕ at a density of 2.0/μm², and FIG. 42(C) is a graph showing the stress time dependence of ΔVₛₕ at a density of 2.9/μm². At the density of 1.0/μm², the change after a stress elapsed time of 12 hrs was approximately +0.24 V; at the density of 2.0/μm², the change after a stress elapsed time of 12 hrs was approximately +0.11 V; and at the density of 2.9/μm², there was few change after a stress elapsed time of 12 hrs. That is, this result indicates that ΔVₛₕ depends on the density, but the difference is extremely small.

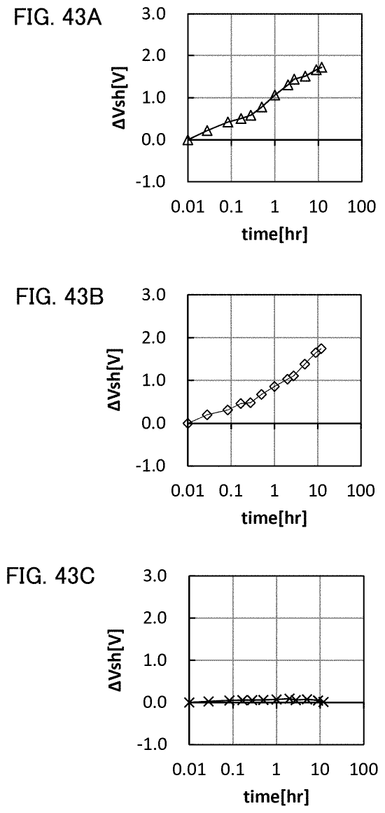

FIG. 43 is a graph showing the +GBT stress time dependence of ΔVₛₕ in Sample B. FIG. 43(A) is a graph showing the stress time dependence of ΔVₛₕ at a density of 1.0/μm², FIG. 43(B) is a graph showing the stress time dependence of ΔVₛₕ at a density of 2.0/μm², and FIG. 43(C) is a graph showing the stress time dependence of ΔVₛₕ at a density of 2.9/μm². At the density of 1.0/μm² and the density of 2.0/μm², change of approximately +1.7 V was observed after a stress elapsed time of 12 hrs. Furthermore, at the density of 2.9/μm², there was few change after a stress elapsed time of 12 hrs. That is, it is found that ΔVₛₕ depends on density, and as the density is lower, deterioration becomes more significant.

From the above results, it is confirmed that the density dependence of ΔVₛₕ in Sample A is greatly improved as compared with that in Sample B.

Next, the correlation between the transistor characteristics before the reliability test (initial characteristics) and the reliability was evaluated. Specifically, the correlation between Vₛₕ in the initial characteristics and ΔVₛₕ that is a value of change after the +GBT stress test was evaluated. The stress elapsed time was 1 hour. In addition, 9 points on a substrate surface of the samples were measured.

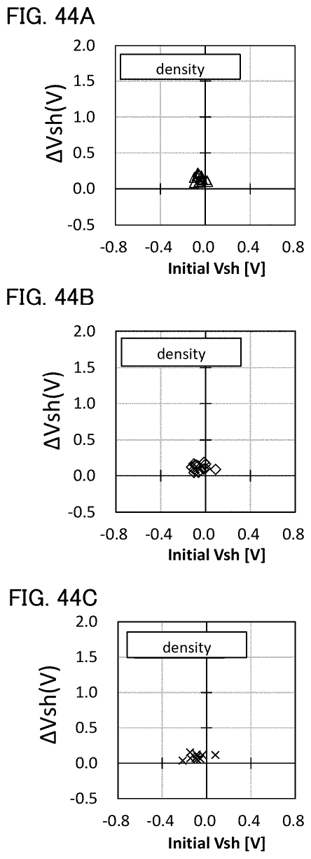

FIG. 44 is a graph showing the correlation between Vₛₕ in the initial characteristics of Sample A and ΔVₛₕ after the +GBT stress test. In the graph, the horizontal axis represents Vₛₕ in the initial characteristics (Initial Vₛₕ) and the vertical axis represents ΔVₛₕ. FIG. 44(A) is a graph at the density of 1.0/μm², FIG. 44(B) is a graph at the density of 2.0/μm², and FIG. 44(C) is a graph at the density of 2.9/μm².

According to FIG. 44, Sample A has approximately the same Initial Vₛₕ at each of the density of 1.0/μm², the density of 2.0/μm², and the density of 2.9/μm²; thus, the density dependence was not observed. In addition, variation in Initial Vₛₕ was small. Change in ΔVₛₕ after the +GBT stress test (after a stress elapsed time of 1 hr) was also small at each density.

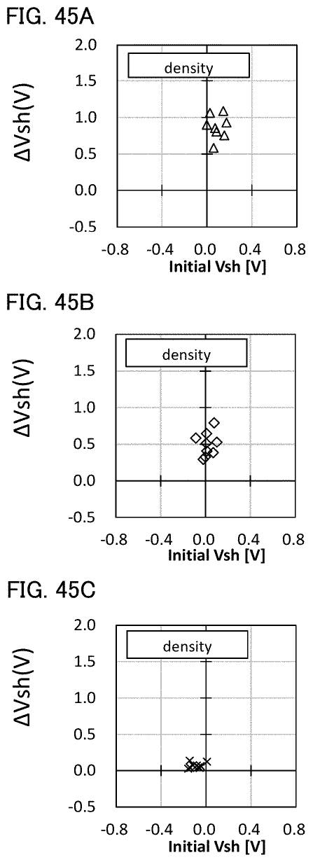

FIG. 45 is a graph showing the correlation between Vₛₕ in the initial characteristics of Sample B and ΔVₛₕ after the +GBT stress test. FIG. 45 is a graph at the density of 1.0/μm², FIG. 45(B) is a graph at the density of 2.0/μm², and FIG. 45(C) is a graph at the density of 2.9/μm².

According to FIG. 45, Initial Vₛₕ in Sample B tends to decrease as the density increases. That is, Vₛₕ tends to shift in the negative direction as the density increases. Difference in variation in Initial Vₛₕ among the densities was not observed. As for the change in ΔVₛₕ after the +GBT stress test (after a stress elapsed time of 1 hr), there was a large change at the density of 1.0/μm² and the density of 2.0/μm², and the variation in ΔVₛₕ was also large. The variation was small at the density of 2.9/μm². From the above, it was found that variations in Initial Vₛₕ and ΔVₛₕ depend on density in Sample B.

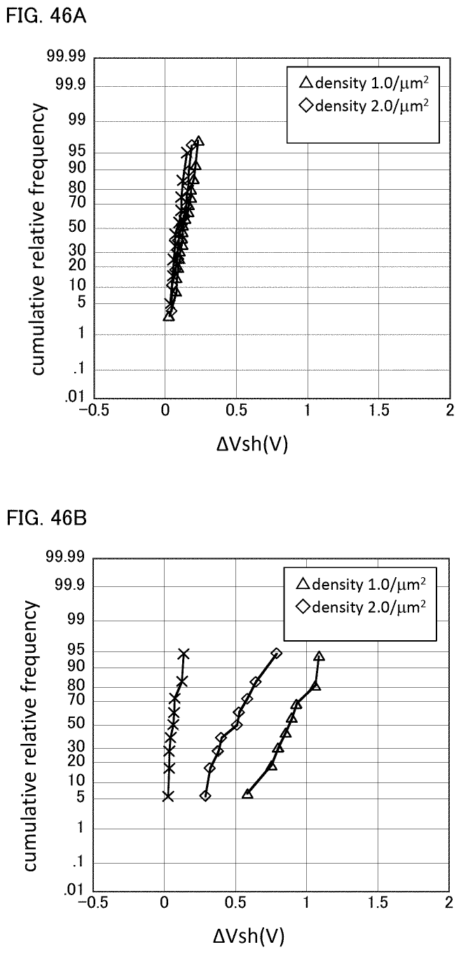

FIG. 46 is a graph showing a cumulative relative frequency using data of ΔVₛₕ in the data of FIG. 45. The horizontal axis represents ΔVₛₕ and the vertical axis represents the cumulative relative frequency. As the gradient of a line obtained by connecting each points in the graph (a cumulative relative frequency line) is closer to vertical, the variation is smaller.

FIG. 46(A) is a graph showing a cumulative relative frequency of ΔVₛₕ at each density in Sample A, and FIG. 46(B) is a graph showing a cumulative relative frequency of ΔVₛₕ at each density in Sample B. In FIG. 46(A), the cumulative relative frequency lines at the density of 1.0/μm², the density of 2.0/μm², and the density of 2.9/μm² are overlapped with each other, and the gradient of the cumulative relative frequency lines are steep. Thus, the density dependence of ΔVₛₕ was not observed, and substantially the same value was obtained at each density. In addition, variation was also small.

According to FIG. 46(B), ΔVₛₕ in Sample B depends on the density, and ΔVₛₕ increases as the density decreases. Furthermore, the variation in ΔVₛₕ at the density of 2.9/μm² was small as in Sample A, whereas the variations in ΔVₛₕ at the density of 1.0/μm² and the density of 2.0/μm² were larger than that in ΔVₛₕ in Sample A.

From the above results, it was confirmed that the transistor having a structure including the S4 of one embodiment of the present invention has small density dependences of the initial characteristics of the transistor and the reliability, and thus has favorable transistor characteristics and high reliability.

### REFERENCE NUMERALS

B1: terminal
B2: terminal
C31: capacitor
C36: capacitor
C61: capacitor
C62: capacitor
CB31: capacitor
CB36: capacitor
CLK1: clock signal
CLK2: clock signal
CS1: capacitor
M31: Si transistor
M37: Si transistor
MN61: transistor
MN62: transistor
MO31: OS transistor
MO32: OS transistor
MO35: OS transistor
MO36: OS transistor
MO61: OS transistor
MO62: OS transistor
MOB31: OS transistor
MOB32: OS transistor
MOB35: OS transistor
MOB36: OS transistor
MP61: transistor
MP62: transistor
MP63: transistor
MW1: transistor
N31: node
N32: node
N36: node
N37: node
NB32: node
NB36: node
NB37: node
100: capacitor
101: capacitor
110: conductor
112: conductor
120: conductor
122: barrier layer
130: insulator
150: insulator
161: memory cell
200: transistor
201: transistor
210: insulator
212: insulator
214: insulator
216: insulator
218: conductor
220: insulator
222: insulator
224: insulator
230c: oxide
230d: oxide
240b: conductor
245b: barrier layer
246: insulator
248: conductor
250: insulator
260: conductor
270: barrier layer
280: insulator
282: insulator
286: insulator
300: transistor
301: insulator
302: insulator
303: insulator
310: conductor
310a: conductor
310b: conductor
311: substrate
313: semiconductor region
314a: low-resistance region
314b: low-resistance region
315: insulator
316: conductor
320: insulator
322: insulator
324: insulator
326: insulator
328: conductor
330: conductor
340: transistor
345: transistor
350: insulator
352: insulator
354: insulator
356: conductor
360: insulator
362: insulator
364: insulator
366: conductor
370: insulator
372: insulator
374: insulator
376: conductor
380: insulator
382: insulator
384: insulator
386: conductor
401: insulator
402: insulator
404: conductor
404a: conductor
404b: conductor
405: conductor
405a: conductor
405b: conductor
406: oxide
406a: oxide
406a1: oxide
406a2: oxide
406a3: oxide
406b: oxide
406b1: oxide
406b2: oxide
406b3: oxide
406c: oxide
406c1: oxide
406d: oxide
406d1: oxide
407: region
407a: region
408a: insulator
408b: insulator
410: insulator
411: conductor
411a: conductor
411a1: conductor
411a2: conductor
412: insulator
412a: insulator
415: insulator
416: conductor
416a: conductor
416a1: conductor
416a2: conductor
417: barrier film
417a: barrier film
417a1: barrier film
417a2: barrier film
418: insulator
420: insulator
421: resist
422: insulator
430: insulator
430c: oxide
430d: oxide
431a: oxide
431b: oxide
432: insulator
432a: oxide
432b: oxide
440: conductor
440a: conductor
440b: conductor
441a: conductor
441b: conductor
445: barrier layer
445a: barrier layer
445b: barrier layer
450: insulator
450a: insulator
450b: insulator
451: conductor
451a: conductor
451b: conductor
452a: conductor
452b: conductor
453a: conductor
453b: conductor
460: conductor
460a: conductor
460b: conductor
470: barrier layer
500: structure
711: substrate
712: circuit region
713: separation region
714: separation line
715: chip
750: electronic component
752: printed circuit board
754: circuit board
755: lead
1000: transistor
1000a: transistor
1000b: transistor
1000c: transistor
1400: DOSRAM
1405: controller
1410: row circuit
1411: decoder
1412: word line driver circuit
1413: column selector
1414: sense amplifier driver circuit
1415: column circuit
1416: global sense amplifier array
1417: input/output circuit
1420: sense amplifier array
1422: memory cell array
1423: sense amplifier array
1425: local memory cell array
1426: local sense amplifier array
1444: switch array
1445: memory cell
1446: sense amplifier
1447: global sense amplifier
1600: NOSRAM
1610: memory cell array
1611: memory cell
1612: memory cell
1613: memory cell
1614: memory cell
1640: controller
1650: row driver
1651: row decoder
1652: word line driver
1660: column driver
1661: column decoder
1662: driver
1663: DAC
1670: output driver
1671: selector
1672: ADC
1673: output buffer
2000: transistor
2910: information terminal
2911: housing
2912: display portion
2913: camera
2914: speaker portion
2915: operation switch
2916: external connection portion
2917: microphone
2920: notebook personal computer
2921: housing
2922: display portion
2923: keyboard
2924: pointing device
2940: video camera
2941: housing
2942: housing
2943: display portion
2944: operation switch
2945: lens
2946: adjoining portion/joint
2950: information terminal
2951: housing
2952: display portion
2960: information terminal
2961: housing
2962: display portion
2963: band
2964: buckle
2965: operation switch
2966: input/output terminal
2967: icon
2980: car
2981: car body
2982: wheel
2983: dashboard
2984: light
3001: wiring
3002: wiring
3003: wiring
3004: wiring
3005: wiring
3006: wiring
3007: wiring
3008: wiring
3009: wiring
3010: wiring
3110: OS-FPGA
3111: controller
3112: word driver
3113: data driver
3115: programmable area
3117: IOB
3119: core
3120: LAB
3121: PLE
3123: LUT block
3124: register block
3125: selector
3126: CM
3127: power switch
3128: CM
3130: SAB
3131: SB
3133: PRS
3135: CM
3137: memory circuit
3137B: memory circuit
3140: OS-FF
3141: FF
3142: shadow register
3143: memory circuit
3143B: memory circuit
3188: inverter circuit
3189: inverter circuit
4010: arithmetic portion
4011: analog arithmetic circuit
4012: DOSRAM
4013: NOSRAM
4014: FPGA
4020: control portion
4021: CPU
4022: GPU
4023: PLL
4025: PROM
4026: memory controller
4027: power supply circuit
4028: PMU
4030: input/output portion
4031: external memory control circuit
4032: audio codec
4033: video codec
4034: general-purpose input/output module
4035: communication module
4041: AI system
4041_n: AI system
4041_1: AI system
4041A: AI system
4041B: AI system
4098: bus line
4099: network
7000: AI system IC
7001: lead
7003: circuit portion
7031: Si transistor layer
7032: wiring layer
7033: OS transistor layer

1. A semiconductor device comprising:
a first oxide;
a second oxide over the first oxide;
a source electrode and a drain electrode over the second oxide;
a third oxide over the second oxide, the source electrode, and the drain electrode;
a fourth oxide over the third oxide;
a gate insulating film over the fourth oxide; and
a gate electrode over the gate insulating film,
wherein a band gap of the first oxide is substantially the same as a band gap of the fourth oxide,
wherein a band gap of the second oxide is substantially the same as a band gap of the third oxide,
wherein the band gap of the first oxide is larger than the band gap of the second oxide, and
wherein the fourth oxide is less likely to transmit oxygen than the third oxide.

2. The semiconductor device according to claim 1,
wherein the second oxide and the third oxide each comprise a channel formation region,
wherein the channel formation region is positioned between the source electrode and the drain electrode, and
wherein a height from a bottom surface of the first oxide to each of the channel formation region, the source electrode, and the drain electrode is substantially the same.

3. The semiconductor device according to claim 1,
wherein a difference between the band gap of the first oxide and the band gap of the fourth oxide is less than or equal to 0.15 eV,
wherein a difference between the band gap of the second oxide and the band gap of the third oxide is less than or equal to 0.15 eV, and
wherein a difference between the band gap of the first oxide and the band gap of the second oxide is greater than or equal to 0.3 eV and less than or equal to 0.7 eV.

4. The semiconductor device according to claim 1,
wherein the first to fourth oxides each comprise In, an element M, and Zn,
wherein the element M is Al, Ga, Y, or Sn,
wherein the first oxide and the fourth oxide each comprise a region in which a proportion of the element M is higher than a proportion of In,
wherein the second oxide and the third oxide each comprise a region in which a proportion of the element M is lower than a proportion of In,
wherein the first oxide and the fourth oxide have the same composition or similar compositions, and
wherein the second oxide and the third oxide have the same composition or similar compositions.

5. The semiconductor device according to claim 1, wherein the fourth oxide is less likely to transmit oxygen than the gate insulating film.

6. A module characterized by comprising the semiconductor device according to claim 1 and a printed circuit board.

7. An electronic device comprising the module according to claim 6, and a speaker or an operation key.

8. A semiconductor wafer comprising:
a plurality of the semiconductor devices according to claim 1; and
a region for dicing.

9. A method for fabricating a semiconductor device comprising:
forming a first oxide by a sputtering method using a first target;
forming a second oxide over the first oxide by the sputtering method using a second target;
forming a first conductor and a second conductor over the second oxide;
forming a third oxide over the second oxide, the first conductor, and the second conductor by the sputtering method using a third target;
forming a fourth oxide over the third oxide by the sputtering method using a fourth target;
forming an insulator over the fourth oxide; and
forming a third conductor over the insulator,
wherein the first to fourth targets each comprise two or more kinds of metal elements,
wherein an atomic ratio of the metal elements in the first target and an atomic ratio of the metal elements in the fourth target are the same or similar to each other, and
wherein an atomic ratio of the metal elements in the second target and an atomic ratio of the metal elements in the third target are the same or similar to each other.

10. The method according to claim 9,
wherein the first target and the fourth target each comprise In, an element M, and Zn,
wherein the element M is Al, Ga, Y, or Sn,
wherein the number of In atoms are less than the number of the element M atoms,
wherein the second target and the third target each comprise In, the element M, and Zn,
wherein the element M is Al, Ga, Y, or Sn, and
wherein the number of In atoms are greater than the number of the element M atoms.

11. The method according to claim 9,
wherein the first oxide and the second oxide are formed under a reduced pressure in an order of the first oxide and the second oxide, and
wherein the third oxide and the fourth oxide are formed under the reduced pressure in an order of the third oxide and the fourth oxide.

12. A module comprising a semiconductor device fabricated using the method according to claim 9, and a printed circuit board.

13. An electronic device comprising the module according to claim 12, and a speaker or an operation key.
